(19) United States
(12) Patent Application Publication
(10) Pub. No.: US 2008/0113302 A1
(43) Pub. Date: May 15, 2008

(54) Pattern Forming Process

(76) Inventors: Masanobu Takashima, Shizuoka (JP); Hiromi Ishikawa, Kanagawa (JP); Yuji Shimoyama, Kanagawa (JP)

Correspondence Address: SUGHRUE MION, PLLC, 2100 PENNSYLVANIA AVENUE, N.W., SUITE 800, WASHINGTON, DC, 20037, US

(21) Appl. No.: 11/597,741

(22) PCT Filed: May 25, 2005
(86) PCT No.: PCT/JP05/09554

§ 371 Date: Aug. 17, 2007

(30) Foreign Application Priority Data
May 26, 2004 (JP) 2004-156596
Apr. 4, 2005 (JP) 2005-107956

(51) Int. Cl. G03F 7/207

(52) U.S. Cl. 430/322

(57) ABSTRACT

The present invention aims to provide a pattern forming process which allows efficiently, highly precisely forming of a permanent pattern such as interconnection patterns and also allows achieving both tent property and resolution at high level. The pattern forming process includes laminating a photosensitive layer on a substrate to be processed in a pattern forming material which comprises at least the photosensitive layer, and exposing two or more arbitrarily selected regions in the photosensitive layer with light of a different amount of energy, wherein a laser beam emitted from a light irradiating unit having ‘n’ imaging portions receiving light from a light irradiating unit and outputting the light is modulated before the photosensitive layer is exposed with the laser beam through a microlens array in which microlenses each having a non-spherical surface capable of compensating the aberration due to distortion of output surfaces of the imaging portions are arrayed.

### TECHNICAL FIELD

The present invention relates to a pattern forming process in which laser beams modulated by a light modulating unit such as a spatial light modulator are imaged on pattern a forming material thereby exposing the pattern forming material, and the resulting patterns produced by the pattern forming processes.

### BACKGROUND ART

Exposing devices have become popular in which lights or laser beams modulated by spatial light modulators and the like are directed to imaging optical systems and optical images are formed on pattern forming materials so as to expose the pattern forming materials. Typically, such exposing devices are provided with a spatial light modulator that is equipped with planar arrays of many imaging portions that modulate an incident light or laser beam depending on various controlling signals, a laser source that irradiates a laser beam to the spatial light modulator, and an imaging optical system that forms an image from the modulated laser beam through the spatial light modulator onto a pattern forming material (see Non Patent Literature 1 and Patent Literature 1).

Examples of the spatial light modulators include liquid crystal displays (LCD), digital micromirror devices (DMD). The DMD is referred to as a mirror device that is equipped with planar arrays of many micromirrors as imaging portions that change the reflecting angle depending on the controlling signal on a semiconductor substrate made of silicon or the like.

In the exposing devices, images to be projected on the pattern forming material are often desired to magnify, thus a magnified imaging optical system is utilized as the imaging optical system for responding to such a desire. However, the means to solely direct the modulated light from the spatial light modulator into the magnified imaging optical system leads to magnify the light flux from the respective imaging portions of the spatial light modulator, resulting in a disadvantage that clearness of pixels decreases due to magnified pixel size within the projected pattern.

In order to address such a disadvantage, Patent Literature 1 proposes a magnified projection wherein a first imaging optical device is on a path of laser beam modulated by the spatial light modulator, an array of microlenses is disposed on the imaging surface of the first imaging optical device, the microlenses respectively correspond to the imaging portions of the spatial light modulator, a second imaging optical device is disposed on the path of laser beam from the array of microlenses that images the modulated light on a pattern forming material or a screen, and images are magnified by the first and the second imaging optical devices. In this proposal, while the size of images projected on the pattern forming material or screen may be magnified, the laser beam from the respective imaging portions of the spatial light modulator is collected by the respective microlenses of the array, therefore, the drawing size or spot size of the projected image is focused and reduced, resulting in higher sharpness of images.

In addition, an exposure device that combines DMD as the spatial light modulator and a microlens array is proposed (see Patent Literature 2). A similar exposure device is also proposed in which a perforated plate having apertures corresponding to each of the microlenses of the array is disposed behind the microlens array such that only the laser beam through the microlenses passes through the apertures (see Patent Literature 3). In these exposure devices, excluding the incident laser beam from the adjacent microlenses that do not correspond to the respective apertures may enhance extinction ratio.

However, these proposals suffer from a problem that images formed on the pattern forming materials are deformed through utilizing the laser beam collected by the microlenses of the array. The problem is significant in particular when the DMD is utilized as the spatial light modulator.

To increase the resolution of pattern forming materials, it is effective to thin the thickness of the photosensitive layer. When the thickness of a photosensitive layer on a hole portion such as a through hole or a via hole of a printed circuit board, it causes a problem that a tent layer protecting the hole portion tears in the process of dissolving and removing unhardened portions and in the process of etching exposed metal layer portions.

Besides print circuit boards having hole portions, a pattern forming process that allows improvements in tenting property while keeping the resolution is required when there is a need to improve the hardness of respective reasons of a photosensitive layer made of a pattern forming material.

By curbing distortions of images to be formed on pattern forming materials, permanent patterns such as interconnection patterns can be finely and efficiently formed. A pattern forming process highly achieving both tenting property and resolution has not been provided yet, and the current situation is that further improvements and developments are desired.

Patent Literature 1 Japanese Patent Application Laid Open (JP-A) No. 2004-1244

Patent Literature 2 Japanese Patent Application Laid Open (JP-A) No. 2001-305663

Patent Literature 3 Japanese Patent Application Laid Open (JP-A) No. 2001-500628

Non Patent Literature “Shortening of Research and Application to Massproduction by Maskless Exposure” Akito Ishikawa, Electronics Jisso Gijyutsu, Gicho Publishing & Advertising Co., Ltd., vol. 18, No. 6, pp. 74-79 (2002)

### DISCLOSURE OF THE INVENTION

The present invention aims to provide a pattern forming process which allows finely and efficiently forming permanent patterns such as interconnection patterns and highly achieving both tent property and resolution by curbing distortions of images to be formed on pattern forming materials having at least a photosensitive layer.

<1> A pattern forming process which includes laminating a photosensitive layer on a substrate to be processed in a pattern forming material which contains at least the photosensitive layer, and exposing two or more arbitrarily selected regions in the photosensitive layer respectively with a laser beam of a different amount of energy.

In the pattern forming process according to the item <1>, when a higher hardness is required for a certain region in a photosensitive layer than in other regions for example, it can be easily achieved by exposing the photosensitive layer with varying an energy amount of irradiation light for each region of the photosensitive layer, or by applying light with a high energy amount only to the certain region. Thus, there is no need to thicken the photosensitive layer as a whole, and high resolution and etching property can be maintained. Further, the pattern forming process allows uniformly harden a photosensitive layer of a pattern forming material with nonuniform in thickness to avoid etching defects caused by nonuniform thickness thereof. The energy amount of applied light can be referred to as “exposure dose”, and the unit is (m)J/cm².

<2> The pattern forming process according to the item <1>, wherein a laser beam emitted from a light irradiating unit having ‘n’ imaging portions receiving light from a light irradiating unit and outputting the light is modulated before the photosensitive layer is exposed with the laser beam through a microlens array in which microlenses each having a non-spherical surface capable of compensating the aberration due to distortion of output surfaces of the imaging portions are arrayed.

In the pattern forming process according to the item <2>, the light irradiating unit is configured to irradiate light toward the light modulating unit. The ‘n’ imaging portions in the light irradiating unit receive light from the light irradiating unit and output the light to thereby modulate the light received from the light irradiating unit. The light modulated by the light modulating unit passes through the each non-spherical surface in the microlens array to thereby compensate the aberration due to distortion of output surfaces of the imaging portions and then to substantially prevent distortion of an image to be formed on the pattern forming material. For example, thereafter, by developing the photosensitive layer, a highly precise pattern can be formed on the pattern forming material.

<3> The pattern forming process according to the item <1>, wherein a laser beam emitted from a light irradiating unit having ‘n’ imaging portions receiving light from a light irradiating unit and outputting the light is modulated before the photosensitive layer is exposed with the laser beam through a microlens array in which microlenses each having a lens aperture shape that prevents light from the periphery of the imaging portions from entering the each of lenses.

In the pattern forming process according to the item <3>, the light irradiating unit is configured to irradiate light toward the light modulating unit. The ‘n’ imaging portions in the light irradiating unit receive light from the light irradiating unit and output the light to thereby modulate the light received from the light irradiating unit. The light modulated by the light modulating unit passes through the each of microlenses having a lens aperture shape that prevents light from the periphery of the imaging portions from entering the each of lenses. Therefore, the laser beam reflected or transmitted at the periphery portions of the micromirror where the distortion level is relatively large, particularly the laser beam reflected at the four corners cannot be collected by microlens, thus the distortion of laser beam may be prevented at the collecting site. Consequently, the pattern forming material can be highly precisely exposed. For example, thereafter, by developing the photosensitive layer, a highly precise pattern can be formed.

<4> The pattern forming process according to the item <3>, wherein each of the microlenses contains a non-spherical surface capable of compensating the aberration due to distortion of output surfaces of the imaging portions.

In the pattern forming process according to the item <4>, the light modulated by the light modulating unit passes through the each non-spherical surface in the microlens array to thereby compensate the aberration due to distortion of output surfaces of the imaging portions and then to substantially prevent distortion of an image to be formed on the pattern forming material. For example, thereafter, by developing the photosensitive layer, a highly precise pattern can be formed on the pattern forming material.

<5> The pattern forming process according to any one of the items <2> to <4>, wherein the non-spherical surface is a toric surface.

In the pattern forming process according to the item <5>, the non-spherical surface is a toric surface, thereby the aberration due to distortion of output surfaces of the imaging portions can be efficiently compensated, and distortion of an image to be formed on the pattern forming material can be efficiently prevented. Consequently, the pattern forming material can be highly precisely exposed. For example, thereafter, by developing the photosensitive layer, a highly precise pattern can be formed.

<6> The pattern forming process according to any one of the items <3> to <5>, wherein each of the microlenses has a circular aperture shape.

<7> The pattern forming process according to any one of the items <3> to <6>, wherein the lens aperture shape is defined by providing with a light shielding part on the lens surface.

<8> The pattern forming process according to any one of the items <1> to <7>, wherein the substrate to be processed has hole portions; and the energy amount of light applied to the hole portions of the photosensitive layer differs from the energy amount of light applied to the regions of the photosensitive layer other than the hole portions.

In the pattern forming process according to the item <8>, the energy amount of light applied to the hole portions of the photosensitive layer differs from the energy amount of light applied to the regions of the photosensitive layer other than the hole portions, and thus by developing the photosensitive layer after the exposure treatment, a hardened film having a different hardness from those of the other regions or a hardened film having different thicknesses depending on region can be formed.

<9> The pattern forming process according to the item <8>, wherein when the energy amount of light applied to the hole portions of the photosensitive layer is represented by A and the energy amount of light applied to the regions of the photosensitive layer other than the hole portions is represented by B, the relation A>B is satisfied.

In the pattern forming process according to the item <9>, particularly in the case of a substrate for a printed wiring board having hole portions such as through holes or via holes, by making the energy amount of light applied to the hole portions of the photosensitive layer larger than that of regions of the photosensitive layer other than the hole portions, the hardness of a tent layer to be formed on the hole portions can be increased, and the durability of the tent layer can be increased after the developing treatment. Further, even when the diameter of the hole portions is relatively large, a tent layer having a high hardness can be formed without necessity of thickening the photosensitive layer.

<10> The pattern forming process according to any one of the items <2> to <9>, wherein the light modulating unit is able to control any imaging portions of less than arbitrarily selected “n” imaging portions disposed successively from among the ‘n’ imaging portions depending on the pattern information.

In the pattern forming process according to the item <10>, by controlling any imaging portions of less than arbitrarily selected “n” imaging portions disposed successively from among the ‘n’ imaging portions depending on the pattern information, light emitted from the light irradiating unit can be modulated at high speed.

<11> The pattern forming process according to any one of the items <2> to <10>, wherein the light modulating unit is a spatial light modulator.

<12> The pattern forming process according to the item <11>, wherein the spatial light modulator is a digital micromirror device (DMD).

<13> The pattern forming process according to any one of the items <1> to <12>, wherein the photosensitive layer is exposed through an aperture array.

In the pattern forming process according to the item <13>, the photosensitive layer is exposed through an aperture array, thereby the extinction ratio can be improved. Consequently, the pattern forming material can be highly precisely exposed. For example, thereafter, by developing the photosensitive layer, a highly precise pattern can be formed.

<14> The pattern forming process according to any one of the items <1> to <13>, wherein the photosensitive layer is exposed while relatively moving the exposure light and the photosensitive layer.

In the pattern forming process according to the item <14>, by exposing the photosensitive layer while relatively moving the exposure light and the photosensitive layer, the photosensitive layer can be exposed at high speed.

<15> The pattern forming process according to any one of the items <1> to <14>, wherein the photosensitive layer is exposed before the photosensitive layer is developed.

<16> The pattern forming process according to the item <15>, wherein the photosensitive layer is developed before a permanent pattern is formed thereon.

<17> The pattern forming process according to the item <16>, wherein the permanent pattern is an interconnection pattern and is formed by any one of an etching treatment and a plating treatment.

In the pattern forming process according to the item <17>, the permanent pattern is the interconnection pattern, and the permanent pattern is formed by any one of an etching treatment and a plating treatment, thereby a highly precise interconnection pattern can be formed.

<18> The pattern forming process according to any one of the items <2> to <17>, wherein the light irradiating unit allows irradiation with two or more types of light.

In the pattern forming process according to the item <18>, the light irradiating unit allows irradiation with two or more type of light, thereby the photosensitive layer can be exposed with exposure laser beams with a deep focus depth. Consequently, the pattern forming material can be highly precisely exposed. For example, thereafter, by developing the photosensitive layer, a highly precise pattern can be formed.

<19> The pattern forming process according to any one of the items <2> to <18>, wherein the light irradiating unit contains a plurality of lasers, a multi-mode optical finer, and a collecting optical system which collects respective laser beams and connect them to the multimode optical fiber.

In the pattern forming process according to the item <19>, laser beams emitted respectively from the plurality of lasers are collected to the collecting optical system by means of the light irradiating unit to allow them to connect the multimode optical fiber, thereby the photosensitive layer can be exposed with exposure laser beams with a deep focus depth. Consequently, the pattern forming material can be highly precisely exposed. For example, thereafter, by developing the photosensitive layer, a highly precise pattern can be formed.

<20> The pattern forming process according to any one of the items <1> to <19>, wherein the photosensitive layer is formed by transcription of a dry film resist.

<21> The pattern forming process according to any one of the items <1> to <20>, wherein the photosensitive layer is formed by application of a liquid resist.

<22> The pattern forming process according to any one of the items <1> to <21>, wherein the photosensitive layer contains at least a binder, a polymerizable compound, and a photopolymerization initiator.

<23> The pattern forming process according to the item <22>, wherein the binder contains an acid group.

<24> The pattern forming process according to any one of the items <22> to <23>, wherein the binder contains a vinyl copolymer.

<25> The pattern forming process according to any one of the items <22> to <24>, wherein the binder has an acid value of 70 mgKOH/g to 250 mgKOH/g.

<26> The pattern forming process according to any one of the items <22> to <25>, wherein the polymerizable compound contains at least any one of a urethane group and an aryl group.

<27> The pattern forming process according to any one of the items <22> to <26>, wherein the photopolymerization initiator is at least one selected from the group consisting of halogenated hydrocarbon derivatives, hexaaryl-bimidazole compounds, oxime derivatives, organic peroxides, thio-compounds, ketone compounds, aromatic onium salts, and metallocenes.

<28> The pattern forming process according to any one of the items <1> to <27>, wherein the photosensitive layer contains the binder in an amount of 10% by mass to 90% by mass and the polymerizable compound in an amount of 5% by mass to 9% by mass.

<29> The pattern forming process according to any one of the items <1> to <28>, wherein the photosensitive layer has a thickness of 1 μm to 100 μm.

<30> The pattern forming process according to any one of the items <1> to <29>, wherein the pattern forming material contains at least the photosensitive layer on a support.

<31> The pattern forming process according to any one of the items <1> to <30>, wherein the pattern forming material contains a cushion layer between the support and the photosensitive layer.

<32> The pattern forming process according to any one of the items <30> to <31>, wherein the support contains a synthetic resin and is transparent.

<33> The pattern forming process according to any one of the items <30> to <32>, wherein the support is formed in an elongated shape.

<34> The pattern forming process according to any one of the items <1> to <33>, wherein the pattern forming material is formed in an elongated roll shape.

<35> The pattern forming process according to any one of the items <1> to <34>, wherein a protective film is formed on the photosensitive layer in the pattern forming material.

### BRIEF DESCRIPTION OF DRAWINGS

FIG. 1 is a partially enlarged view that shows exemplarily a construction of a digital micromirror device (DMD).

FIG. 2A is a view that explains exemplarily the motion of the DMD.

FIG. 2B is a view that explains exemplarily the motion of the DMD.

FIG. 3A is an exemplary plan view that shows the exposing beam and the scanning line in the case where the DMD is not inclined, compared to the exposing beam and the scanning line in the case where the DMD is inclined.

FIG. 3B is an exemplary plan view that shows the exposing beam and the scanning line in the case where a DMD similar to that in FIG. 3A is not inclined, compared to the exposing beam and the scanning line in the case where the DVD is inclined.

FIG. 4A is an exemplary view that shows an available region of the DMD.

FIG. 4B is an exemplary view that shows another available region of the DMD shown in FIG. 4A.

FIG. 5 is an exemplary plan view that explains a way to expose a pattern forming material in one scanning by means of a scanner.

FIG. 6A is an exemplary plan view that explains a way to expose a pattern forming material in plural scannings by means of a scanner.

FIG. 6B is another exemplary plan view that explains a way to expose a pattern forming material in plural scannings by means of a scanner.

FIG. 7 is a schematic perspective view that shows exemplarily the appearance of a pattern forming apparatus.

FIG. 8 is a schematic perspective view that shows exemplarily a scanner construction of a pattern forming apparatus.

FIG. 9A is an exemplary plan view that shows exposed regions formed on a pattern forming material.

FIG. 9B is an exemplary plan view that shows regions exposed by respective exposing heads.

FIG. 10 is a schematic perspective view that shows exemplarily an exposing head containing a light modulating unit.

FIG. 11 is an exemplary cross sectional view that shows the construction of the exposing head shown in FIG. 10 in the sub-scanning direction along the optical axis.

FIG. 12 shows an exemplary controller to control the DMD based on pattern information.

FIG. 13A is an exemplary cross sectional view that shows a construction of another exposing head in other connecting optical system along the optical axis.

FIG. 13B is an exemplary plan view that shows an optical image projected on an exposed surface when a microlens array is not employed.

FIG. 13C is an exemplary plan view that shows an optical image projected on an exposed surface when a microlens array is employed.

FIG. 14 is an exemplary view that shows distortion of a reflective surface of a micromirror that constitutes a DMD by means of contour lines.

FIG. 15A is an exemplary graph that shows height displacement of a micromirror along the X direction.

FIG. 15B is an exemplary graph that shows height displacement of a micromirror along the Y direction.

FIG. 16A is an exemplary front view that shows a microlens array employed in a pattern forming apparatus.

FIG. 16B is an exemplary side view that shows a microlens array employed in a pattern forming apparatus.

FIG. 17A is an exemplary front view that shows a microlens of a microlens array.

FIG. 17B is an exemplary side view that shows a microlens of a microlens array.

FIG. 18A is an exemplary view that schematically shows a laser collecting condition in a cross section of a microlens.

FIG. 18B is an exemplary view that schematically shows a laser collecting condition in another cross section of a microlens.

FIG. 19A is an exemplary view that shows a simulation of beam diameters near the focal point of a microlens in accordance with the present invention.

FIG. 19B is an exemplary view that shows another simulation similar to FIG. 19A in terms of other sites in accordance with the present invention.

FIG. 19C is an exemplary view that shows still another simulation similar to FIG. 19A in terms of other sites in accordance with the present invention.

FIG. 19D is an exemplary view that shows still another simulation similar to FIG. 19A in terms of other sites in accordance with the present invention.

FIG. 20A is an exemplary view that shows a simulation of beam diameters near the focal point of a microlens in a conventional pattern forming process.

FIG. 20B is an exemplary view that shows another simulation similar to FIG. 20A in terms of other sites.

FIG. 20C is an exemplary view that shows still another simulation similar to FIG. 20A in terms of other sites.

FIG. 20D is an exemplary view that shows still another simulation similar to FIG. 20A in terms of other sites.

FIG. 21 is an exemplary plan view that shows another construction of a combined laser source.

FIG. 22A is an exemplary front view that shows a microlens of a microlens array.

FIG. 22B is an exemplary side view that shows a microlens of a microlens array.

FIG. 23A is an exemplary view that schematically shows a laser collecting condition in the cross section of the microlens shown in FIG. 22B.

FIG. 23B is an exemplary view that schematically shows a laser collecting condition in another cross section of the microlens shown in FIG. 22B.

FIG. 24A is an exemplary view that explains the concept of compensation by an optical system of optical quantity distribution compensation.

FIG. 24B is another exemplary view that explains the concept of compensation by an optical system of optical quantity distribution compensation.

FIG. 24C is another exemplary view that explains the concept of compensation by an optical system of optical quantity distribution compensation.

FIG. 25 is an exemplary graph that shows an optical quantity distribution of Gaussian distribution without compensation of optical quantity.

FIG. 26 is an exemplary graph that shows a compensated optical quantity distribution by an optical system of optical quantity distribution compensation.

FIG. 27A (A) is an exemplary perspective view that shows a constitution of a fiber array laser source.

FIG. 27A (B) is a partially enlarged view of FIG. 27A (A).

FIG. 27A (C) is an exemplary plan view that shows an arrangement of emitting sites of laser output.

FIG. 27A (D) is an exemplary plan view that shows another arrangement of laser emitting sites.

FIG. 27B is an exemplary front view that shows an arrangement of laser emitting sites in a fiber array laser source.

FIG. 28 is an exemplary view that shows a construction of a multimode optical fiber.

FIG. 29 is an exemplary plan view that shows a construction of a combined laser source.

FIG. 30 is an exemplary plan view that shows a construction of a laser module.

FIG. 31 is an exemplary side view that shows a construction of the laser module shown in FIG. 30.

FIG. 32 is a partial side view that shows a construction of the laser module shown in FIG. 30.

FIG. 33 is an exemplary perspective view that shows a construction of a laser array.

FIG. 34A is an exemplary perspective view that shows a construction of a multi cavity laser.

FIG. 34B is an exemplary perspective view that shows a multi cavity laser array in which the multi cavity lasers shown in FIG. 34A are arranged in an array.

FIG. 35 is an exemplary plan view that shows another construction of a combined laser source.

FIG. 36A is an exemplary plan view that shows still another construction of a combined laser source.

FIG. 36B is an exemplary cross section of FIG. 36A along the optical axis.

FIG. 37A is an exemplary cross section of an exposing device that shows focal depth in the pattern forming process of the prior art.

FIG. 37B is an exemplary cross section of an exposing device that shows focal depth in the pattern forming process according to the present invention.

FIG. 38A is a front view of another exemplary microlens that constitute a microlens array.

FIG. 38B is a side view of another exemplary microlens that constitute a microlens array.

FIG. 39A is a front view of still another exemplary microlens that constitute a microlens array.

FIG. 39B is a side view of still another exemplary microlens that constitute a microlens array.

FIG. 40 is an exemplary graph that shows a lens configuration.

FIG. 41 is an exemplary graph that shows another lens configuration.

FIG. 42 is an exemplary perspective view that shows a microlens array.

FIG. 43 is an exemplary plan view that shows another microlens array.

FIG. 44 is an exemplary plan view that shows still another microlens array.

FIG. 45A is an exemplary longitudinal section that shows still another microlens array.

FIG. 45B is an exemplary longitudinal section that shows still another microlens array.

FIG. 45C is an exemplary longitudinal section that shows still another microlens array.

### BEST MODE FOR CARRYING OUT THE INVENTION

### (Pattern Forming Process)

The pattern forming process of the present invention includes an exposing step for exposing a laminate of which a photosensitive layer made from a pattern forming material having at least the photosensitive layer is laminated on a substrate surface and further includes other steps suitably selected.

### [Exposing Step]

In the exposing step, a pattern forming process is provided that includes, after laminating a photosensitive layer in a pattern forming material, modulating a laser beam applied from a light irradiating unit having ‘n’ imaging portions receiving light from a light irradiating unit and outputting the light, and exposing the photosensitive layer with the laser beam through a microlens array in which microlenses each having a non-spherical surface capable of compensating the aberration due to distortion of the output surface of the imaging portions are arrayed or a microlens array in which microlenses each having a lens aperture shape that prevents light from the periphery of the imaging portions from entering the each of lenses, wherein two or more arbitrarily selected regions in the photosensitive layer are respectively irradiated with a light with a different amount of energy.

The method of varying the amount of light energy applied to the arbitrarily selected regions is not particularly limited and may be suitably selected in accordance with the intended use. Examples of the method include a method of controlling the total amount of supplied light energy by controlling the light irradiation time; a method of controlling the intensity of irradiation light by controlling the amount of current supplied to a light source; a method of controlling the amount of irradiation light energy by controlling the turn-on and turn-off of a light source; and a method of controlling the amount of light energy reaching an exposed surface by using a halftone mask or two masks each having a different amount of light transmission.

Examples of the method of controlling the amount of irradiation light energy by controlling the turn-on and turn-off of a light source include the method described in Japanese Patent Application Laid Open (JP-A) No. 2003-156853. In the method, an exposing apparatus has a first and a second light sources, a scanning part serving to scan a subject with light from the light sources, and a controlling part serving to control the turn-on and turn-off of the light sources independently, wherein different regions on a substrate surface are individually exposed with light of a different exposure dose by exposing a certain region of the substrate surface with both of the first and second light sources and exposing regions other than the certain region with only one of the light sources by means of a function that computing the position at which the first and second light sources should be turned on or turned off based on information on regions that the exposure dose should be changed.

The amount of light energy to be applied can be arbitrarily selected according to the thickness and the hardness required by a hardened layer to be formed. For example, when a printed circuit board having hole portions is used based on the optimum energy amount to form a hardened layer on the printed circuit board, it is preferred to set the amount of light energy to be applied for forming a tent layer which covers the hole portions to 1.1 times to 10 times the optimum energy amount.

The regions of which the exposure dose should be changed are not particularly limited and may be suitably selected in accordance with the intended use. For example, in the case of a printed circuit board having hole portions, regions completely corresponding to the hole portions may be exposed, or regions having a diameter of 1 μm to 100 μm greater than those of the hole portions within the limits of not affecting the interconnection part.

### —Light Modulating Unit—

The light modulating unit is not particularly limited and may be suitably selected in accordance with the intended use as long as it contains “n” imaging portions. Preferable examples of the light modulating unit include a spatial light modulator.

Specific examples of the spatial light modulator include a digital micromirror devices (DMDs), spatial light modulators of micro electro mechanical system type, PLZT elements or optical elements which modulate transmitted light by the effect of electrooptics, and liquid crystal shatters; among these, the DMDs are preferable.

The light modulating unit will be specifically explained with reference to figures in the following.

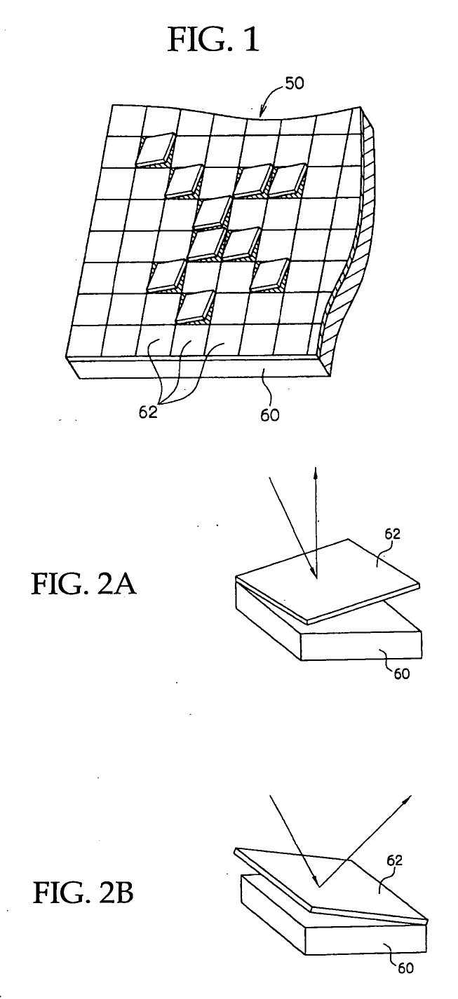

DMD 50 is a mirror device that has lattice arrays of many micromirrors 62, e.g. 1024×768, on SRAM cell or memory cell 60 as shown in FIG. 1, wherein each of the micromirrors serves as an imaging portion. At the upper most portion of the each imaging portion, micromirror 62 is supported by a pillar. A material having a higher reflectivity such as aluminum is vapor deposited on the surface of the micromirror. The reflectivity of the micromirrors 62 is 90% or more; the array pitches in longitudinal and width directions are respectively 13.7 μm, for example. Further, SRAM cell 60 of a silicon gate CMOS produced by conventional semiconductor memory production processes is disposed just below each micromirror 62 through a pillar containing a hinge and yoke. The mirror device is entirely constructed as a monolithic body.

When a digital signal is written into SRAM cell 60 of DMD 50, micromirror 62 supported by a pillar is inclined toward the substrate, on which DMD 50 is disposed, within ±alpha degrees e.g. 12 degrees around the diagonal as the rotating axis. FIG. 2A indicates the condition that micromirror 62 is inclined+alpha degrees at on state, FIG. 2B indicates the condition that micromirror 62 is inclined−alpha degrees at off state. Therefore, each incident laser beam B on DMD 50 is reflected depending on each inclined direction of micromirrors 62 by controlling each inclined angle of micromirrors 62 in imaging portions of DMD 50 depending on pattern information as shown in FIG. 1.

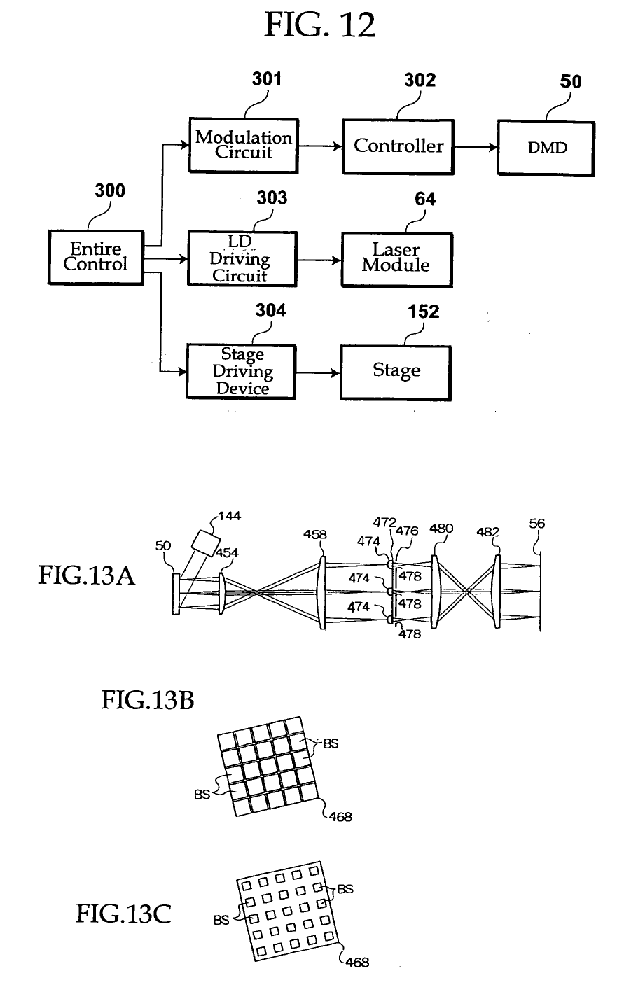

FIG. 1 exemplarily shows a magnified condition of DMD 50 partly in which micromirrors 62 are controlled at an angle of −alpha degrees or +alpha degrees. Controller 302 (see FIG. 12) connected to DMD 50 carries out on-off controls of the respective micromirrors 62. An optical absorber (not shown) is disposed on the way of laser beam B reflected by micromirrors 62 at off state.

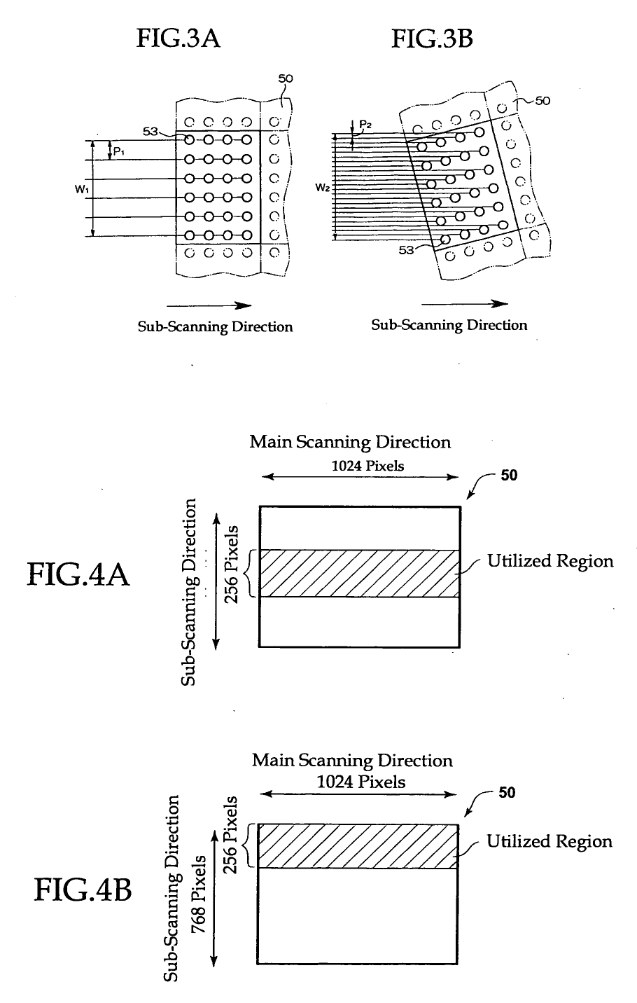

Preferably, DMD 50 is slightly inclined in the condition that the shorter side presents a pre-determined angle, e.g. 0.1 degrees to 5 degrees against the sub-scanning direction. FIG. 3A shows scanning traces of reflected laser image or exposing beam 53 by the respective micromirrors when DMD 50 is not inclined; FIG. 3B shows scanning traces of reflected laser image or exposing beam 53 by the respective micromirrors when DMD 50 is inclined.

In DMD 50, many micromirrors, e.g. 1024, are disposed in the longer direction to form one array, and many arrays, e.g. 756, are disposed in the shorter direction. Thus, by means of inclining DMD 50 as shown in FIG. 3B, the pitch P₁ of scanning traces or lines of exposing beam 53 from each micromirror may be reduced than the pitch P₂ of scanning traces or lines of exposing beam 53 without inclining DMD 50, thereby the resolution may be improved remarkably. On the other hand, the inclined angle of DMD 50 is small, therefore, the scanning direction W₂ when DMD 50 is inclined and the scanning direction W₁ when DMD 50 is not inclined are approximately the same.

The method to accelerate the modulation rate of the light modulating unit (hereinafter referring to as “high rate modulation”) will be explained in the following.

Preferably, the light modulating unit is able to control any imaging portions of less than “n” disposed successively among the imaging portions depending on the pattern information (“n”: an integer of 2 or more). Since there exist a limit in the data processing rate of the light modulating unit and the modulation rate per one line is defined in proportion to the utilized imaging portion number, the modulation rate per one line may be increased by utilizing only the imaging portions of less than “n” disposed successively.

The high rate modulation will be explained with reference to figures in the following.

When laser beam B is applied from fiber array laser source 66 to DMD 50, the reflected laser beam, at the micromirrors of DMD 50 being on state, is imaged on pattern forming material 150 by lens systems 54 and 58. In this way, the laser beam applied from the fiber array laser source is turned into on or off for each imaging portion, and the pattern forming material 150 is exposed in approximately the same number of imaging portion units or exposing areas 168 as the imaging portions utilized in DMD 50. In addition, when the pattern forming material 150 is conveyed with stage 152 at a constant rate, the pattern forming material 150 is sub-scanned to the direction opposite to the stage moving direction by scanner 162, thus exposed regions 170 of band shape are formed correspondingly to the respective exposing heads 166.

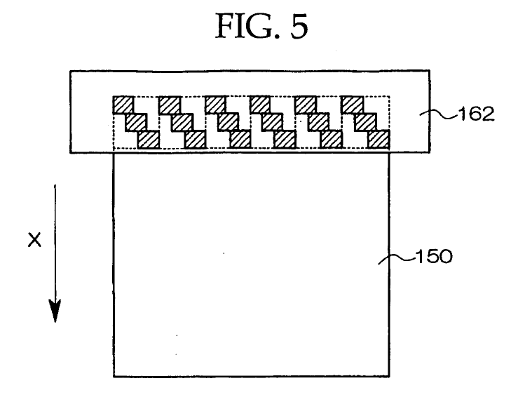

In this example, micromirrors are disposed on DMD 50 as 1,024 arrays in the main-scanning direction and 768 arrays in the sub-scanning direction as shown in FIGS. 4A and 4B. Among these micromirrors, a part of micromirrors, e.g. 1,024×256, may be controlled and driven by the controller 302 (see FIG. 12).

In such control, the micromirror arrays disposed at the central area of DMD 50 may be employed as shown in FIG. 4A; alternatively, the micromirror arrays disposed at the edge portion of DMD 50 may be employed as shown in FIG. 4B. In addition, when micromirrors are partly damaged, the utilized micromirrors may be properly altered depending on the situations such that micromirrors with no damage are utilized.

Since there exist a limit in the data processing rate of DMD 50 and the modulation rate per one line is defined in proportion to the utilized imaging portion number, partial utilization of micromirror arrays leads to higher modulation rate per one line. Further, when exposing is carried out by moving continuously the exposing head relative to the exposing surface, the entire imaging portions are not necessarily required in the sub-scanning direction.

When the sub-scanning of pattern forming material 150 is completed by scanner 162, and the rear end of the pattern forming material 150 is detected by sensor 164, the stage 152 returns to the original site at the most upstream of gate 160 along guide 158, and the stage 152 is moved again from upstream to downstream of the gate 160 along guide 158 at a constant rate.

For example, when 384 arrays are utilized among the 768 arrays of micromirrors, the modulation rate may be enhanced two times per one line as compared to the modulation rate when utilizing all of 768 arrays; further, when 256 arrays are utilized among the 768 arrays of micromirrors, the modulation rate may be enhanced three times as compared to the modulation rate when utilizing all of 768 arrays.

As explained above, when DMD 50 is provided with 1,024 micromirror arrays in the main-scanning direction and 768 micromirror arrays in the sub-scanning direction, controlling and driving of partial micromirror arrays may lead to higher modulation rate per one line compared to the modulation rate in the case of controlling and driving of entire micromirror arrays.

In addition to the controlling and driving of partial micromirror arrays, elongated DMD on which many micromirrors are disposed on a substrate in planar arrays may similarly increase the modulation rate when the each angle of reflected surface is changeable depending on the various controlling signals, and the substrate is longer in a specific direction than its perpendicular direction.

Preferably, the exposing is performed while moving relatively the exposing laser and the thermosensitive layer; more preferably, the exposing is combined with the high rate modulation described above, thereby exposing may be carried out with higher rate in a shorter period.

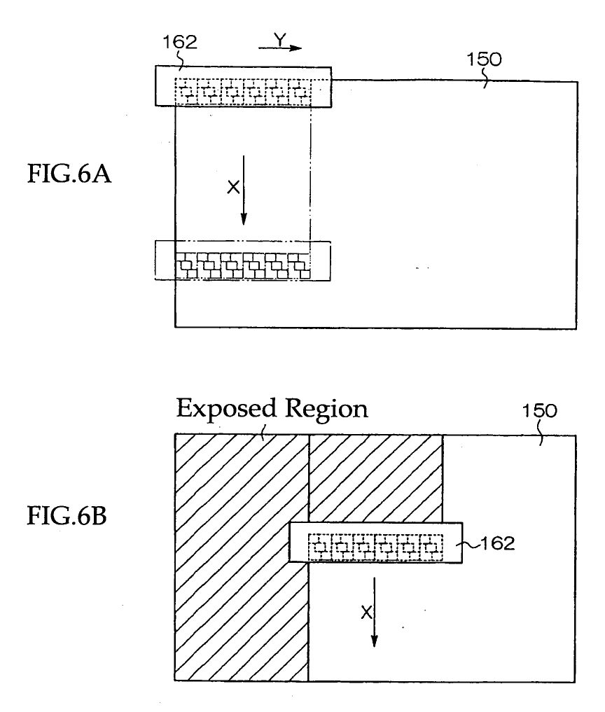

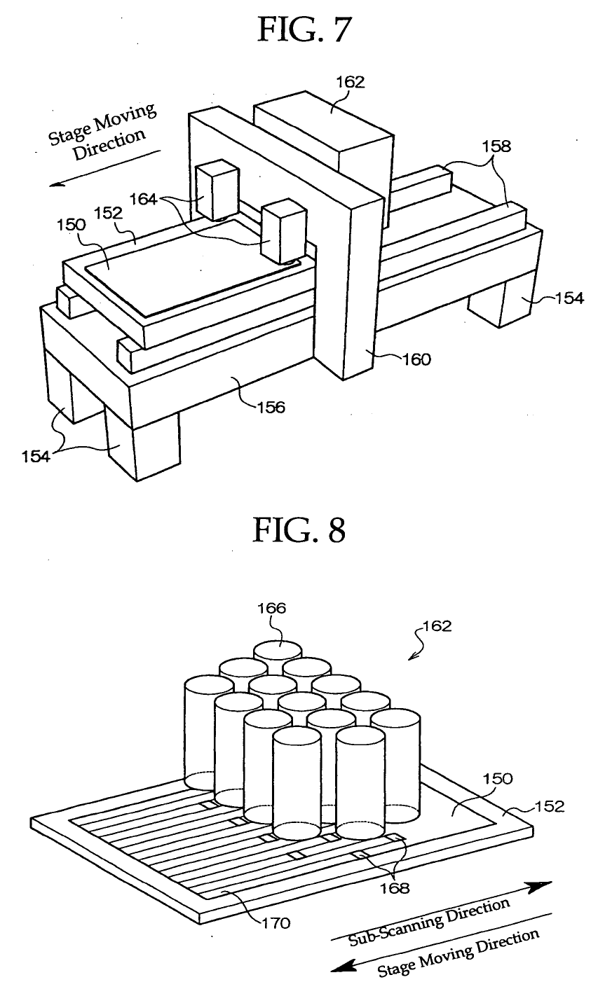

As shown in FIG. 5, pattern forming material 150 may be exposed on the entire surface by one scanning of scanner 162 in X direction; alternatively, as shown in FIGS. 6A and 6B, pattern forming material 150 may be exposed on the entire surface by repeated plural exposing such that pattern forming material 150 is scanned in X direction by scanner 162, then the scanner 162 is moved one step in Y direction, followed by scanning in X direction. In this example, scanner 162 is provided with eighteen exposing heads 166; each exposing head contains a laser source and the light modulating unit.

The exposure is performed on a partial region of the photosensitive layer, thereby the partial region is hardened, followed by un-hardened region other than the partial hardened region is removed in developing step as set forth later, thus a pattern is formed.

A pattern forming apparatus containing the light modulating unit will be exemplarily explained with reference to figures in the following.

The pattern forming apparatus containing the light modulating unit is equipped with flat stage 152 that absorbs and sustains sheet-like pattern forming material 150 on the surface.

On the upper surface of thick plate table 156 supported by four legs 154, two guides 158 are disposed that extend along the stage moving direction. Stage 152 is disposed such that the elongated direction faces the stage moving direction, and supported by guide 158 in reciprocally movable manner. A driving device is equipped with the pattern forming apparatus (not shown) so as to drive stage 152 along guide 158.

At the middle of the table 156, gate 160 is provided such that gate 160 strides the path of stage 152. The respective ends of the gate 160 are fixed to both sides of the table 156. Scanner 162 is provided at one side of gate 160, plural (e.g. two) detecting sensors 164 are provided at the opposite side of gate 160 in order to detect the front and rear ends of pattern forming material 150. Scanner 162 and detecting sensor 164 are mounted on gate 160 respectively and disposed stationarily above the path of stage 152. Scanner 162 and detecting sensor 164 are connected to a controller (not shown) that controls them.

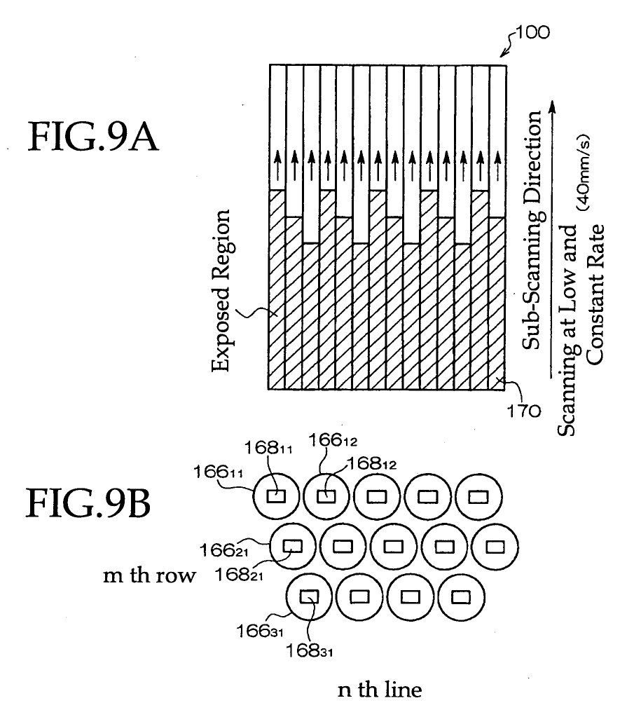

As shown in FIGS. 8 and 9B, scanner 162 contains plural (e.g. fourteen) exposing heads 166 that are arrayed in substantially matrix of “m rows×n lines” (e.g. three×five). In this example, four exposing heads 166 are disposed at the third line considering the width of pattern forming material 150. The specific exposing head at “m”th row and “n”th line is expressed as exposing head 166 hereinafter.

The exposing area 168 formed by exposing head 166 is rectangular having the shorter side in the sub-scanning direction. Therefore, exposed areas 170 are formed on pattern forming material 150 of a band shape that corresponds to the respective exposing heads 166 along with the movement of stage 152. The specific exposing area corresponding to the exposing head at “m”th row and “n”th line is expressed as exposing area 168ₘₙ hereinafter.

As shown in FIGS. 9A and 9B, each of the exposing heads at each line is disposed with a space in the line direction so that exposed regions 170 of band shape are arranged without space in the perpendicular direction to the sub-scanning direction (space: (longer side of exposing area)×natural number; two times in this example). Therefore, the non-exposing area between exposing areas 168₁₁ and 168₁₂ at the first raw can be exposed by exposing area 16821 of the second raw and exposing area 168₃₁ of the third raw.

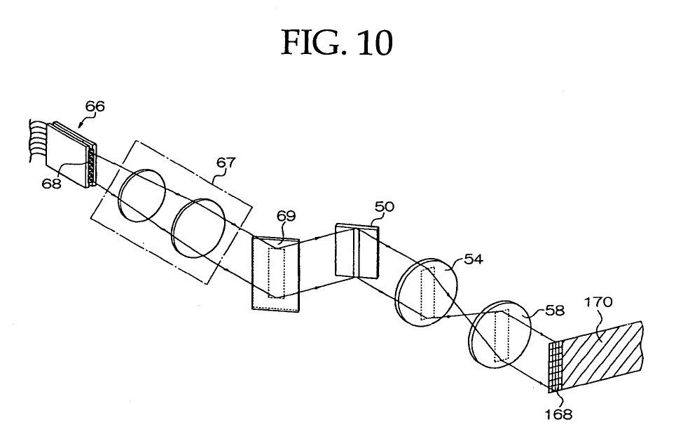

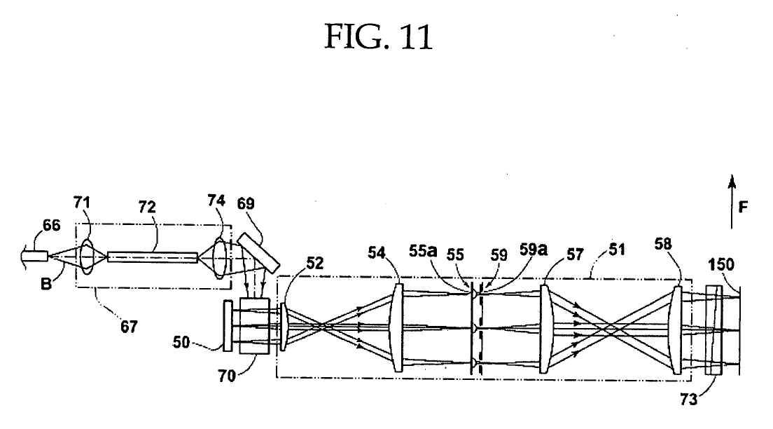

Each of exposing heads 166₁₁ to 166ₘₙ is provided with a digital micromirror device (DMD) 50 (manufactured by US Texas Instruments Inc.) as a light modulating unit or spatial light modulator that modulates the incident laser beam depending on the pattern information as shown in FIGS. 10 and 11. Each DMD 50 is connected to controller 302 that contains a data processing part and a mirror controlling part as shown in FIG. 12. The data processing part of controller 302 generates controlling signals to control and drive the respective micromirrors in the areas to be controlled for the respective exposing heads 166 based on the input pattern information. The area to be controlled will be explained later. The mirror driving-controlling part controls the reflective surface angle of each micromirror of DMD 50 per each exposing head 166 based on the control signals generated at the pattern information processing part. The control of the reflective surface angle will be explained later.

At the incident laser side of DMD 50, fiber array laser source 66 that is equipped with a laser irradiating part where irradiating ends or emitting sites of optical fibers are arranged in an array along the direction corresponding with the longer side of exposing area 168, lens system 67 that compensates the laser beam emitted from fiber array laser source 66 and collects it on the DMD, and mirrors 69 that reflect laser beam through lens system 67 toward DMD 50 are disposed in this order. FIG. 10 schematically shows lens system 67.

Lens system 67 is provided with collective lens 71 that collects laser beam B for illumination from fiber array laser source 66, rod-like optical integrator 72 (hereinafter, referring to as “rod integrator”) inserted on the optical path of the laser passed through collective lens 71, and image lens 74 disposed in front of rod integrator 72 or the side of mirror 69, as shown FIG. 11. Collective lens 71, rod integrator 72, and image lens 74 make the laser beam applied from fiber array laser source 66 enter into DMD 50 as a luminous flux of approximately parallel beam with uniform intensity in the cross section. The shape and effect of the rod integrator will be explained in detail later.

Laser beam B irradiated from lens system 67 is reflected by mirror 69, and is irradiated to DMD 50 through a total internal reflection prism 70 (not shown in FIG. 10).

At the reflecting side of DMD 50, imaging optical system 51 is disposed which images laser beam B reflected by DMD 50 onto pattern forming material 150. The imaging optical system 51 is equipped with the first imaging optical system of lens systems 52, 54, the second imaging optical system of lens systems 57, 58, and microlens array 55 and aperture array 59 interposed between these imaging systems as shown in FIG. 11.

Arranging two-dimensionally many microlenses 55a each corresponding to the respective imaging portions of DMD 50 forms microlens array 55. In this example, micromirrors of 1,024 rows×256 lines among 1,024 rows×768 lines of DMD 50 are driven, therefore, 1,024 rows×256 lines of microlenses are disposed correspondingly. The pitch of disposed microlenses 55a is 41 μm in both of raw and line directions. Microlenses 55a have a focal length of 0.19 mm and a numerical aperture (NA) of 0.11 for example, and are formed of optical glass BK7. The shape of microlenses will be explained later. The beam diameter of laser beam B is 41 μm at the site of microlens 55a.

Aperture array 59 is formed of many apertures 59a each corresponding to the respective microlenses 55a of microlens array 55. The diameter of aperture 59a is 10 μm, for example.

The first imaging system forms the image of DMD 50 on microlens array 55 as a three times magnified image. The second imaging system forms and projects the image through microlens array 55 on pattern forming material 150 as a 1.6 times magnified image. Therefore, the image by DMD 50 is formed and projected on pattern forming material 150 as a 4.8 times magnified image.

Prism pair 73 is installed between the second imaging system and pattern forming material 150; through the operation to move up and down the prism pair 73, the image pint may be adjusted on the image forming material 150. In FIG. 11, pattern forming material 150 is fed to the direction of arrow F as sub-scanning.

The imaging portions are not particularly limited and may be properly selected in accordance with the intended use, provided that the imaging portions can receive the laser beam from the laser source or irradiating unit and can output the laser beam; for example, the imaging portions are pixels when the pattern formed by the pattern forming process according to the present invention is an image pattern, alternatively the imaging portions are micromirrors when the light modulating unit contains a DMD.

The number of imaging portions contained in the light modulating unit may be properly selected in accordance with the intended use.

The alignment of imaging portions in the light modulating unit may be properly selected in accordance with the intended use; preferably, the imaging portions are arranged two dimensionally, more preferably are arranged into a lattice pattern.

### —Microlens Array—

The microlens array may be properly selected in accordance with the intended use, provided that microlenses have a non-spherical surface capable of compensating the aberration due to distortion or strain at irradiating surface of the imaging portion; for example, preferable ones are the microlens array that has a non-spherical surface capable of compensating the aberration due to distortion of the output surface of the imaging portions, and the microlens array that has an aperture configuration of the plural microlenses capable of substantially shielding incident light other than the modulated laser beam from the light modulating unit.

The non-spherical surface is not particularly limited and may be properly selected in accordance with the intended use; preferably, the non-spherical surface is a toric surface, for example.

The microlens array, aperture array, imaging system set forth above will be explained with reference to figures.

FIG. 13A shows an exposing head that is equipped with DMD 50, laser source 144 to irradiate laser beam onto DMD 50, lens systems or imaging optical systems 454 and 458 that magnify and image the laser beam reflected by DMD 50, microlens array 472 that arranges many microlenses 474 corresponding to the respective imaging portions of DMD 50, aperture array 476 that aligns many apertures 478 corresponding to the respective microlenses of microlens array 472, and lens systems or imaging systems 480 and 482 that image laser beam through the apertures onto exposed surface 56.

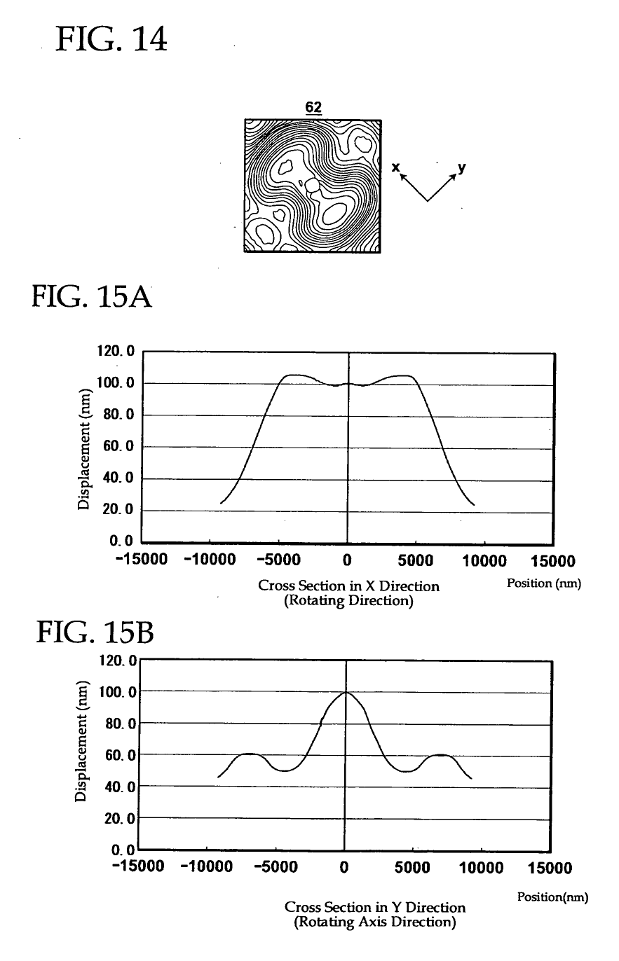

FIG. 14 shows the flatness data as to the reflective surface of micromirrors 62 of DMD 50. In FIG. 14, contour lines express the respective same heights of the reflective surface; the pitch of the contour lines is five nano meters. In FIG. 14, X direction and Y direction are two diagonal directions of micromirror 62, and the micromirror 62 rotates around the rotation axis extending in Y direction. FIGS. 15A and 15B show the height displacements of micromirrors 62 along the X and Y directions respectively.

As shown in FIGS. 14, 15A and 15B, there exist strains on the reflective surface of micromirror 62, the strains of one diagonal direction (Y direction) is larger than another diagonal direction (X direction) at the central region of the mirror in particular. Accordingly, a problem may arise in which the shape is distorted at the site that collects laser beam B by microlenses 55a of microlens array 55.

In order to prevent such a problem, microlenses 55a of microlens array 55 are of special shape that is different from the prior art as explained later.

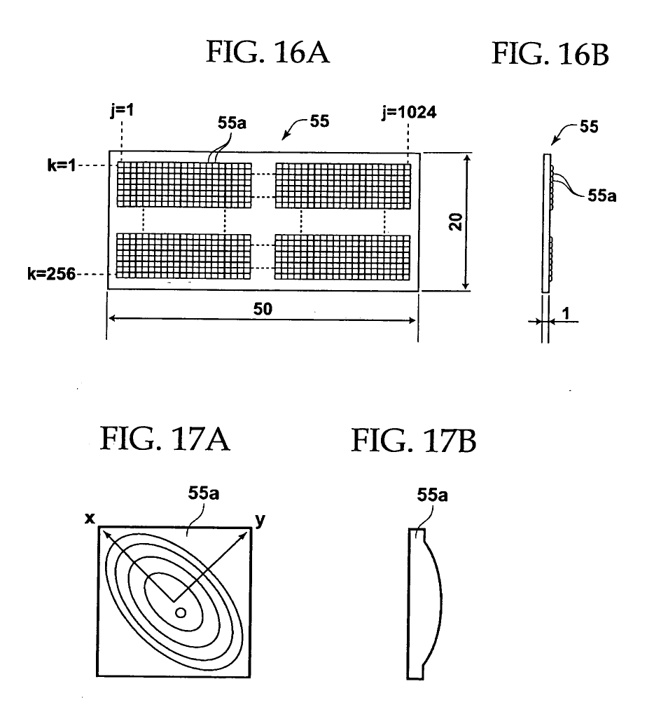

FIGS. 16A and 16B show the front shape and side shape of the entire microlens array 55 in detail. In FIGS. 16A and 16B, various parts of the microlens array are indicated as the unit of mm (millimeter). In the pattern forming process according to the present invention, micromirrors of 1,024 rows×256 lines of DMD 50 are driven as explained above; microlens arrays 55 are correspondingly constructed as 1,024 arrays in length direction and 256 arrays in width direction. In FIG. 16A, the site of each microlens is expressed as “j”th line and “k”th row.

FIGS. 17A and 17B respectively show the front shape and side shape of one microlens 55a of microlens array 55. FIG. 17A also shows the contour lines of microlens 55a. The end surface of each microlens 55a of irradiating side is of a non-spherical shape to compensate the strain aberration of reflective surface of micromirrors 62. Specifically, microlens 55a is a toric lens; the curvature radius of optical X direction Rx is −0.125 mm, and the curvature radius of optical Y direction Ry is −0.1 mm.

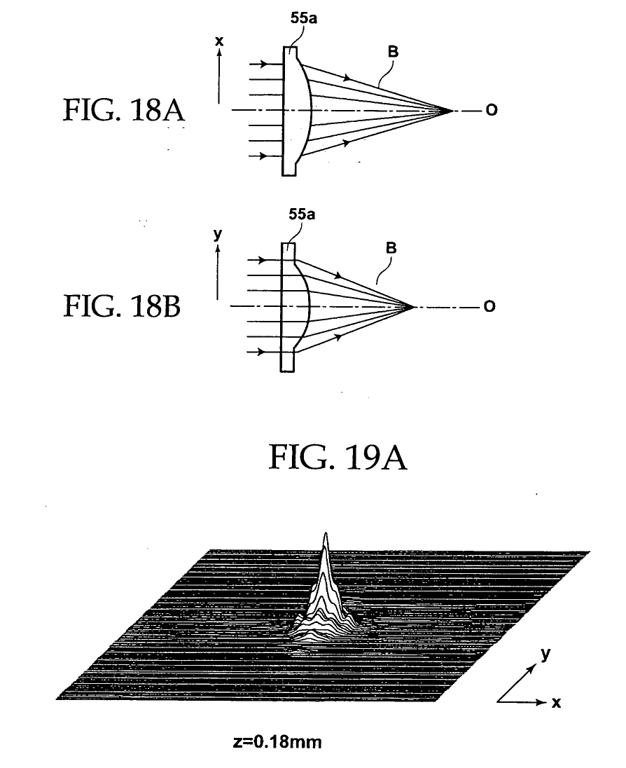

Accordingly, the collecting condition of laser beam B within the cross section parallel to the X and Y directions are approximately as shown in FIGS. 18A and 18B respectively. Namely, comparing the X and Y directions, the curvature radius of microlens 55a is shorter, and the focal length is also shorter in Y direction.

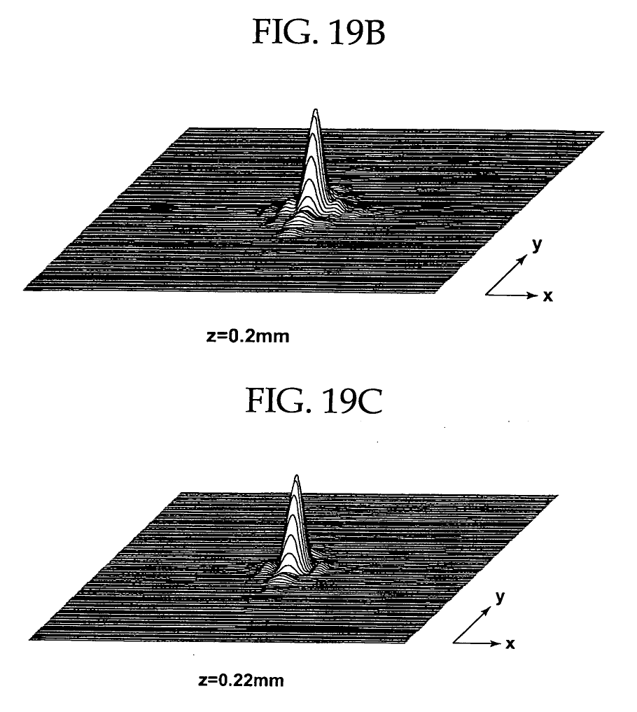

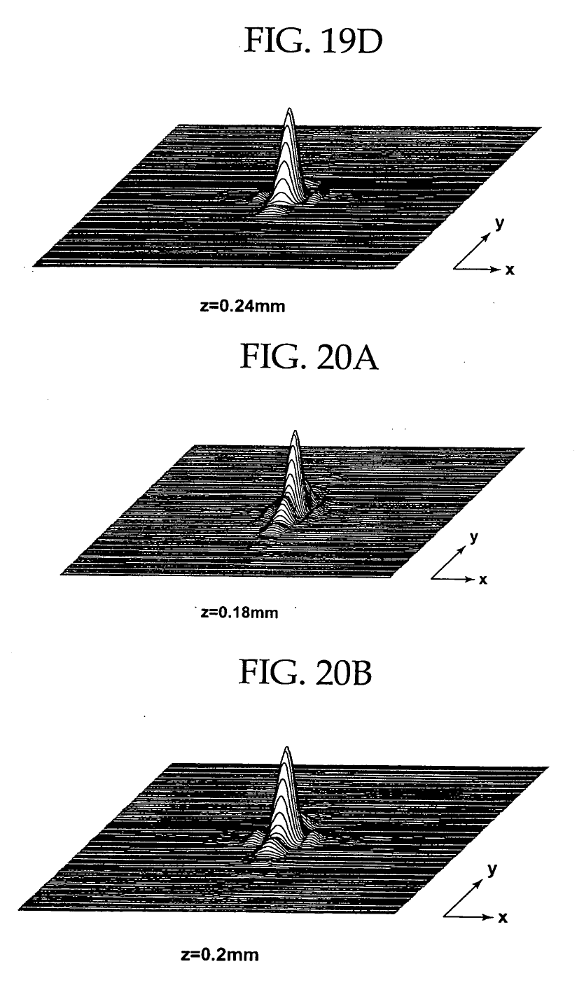

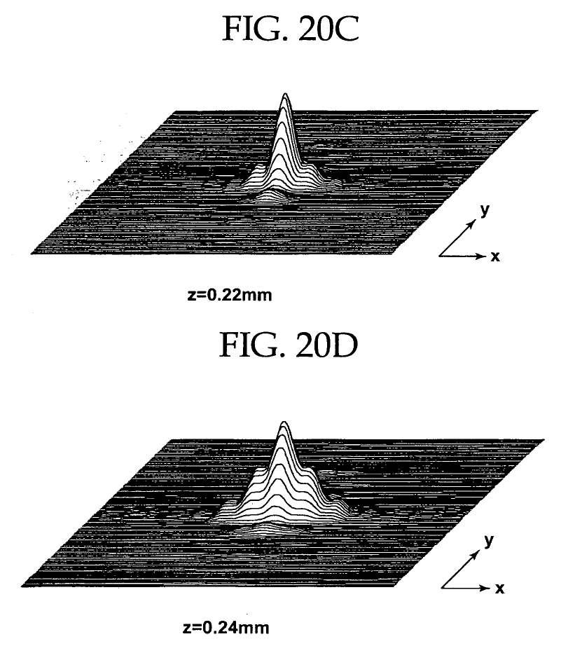

FIGS. 19A, 19B, 19C, and 19D show the simulations of beam diameter near the focal point of microlens 55a in the above noted shape by means of a computer. For the reference, FIGS. 20A, 20B; 20C, and 20D show the similar simulations for microlens in a spherical shape of Rx=Ry=−0.1 mm. The values of “z” in the figures are expressed as the evaluation sites in the focus direction of microlens 55a by the distance from the beam irradiating surface of microlens 55a.

The surface shape of microlens 55a in the simulation may be calculated by the following equation (1).

$$Z = \frac{{C}_{x}^{2} {X}^{2} + {C}_{y}^{2} {Y}^{2}}{1 + SQRT ( 1 - {C}_{x}^{2} {X}^{2} - {C}_{y}^{2} {Y}^{2} )}$$

In the above equation, Cx means the curvature (=1/Rx) in X direction, Cy means the curvature (=1/Ry) in Y direction, X means the distance from optical axis O in X direction, and Y means the distance from optical axis O in Y direction.

From the comparison of FIGS. 19A to 19D, and FIGS. 20A to 20D, it is apparent in the pattern forming process according to the present invention that the employment of the toric lens as the microlens 55a that has a shorter focal length in the cross section parallel to Y direction than the focal length in the cross section parallel to X direction may reduce the strain of the beam shape near the collecting site. Accordingly, images can be exposed on pattern forming material 150 with more clearness and without strain. In addition, it is apparent that the inventive mode shown in FIGS. 19A to 19D may bring about a wider region with smaller beam diameter, i.e. longer focal depth.

When the larger or smaller strain at the central region appears at the central region of micromirror 62 inversely with those set forth above, the employment of microlenses that has a shorter focal length in the cross section parallel to X direction than the focal length in the cross section parallel to Y direction may make possible to expose images on pattern forming material 150 with more clearness and without strain or distortion.

Aperture arrays 59 disposed near the collecting site of microlens array 55 are constructed such that each aperture 59a receives only the laser beam through the corresponding microlens 55a. Namely, aperture array 59 may afford the respective apertures with the insurance that the light incidence from the adjacent apertures 55a may be prevented and the extinction ratio may be enhanced.

Essentially, smaller diameter of apertures 59a provided for the above noted purpose may afford the effect to reduce the strain of beam shape at the collecting site of microlens 55a. However, such a construction inevitably increases the optical quantity interrupted by the aperture array 59, resulting in lower efficiency of optical quantity. On the contrary, the non-spherical shape of microlenses 55a does not bring about the light interruption, thus the higher efficiency of optical quantity can be maintained.

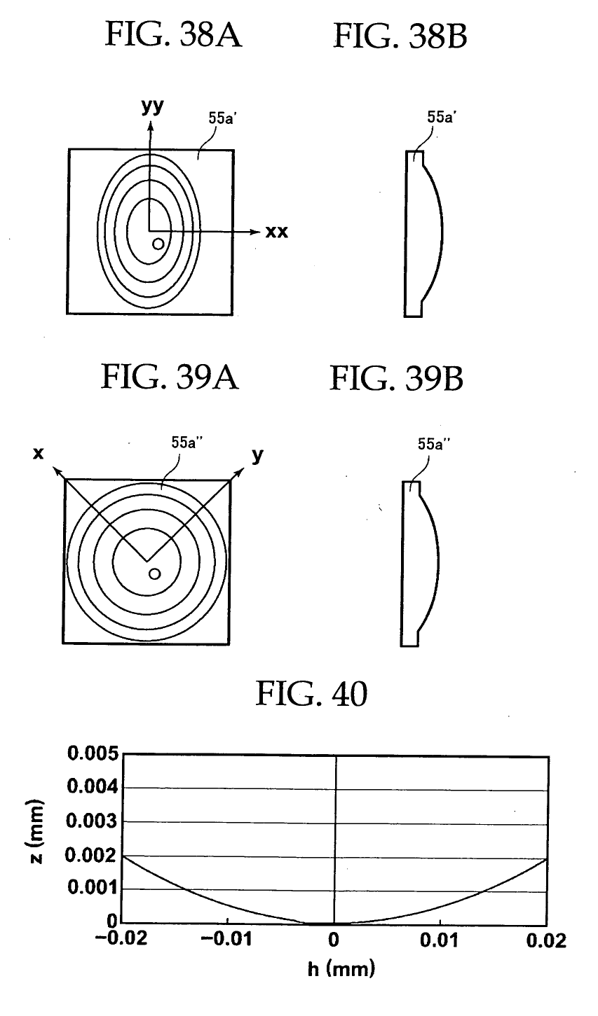

In the pattern forming process explained above, microlens 55a of toric lens is applied which has different curvature radiuses in X and Y directions that respectively correspond to two diagonal directions of micromirror 62; alternatively, another microlens 55a′ of toric lens may be applied which has different curvature radiuses in XX and YY directions that respectively correspond to two side directions of rectangular micromirror 62, as shown in FIGS. 38A and 38B that exhibit the front and side shapes with contour lines.

In the pattern forming process according to the present invention, the microlenses 55a may be non-spherical shape of secondary or higher order such as fourth or sixth. The employment of higher order non-spherical surface may lead to higher accuracy of beam shape. In addition, such lens configuration is available that has the same curvature radiuses in X and Y directions corresponding to the distortion of reflective surface of micromirrors 62. Such lens configuration will be discussed in detail.

The microlens 55a″, of which the front shape and the side shape are shown in FIGS. 39A and 39B respectively, has the same curvature radiuses in X and Y directions, and the curvature radiuses are designed such that the curvature Cy of spherical lens is compensated depending on the distance ‘h’ from the lens center. Namely, the configuration of spherical lens of microlens 55a″ is designed in terms of lens height ‘z’ (height of curved lens surface in optical axis direction) based on the following equation (2), for example.

$$Z = \frac{{C}_{y} {h}^{2}}{1 + SQRT ( 1 - {C}_{y}^{2} {h}^{2} )}$$

The relation between the lens height ‘z’ and the distance ‘h’ is expressed in FIG. 40 in the case that the curvature Cy=1/0.1 mm.

Then, the curvature radius of the spherical lens is compensated depending on the distance ‘h’ from the lens center based on the following equation (3), thereby the lens configuration of microlens 55a″ is designed.

$$Z = \frac{{C}_{y}^{2} {h}^{2}}{1 + SQRT ( 1 - {C}_{y}^{2} {h}^{2} )} + {ah}^{4} + {bh}^{6}$$

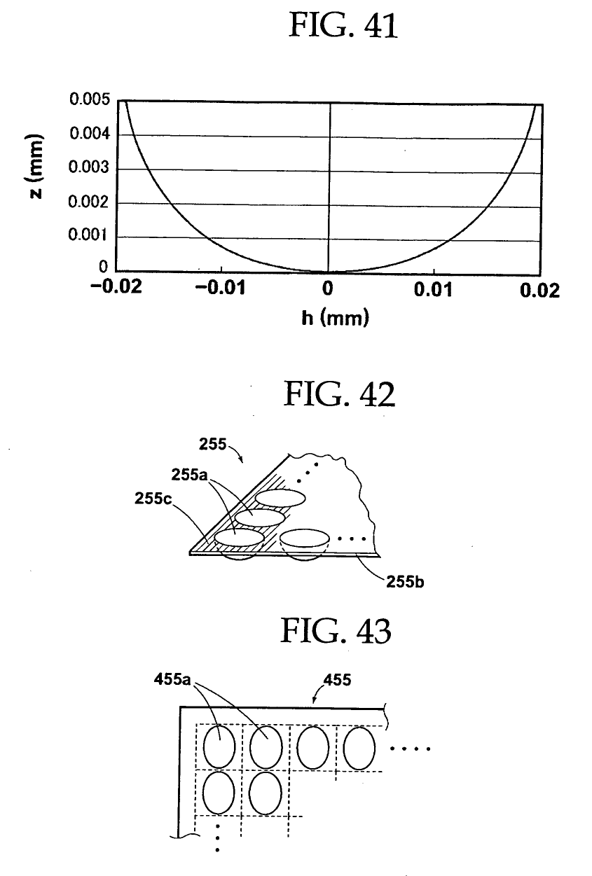

In equations (2) and (3), the respective Z mean the same concept; in equation (3), the curvature Cy is compensated using the fourth coefficient ‘a’ and sixth coefficient ‘b’. The relation between the lens height ‘z’ and the distance ‘h’ is expressed in FIG. 41 in the case that the curvature Cy=1/0.1 mm, the fourth coefficient ‘a’=1.2×10³, and the sixth coefficient ‘b’=5.5×10⁷.

In the mode set forth above, the end surface of irradiating side of microlens 55a is non-spherical or toric; alternatively, substantially the same effect may be derived by constructing one of the end surface as a spherical surface and the other surface as a cylindrical surface and thus providing the microlens.

Further, in the mode set forth above, each microlens 55a of microlens array 55 is non-spherical so as to compensate the aberration due to the strain of reflective surface of micromirror 62; alternatively, substantially the same effect may be derived by providing each microlens of the microlens array with the distribution of refractive index so as to compensate the aberration due to the strain of reflective surface of micromirror 62.

FIGS. 22A and 22B show exemplarily such a microlens 155a. FIGS. 22A and 22B respectively show the front shape and side shape of microlens 155a. The entire shape of microlens 155a is a planar plate as shown in FIGS. 22A and 22B. The X and Y directions in FIGS. 22A and 22B mean the same as set forth above.

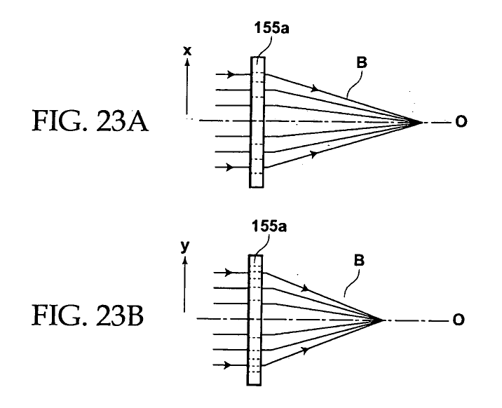

FIGS. 23A and 23B schematically show the condition to collect laser beam B by microlens 155a in the cross section parallel with X and Y directions respectively. The microlens 155a exhibits a refractive index distribution that the refractive index gradually increases from the optical axis O to outward direction; the broken lines in FIGS. 23A and 23B indicate the positions where the refractive index decreases a certain level from that of optical axis O. As shown in FIGS. 23A and 23B, comparing the cross section parallel to the X direction and the cross section parallel to the Y direction, the latter represents a rapid change in the refractive index distribution, and shorter focal length. Thus, the microlens array having such a refractive index distribution may provide the similar effect as the microlens array 55 set forth above.

In addition, the microlens having a non-spherical surface as shown in FIGS. 17A, 17B, 18A and 18B may be provided with such a refractive index distribution, and both of the surface shape and the refractive index distribution may compensate the aberration due to strain or distortion of the reflective surface of micromirror 62.

Another microlens array will be exemplarily discussed with reference to figures.

The exemplary microlens array has an aperture configuration of the plural microlenses capable of substantially shielding incident light other than the modulated laser beam from the light modulating unit, as shown in FIG. 42.

As discussed before with reference to FIGS. 14 and 15A and 15B, distortions exist on the reflective surface of micromirror 62 in DMD 50, and the distortion level tends to gradually increase from the central portion toward the peripheral portions of micromirror 62. Further, the distortion level at the peripheral portions is larger in one diagonal direction e.g. Y direction of micromirror 62 compared to in the other diagonal direction e.g. X direction, and the tendency explained above is more significant in Y direction.

The exemplary microlens array is prepared to address such problems. Each of the microlens 255a of the microlens array 255 has a circular aperture shape; therefore, the laser beam reflected or transmitted at the periphery portions of the micromirror 62 where the distortion level is relatively large, particularly the laser beam B reflected at the four corners cannot be collected by microlens 255a, thus the distortion of laser beam B may be prevented at the collecting site. Accordingly, highly fine and precise images may be exposed on pattern forming material with reducing distortions.

Additionally, in the microlens array 255, shielding mask 255c is prepared at the back side of transparent members 255b, which are usually formed monolithically with microlenses 255a, that sustains microlenses 255a; namely shielding mask 255c is provided such that outer regions of plural microlens apertures are covered at the opposite side of the plural microlenses 255a as shown in FIG. 42. The shielding mask 255c can surely reduce the distortion of collected laser beam B, since the laser beam reflected or transmitted at the periphery portions of the micromirror 62, particularly the laser beam B reflected at the four corners is absorbed or interrupted by the shielding mask 255c.

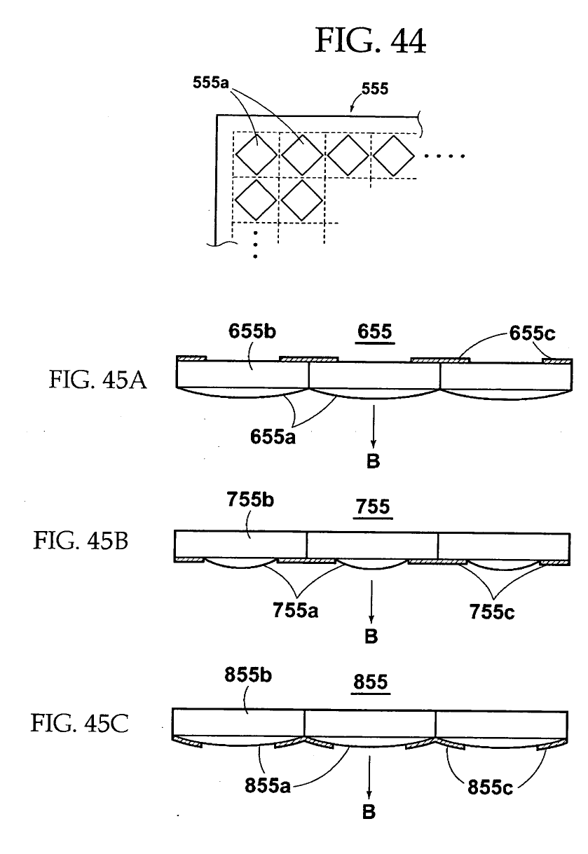

The aperture configuration of the microlens is not limited to circular in the microlens array 255, but other aperture configurations are applicable as microlens 455a with elliptic aperture configuration shown in FIG. 43, microlens 555a with polygonal aperture configuration e.g. rectangular in FIG. 44, and the like.

Microlenses 455a or 555a is of the configuration that a symmetrical lens is cut into circular or polygonal shape, thus microlenses 455a or 555a may exhibit light-collecting performance similarly to conventional symmetrical spherical lenses.

Additionally, the aperture configurations shown in FIGS. 45A, 45B, and 45C are applicable in the present invention. Microlens array 655 shown in FIG. 45A is constructed such that plural microlenses 655a are disposed adjacently at the side of transparent member 655b from where laser beam B outputs, and mask 655c is disposed at the side of transparent member 655b to where laser beam inputs. Mask 255c is provided at the outer region of the lens aperture in FIG. 42, whereas mask 655c is provided at the inner region of the lens aperture in FIG. 45A. Microlens array 755 shown in FIG. 45B is constructed such that plural microlenses 755a are disposed adjacently at the side of transparent member 755b from where laser beam B outputs, and mask 755c is disposed between the microlenses 755a. Microlens array 855 shown in FIG. 45C is constructed such that plural microlenses 855a are disposed adjacently at the side of transparent member 855b from where laser beam B outputs, and mask 855c is disposed at the peripheral portion of each microlens 855a.

All of the exemplary masks 655c, 755c, and 855c have a circular aperture similarly to mask 255c, thereby the aperture of each microlens is defined to be circular.

The aperture configuration of plural microlenses, wherein the mask substantially shields incident light other than from micromirrors 62 of DMD 50 as shown in microlenses 255a, 455a, 555a, 655a, and 755a, may be combined with non-spherical lenses capable of compensating the aberration due to distortion of micromirror 62 as microlens 55a shown in FIGS. 17A and 17B, or lenses having a refractive index distribution capable of compensating the aberration as shown in FIGS. 22A and 22B; thereby the effect to prevent distortion of exposed images due to distortion of reflective surface of micromirror 62 may be enhanced synergistically.

Particularly, in the construction that mask 855c is provided on the lens surface of microlens 855a as shown in FIG. 45C, when microlens 855a have a non-spherical surface or a refractive index distribution and also the imaging site of the first imaging system is determined at the lens surface of microlens 855a as lens systems 52 and 54 shown in FIG. 11, the optical efficiency may be higher in particular, thus pattern forming material 150 may be exposed with more intense laser beam. Namely, although the laser beam is refracted such that the stray light due to the reflective surface of micromirror 62 focuses at the imaging site by action of the first imaging system, mask 855c provided at appropriate site does not shield light other than the stray light, thereby the optical efficiency may be enhanced remarkably.

In the respective microlens array set forth above, the aberration due to strain of reflective surface of micromirror 62 in DMD 50 is compensated; similarly, in the pattern forming process according to the present invention that employs a spatial light modulator other than DMD, the possible aberration due to strain may be compensated and the strain of beam shape may be prevented when the strain appears at the surface of imaging portion of the spatial light modulator.

The imaging optical system set forth above will be explained in the following.

In the exposing head, when laser beam is applied from the laser source 144, the cross section of luminous flux reflected to on-direction by DMD 50 is magnified several times, e.g. two times, by lens systems 454, 458. The magnified laser beam is collected by each microlens of microlens array 472 correspondingly with each imaging portion of DMD 50, then passes through the corresponding apertures of aperture array 476. The laser beam passed through the aperture is imaged on exposed surface 56 by lens systems 480 and 482.

In the imaging optical system, the laser beam reflected by DMD 50 is magnified into several times by magnifying lenses 454, 458, and is projected onto exposed surface 56, therefore, the entire image region is enlarged. When microlens array 472 and aperture array 476 are not disposed, one drawing size or spot size of each beam spot BS projected on exposed surface 56 is enlarged depending on the size of exposed area 468, thus MTF (modulation transfer function) property that is a measure of sharpness at exposing area 468 is decreased, as shown in FIG. 13B.

On the other hand, when microlens array 472 and aperture array 476 are disposed, the laser beam reflected by DMD 50 is collected correspondingly with each imaging portion of DMD 50 by each microlens of microlens array 472. Thereby, the spot size of each beam spot BS may be reduced into the desired size, e.g. 10 μm×10 μm even when the exposing area is magnified, as shown in FIG. 13C, and the decrease of MFT property may be prevented and the exposure may be carried out with higher accuracy. Inclination of exposing area 468 is caused by the DMD 50 that is disposed with inclination in order to eliminate the spaces between imaging portions.

Further, even when beam thickening exists due to aberration of microlenses, the beam shape may be arranged by the aperture array so as to form spots on exposed surface 56 with a constant size, and interference or cross talk between the adjacent imaging portions may be prevented by passing the beam through the aperture array provided correspondingly to each imaging portion.

In addition, employment of higher luminance laser source as laser source 144 may lead to prevention of partial entrance of luminous flux from adjacent imaging portions, since the angle of incident luminous flux that enters into each microlens of microlens array 472 from lens 458 is narrowed; namely, higher extinction ratio may be achieved.

### —Other Optical System—

In the pattern forming process according to the present invention, the other optical system suitably selected from among conventional optical systems may be combined, for example, an optical system to compensate the optical quantity distribution may be employed additionally.

The optical system to compensate the optical quantity distribution alters the luminous flux width at each output site such that the ratio of the luminous flux width at the periphery region to the luminous flux width at the central region near the optical axis is higher in the output side than the input side, thus the optical quantity distribution at the exposed surface is compensated to be approximately constant when the parallel luminous flux from the light irradiating unit is irradiated to DMD. The optical system to compensate the optical quantity distribution will be explained with reference to figures in the following.

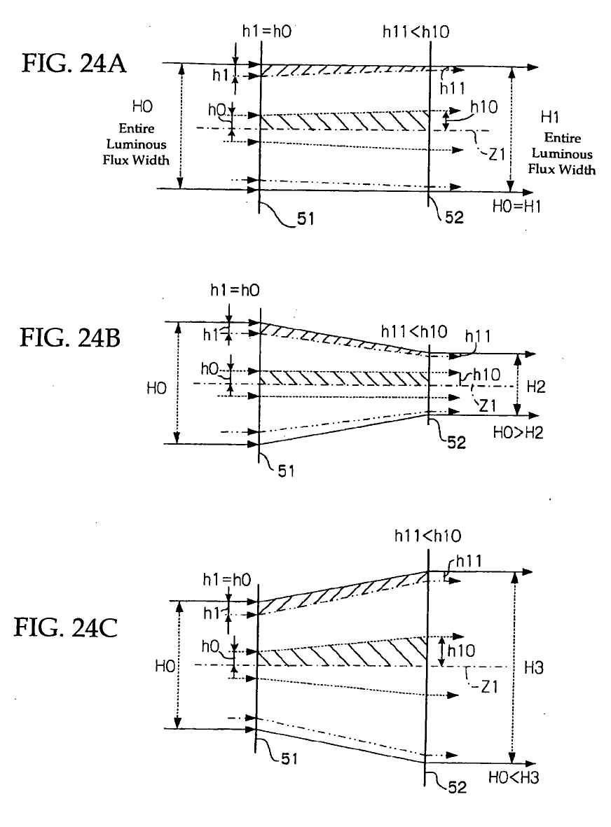

Initially, the optical system will be explained as for the case where the entire luminous flux widths H0 and H1 are the same between the input luminous flux and the output luminous flux, as shown in FIG. 24A. The portions denoted by reference numbers 51, 52 in FIG. 24A indicate imaginarily the input surface and output surface of the optical system to compensate the optical quantity distribution.

In the optical system to compensate the optical quantity distribution, it is assumed that the luminous flux width h0 of the luminous flux entered at central region near the optical axis Z1 and luminous flux width h1 of the luminous flux entered at peripheral region near are the same (h0=h1). The optical system to compensate the optical quantity distribution affects the laser beam that has the same luminous fluxes h0, h1 at the input side, and acts to magnify the luminous flux width h0 for the input luminous flux at the central region, and acts to reduce the luminous flux width h1 for the input luminous flux at the periphery region conversely. Namely, the optical system affects the output luminous flux width h10 at the central region and the output luminous flux width hill at the periphery region to turn into h11<h10. In other words concerning the ratio of luminous flux width, (output luminous flux width at periphery region)/(output luminous flux width at central region) is smaller than the ratio of input, namely [h11/h10] is smaller than (h1/h0=1) or (h11/h10<1).

Owing to alternation of the luminous flux width, the luminous flux at the central region representing higher optical quantity may be supplied to the periphery region where the optical quantity is insufficient; thereby the optical quantity distribution is approximately uniformed at the exposed surface without decreasing the utilization efficiency. The level for uniformity is controlled such that the nonuniformity of optical quantity is 30% or less in the effective region for example, preferably is 20% or less.

When the luminous flux width is entirely altered for the input side and the output side, the operation and effect due to the optical system to compensate the optical quantity distribution are similar to those shown in FIGS. 24A, 24B, and 24C.

FIG. 24B shows the case that the entire optical flux bundle H0 is reduced and outputted as optical flux bundle H2 (H0>H2). In such a case, the optical system to compensate the optical quantity distribution also tends to process the laser beam, in which luminous flux width h0 is the same as h1 at input side, into that the luminous flux width h10 at the central region is larger than that of the periphery region and the luminous flux width hill is smaller than that of the central region in the output side. Considering the reduction ratio of the luminous flux, the optical system affects to decrease the reduction ratio of input luminous flux at the central region compared to the peripheral region, and affects to increase the reduction ratio of input luminous flux at the peripheral region compared to the central region. In the case, (output luminous flux width at periphery region)/(output luminous flux width at central region) is also smaller than the ratio of input, namely [H11/H10] is smaller than (h1/h0=1) or (h11/h10<1).

FIG. 24C explains the case where the entire luminous flux width H0 at input side is magnified and output into width H3 (H0<H3). In such a case, the optical system to compensate the optical quantity distribution also tends to process the laser beam, in which luminous flux width h0 is the same as h1 at input side, into that the luminous flux width h10 at the central region is larger than that of the periphery region and the luminous flux width hill is smaller than that of the central region in the output side. Considering the magnification ratio of the luminous flux, the optical system acts to increase the magnification ratio of input luminous flux at the central region compared to the peripheral region, and acts to decrease the magnification ratio of input luminous flux at the peripheral region compared to that at the central region. In the case, (output luminous flux width at periphery region)/(output luminous flux width at central region) is also smaller than the ratio of input, namely [H11/H11] is smaller than (h1/h0=1) or (h11/h10<1).

As such, the optical system to compensate the optical quantity distribution alters the luminous flux width at each output site, and lowers the ratio (output luminous flux width at periphery region)/(output luminous flux width at central region) at output side compared to the input side; therefore, the laser beam having the same luminous flux turns into the laser beam at output side that the luminous flux width at central region is larger than that at the peripheral region and the luminous flux at the peripheral region is smaller than that at the central region. Owing to such effect, the luminous flux at the central region may be supplied to the periphery region, thereby the optical quantity distribution is approximately uniformed at the luminous flux cross section without decreasing the utilization efficiency of the entire optical system.

Next, specific lens data of a pair of combined lenses to be utilized for the optical system to compensate the optical quantity distribution will be exemplarily set forth. In this discussion, the lens data will be explained in the case that the optical quantity distribution shows Gaussian distribution at the cross section of the output luminous flux, such as the case that the laser source is a laser array as set forth above. In a case that one semiconductor laser is connected to an input end of single mode optical fiber, the optical quantity distribution of output luminous flux from the optical fiber shows Gaussian distribution. The pattern forming process according to the present invention may be applied, in addition, to such a case that the optical quantity near the central region is significantly larger than the optical quantity at the peripheral region as in the case where the core diameter of multimode optical fiber is reduced and constructed similarly to a single mode optical fiber, for example.

The essential data for the lens are summarized in Table 1 below.

TABLE 1
Basic Lens Data

| Si | ri | di | Ni |
|---|---|---|---|
| (surface No.) | (curvature radius) | (surface distance) | (refractive index) |
| 01 | non-spherical | 5.000 | 1.52811 |
| 02 | ∞ | 50.000 | |
| 03 | ∞ | 7.000 | 1.52811 |
| 04 | non-spherical | | |

As demonstrated in Table 1, a pair of combined lenses is constructed from two non-spherical lenses of rotational symmetry. The surfaces of the lenses are defined that the surface of input side of the first lens disposed at the light input side is the first surface; the opposite surface at light output side is the second surface; the surface of input side of the second lens disposed at the light input side is the third surface; and the opposite surface at light output side is the fourth surface. The first and the fourth surfaces are non-spherical.

In Table 1, ‘Si (surface No.)’ indicates “i”th surface (i=1 to 4), ‘ri (curvature radius)’ indicates the curvature radius of the “i”th surface, di (surface distance) means the surface distance between “i”th surface and “i+1” surface. The unit of di (surface distance) is millimeter (mm). Ni (refractive index) means the refractive index of the optical element containing “i”th surface for the light of wavelength 405 nm.

In Table 2 below, the non-spherical data of the first and the fourth surface is summarized.

TABLE 2
non-spherical data

| | first surface | fourth surface |
|---|---|---|
| C | −1.4098 × 10⁻² | −9.8506 × 10⁻³ |
| K | −4.2192 | −3.6253 × 10 |
| a3 | −1.0027 × 10⁻⁴ | −8.9980 × 10⁻⁵ |
| a4 | 3.0591 × 10⁻⁵ | 2.3060 × 10⁻⁵ |
| a5 | −4.5115 × 10⁻⁷ | −2.2860 × 10⁻⁶ |
| a6 | −8.2819 × 10⁻⁹ | 8.7661 × 10⁻⁸ |
| a7 | 4.1020 × 10⁻¹² | 4.4028 × 10⁻¹⁰ |
| a8 | 1.2231 × 10⁻¹³ | 1.3624 × 10⁻¹² |
| a9 | 5.3753 × 10⁻¹⁶ | 3.3965 × 10⁻¹⁵ |
| a10 | 1.6315 × 10⁻¹⁸ | 7.4823 × 10⁻¹⁸ |

The non-spherical data set forth above may be expressed by means of the coefficients of the following equation (A) that represent the non-spherical shape.

$$Z = \frac{C \cdot {ρ}^{2}}{1 + \sqrt{1 - K \cdot {( C \cdot ρ )}^{2}}} + {\sum }_{i = 3}^{10} ai \cdot {ρ}^{i} \qquad ( A )$$

In the above formula (A), the coefficients are defined as follows:
Z: length of perpendicular that extends from a point on non-spherical surface at height p from optical axis (mm) to tangent plane at vertex of non-spherical surface or plane vertical to optical axis;
ρ: distance from optical axis (mm);
K: coefficient for circular conic;
C: paraxial curvature (1/r, r: radius of paraxial curvature);
ai: “i” st non-spherical coefficient (i=3 to 10).

For example, “1.0E-02” means “1.0×10⁻²”.

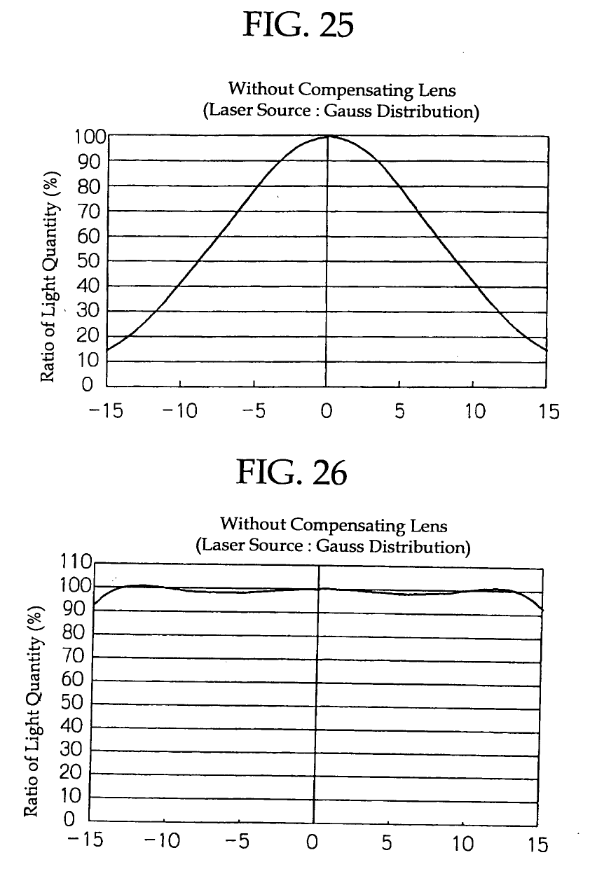

FIG. 26 shows the optical quantity distribution of illumination light obtained by a pair of combined lenses shown in Table 1 and Table 2. The abscissa axis represents the distance from the optical axis, the ordinate axis represents the proportion of optical quantity (%). FIG. 25 shows the optical quantity distribution (Gaussian distribution) of illumination light without the compensation. As is apparent from FIGS. 25 and 26, the compensation by means of the optical system to compensate the optical quantity distribution brings about an approximately uniform optical quantity distribution significantly exceeding the optical quantity distribution obtained without the compensation, thus uniform exposing may be achieved by means of uniform laser beam without decreasing the optical utilization efficiency.

### —Light Irradiating Unit—

The light irradiating unit may be properly selected in accordance with the intended use; examples thereof include an extremely high pressure mercury lamp, xenon lamp, carbon arc lamp, halogen lamp, fluorescent tube, LED, semiconductor laser, and the other conventional laser source, and also combination of these units. Among these units, a unit capable of irradiating two or more types of light or laser beam is preferable.

Examples of the light or laser beam applied from the optical irradiating unit include electromagnetic rays, UV-rays, visible light, electron beam, X-ray, laser beam, each of which penetrates the substrate and activates photopolymerization initiators and sensitizers to be used. Among these, laser beam is preferable, and those containing two or more types of light (hereinafter, sometimes referring to as “combined laser”) are more preferable. When the support is first exfoliated from the photosensitive layer and then is irradiated with light or laser beam similarly to the above can be also used.

The wavelength of the UV-rays and the visual light is preferably 300 nm to 1500 nm, more preferably 320 nm to 800 nm, and most preferably 330 nm to 650 nm.

The wavelength of the laser beam is preferably 200 nm to 1,500 nm, more preferably 300 nm to 800 nm, still more preferably 330 nm to 500 nm, and most preferably 400 nm to 450 nm.

As for the unit to irradiate the combined laser, such a unit is preferably exemplified that contains plural laser irradiating devices, a multimode optical fiber, and a collecting optical system that collects respective laser beams and connect them to a multimode optical fiber.

The unit to irradiate combined laser or the fiber array laser source will be explained with reference to figures in the following.

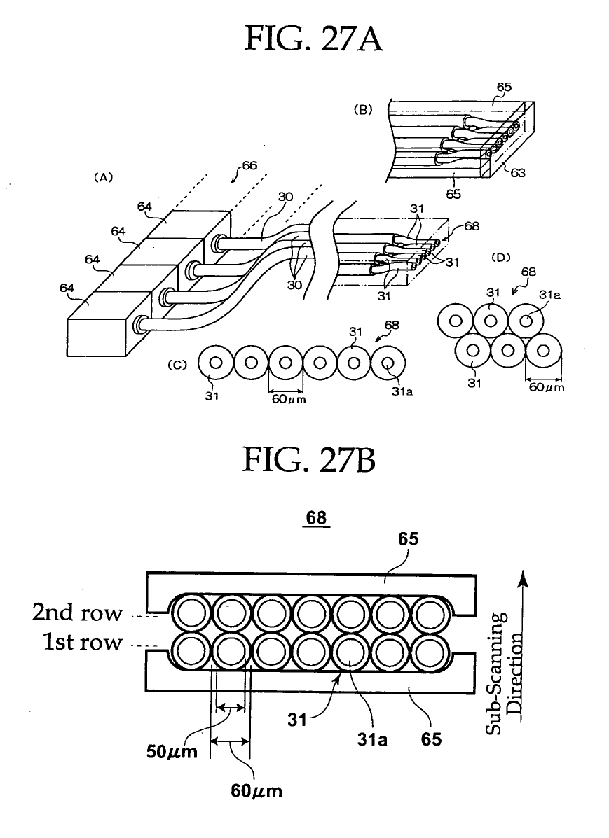

Fiber array laser source 66 is equipped with plural (e.g. fourteen) laser modules 64 as shown in FIG. 27A. One end of each multimode optical fiber 30 is connected to each laser module 64. The other end of each multimode optical fiber 30 is connected to optical fiber 31 of which the core diameter is the same as that of multimode optical fiber 30 and of which the clad diameter is smaller than that of multimode optical fiber 30. As shown in FIG. 27B specifically, the ends of multimode optical fibers 31 at the opposite end of multimode optical fiber 30 are aligned as seven ends along the main scanning direction perpendicular to the sub-scanning direction, and the seven ends are aligned as two rows, thereby laser output portion 68 is constructed.

The laser output portion 68, formed of the ends of multimode optical fibers 31, is fixed by being interposed between two flat support plates 65 as shown in FIG. 27B. Preferably, a transparent protective plate such as a glass plate is disposed on the output end surface of multimode optical fibers 31 in order to protect the output end surface. The output end surface of multimode optical fibers 31 tends to bear dust and to degrade due to its higher optical density; the protective plate set forth above may prevent the dust deposition on the end surface and may retard the degradation.

In this example, in order to align optical fibers 31 having a lower clad diameter into an array without a space, multimode optical fiber 30 is stacked between two multimode optical fibers 30 that contact at the larger clad diameter, and the output end of optical fiber 31 connected to the stacked multimode optical fiber 30 is interposed between two output ends of optical fibers 31 connected to two multimode optical fibers 30 that contact at the larger clad diameter.

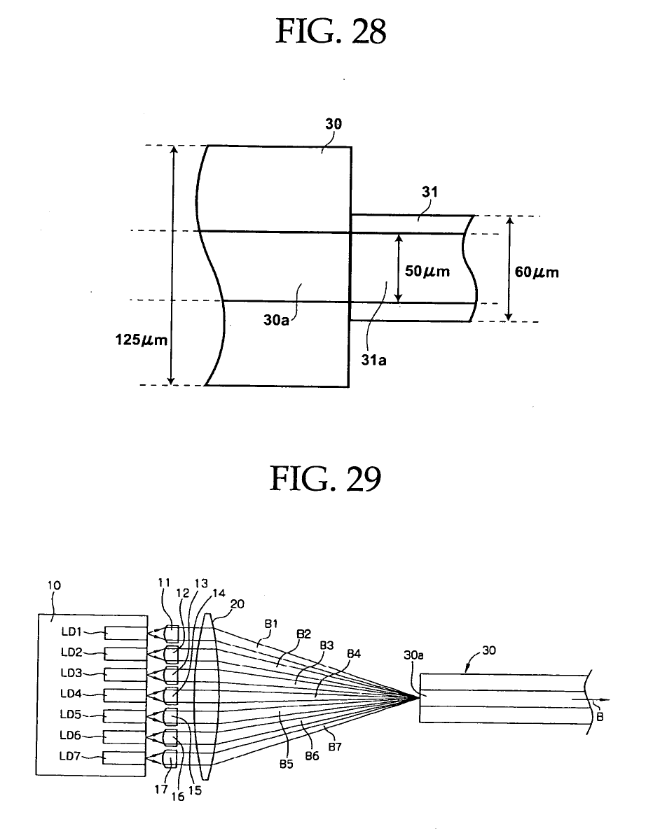

Such optical fibers may be produced by connecting concentrically optical fibers 31 having a length of 1 cm to 30 cm and a smaller clad diameter to the tip portions of laser beam output side of multimode optical fiber 30 having a larger clad diameter, for example, as shown in FIG. 28. Two optical fibers are connected such that the input end surface of optical fiber 31 is fused to the output end surface of multimode optical fiber 30 so as to coincide the center axes of the two optical fibers. The diameter of core 31a of optical fiber 31 is the same as the diameter of core 30a of multimode optical fiber 30 as set forth above.

Further, a shorter optical fiber produced by fusing an optical fiber having a smaller clad diameter to an optical fiber having a shorter length and a larger clad diameter may be connected to the output end of multimode optical fiber through a ferrule, optical connector or the like. The connection through a connector and the like in an attachable and detachable manner may bring about easy exchange of the output end portion when the optical fibers having a smaller clad diameter are partially damaged for example, resulting advantageously in lower maintenance cost for the exposing head. Optical fiber 31 is sometimes referred to as “output end portion” of multimode optical fiber 30.

Multimode optical fiber 30 and optical fiber 31 may be any one of step index type optical fibers, grated index type optical fibers, and combined type optical fibers. For example, step index type optical fibers produced by Mitsubishi Cable Industries, Ltd. are available. In one of the best mode according to the present invention, multimode optical fiber 30 and optical fiber 31 are step index type optical fibers; in the multimode optical fiber 30, clad diameter=125 μm, core diameter=50 μm, NA=0.2, transmittance=99.5% or more (at coating on input end surface); and in the optical fiber 31, clad diameter=60 μm, core diameter=50 μm, NA=0.2.

Laser beams at infrared region typically increase the propagation loss while the clad diameter of optical fibers decreases. Accordingly, a proper clad diameter is defined usually depending on the wavelength region of the laser beam. However, the shorter is the wavelength, the less is the propagation loss; for example, in the laser beam of wavelength 405 nm applied from GaN semiconductor laser, even when the clad thickness (clad diameter−core diameter)/2 is made into about ½ of the clad thickness at which infrared beam of wavelength 800 nm is typically propagated, or made into about ¼ of the clad thickness at which infrared beam of wavelength 1.5 μm for communication is typically propagated, the propagation loss does not increase significantly. Therefore, the clad diameter is possible to be as small as 60 μm.

Needless to say, the clad diameter of optical fiber 31 should not be limited to 60 μm. The clad diameter of optical fiber utilized for conventional fiber array laser sources is 125 μm; the smaller is the clad diameter, the deeper is the focal depth; therefore, the clad diameter of the multimode optical fiber is preferably 80 μm or less, more preferably 60 μm or less, still more preferably 40 μm or less. In the meanwhile, since the core diameter is appropriately at least 3 to 4 μm, the clad diameter of optical fiber 31 is preferably 10 μm or more.

Laser module 64 is constructed from the combined laser source or the fiber array laser source as shown in FIG. 29. The combined laser source is constructed from plural (e.g. seven) multimode or single mode GaN semiconductor lasers LD1, LD2, LD3, LD4, LD5, LD6 and LD7 disposed and fixed on heat block 10, collimator lenses 11, 12, 13, 14, 15, 16, and 17, one collecting lens 20, and one multimode optical fiber 30. Needless to say, the number of semiconductor lasers is not limited to seven. For example, with respect to the multimode optical fiber having clad diameter=60 μm, core diameter=50 μm, NA=0.2, as much as twenty semiconductor lasers may be input, thus the number of optical fibers may be reduced while attaining the necessary optical quantity of the exposing head.

GaN semiconductor lasers LD1 to LD7 have a common oscillating wavelength e.g. 405 nm, and a common maximum output e.g. 100 mW as for multimode lasers and 30 mW as for single mode lasers. The GaN semiconductor lasers LD1 to LD7 may be those having an oscillating wavelength of other than 405 nm as long as within the wavelength of 350 to 450 nm.

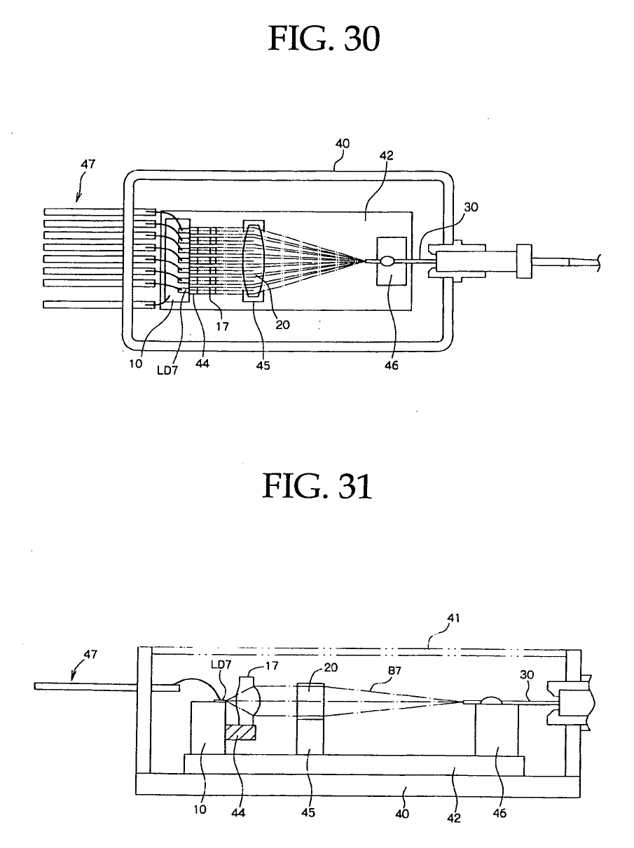

The combined laser source is housed into a box package 40 having an upper opening with other optical elements as shown in FIGS. 30 and 31. The package 40 is equipped with package lid 41 for shutting the opening. Introduction of sealing gas after evacuating procedure and shutting the opening of package 40 by means of package lid 41 presents a closed space or sealed volume constructed by package 40 and package lid 41, and the combined laser source is disposed in a sealed condition.

Base plate 42 is fixed on the bottom of package 40; the heat block 10, collective lens holder 45 to support collective lens 20, and fiber holder 46 to support the input end of multimode optical fiber 30 are mounted to the upper surface of the base plate 42. The output end of multimode optical fiber 30 is drawn out of the package from the aperture provided at the wall of package 40.

Collimator lens holder 44 is attached to the side wall of heat block 10, and collimator lenses 11 to 17 are supported thereby. An aperture is provided at the side wall of package 40, and interconnection 47 that supplies driving power to GaN semiconductor lasers LD1 to LD7 is directed through the aperture out of the package.

In FIG. 31, only the GaN semiconductor laser LD7 is indicated with a reference mark among plural GaN semiconductor laser, and only the collimator lens 17 is indicated with a reference number among plural collimators, in order not to make the figure excessively complicated.

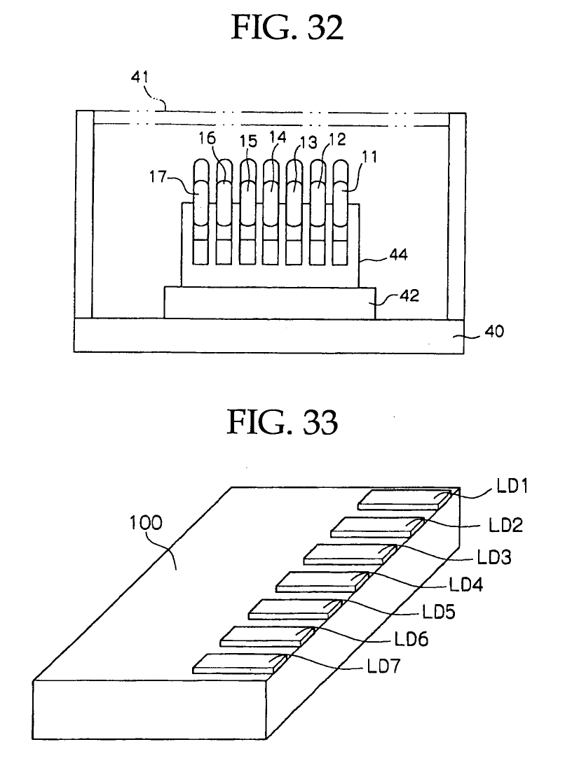

FIG. 32 shows a front shape of attaching part for collimator lenses 11 to 17. Each of collimator lenses 11 to 17 is formed into a shape that a circle lens containing a non-spherical surface is cut into an elongated piece with parallel planes at the region containing the optical axis. The collimator lens with the elongated shape may be produced by a molding process. The collimator lenses 11 to 17 are closely disposed in the aligning direction of emitting points such that the elongated direction is perpendicular to the alignment of the emitting points of GaN semiconductor lasers LD1 to LD7.

In the meanwhile, as for GaN semiconductor lasers LD1 to LD7, the following laser may be employed which contains an active layer having an emitting width of 2 μm and emits the respective laser beams B1 to B7 under the condition that the divergence angle is 10 degrees and 30 degrees for the parallel and perpendicular directions against the active layer. The GaN semiconductor lasers LD1 to LD7 are disposed such that the emitting sites align as one line in parallel to the active layer.

Accordingly, laser beams B1 to B7 emitted from the respective emitting sites enter into the elongated collimator lenses 11 to 17 in a condition that the direction having a larger divergence angle coincides with the length direction of each collimator lens and the direction having a less divergence angle coincides with the width direction of each collimator lens. Namely, the width is 1.1 mm and the length is 4.6 mm with respect to respective collimator lenses 11 to 17, and the beam diameter is 0.9 mm in the horizontal direction and is 2.6 mm in the vertical direction with respect to laser beams B1 to B7 that enter into the collimator lenses. As for the respective collimator lenses 11 to 17, focal length f1=3 mm, NA=0.6, pitch of disposed lenses=1.25 mm.

Collective lens 20 formed into a shape that a part of circle lens containing the optical axis and non-spherical surface is cut into an elongated piece with parallel planes and is arranged such that the elongated piece is longer in the direction of disposing collimator lens 11 to 17 i.e. horizontal direction, and is shorter in the perpendicular direction. As for the collective lens, focal length f2=23 mm, NA=0.2. The collective lens 20 may be produced by molding a resin or optical glass, for example.

Further, since a high luminous fiber array laser source is employed that is arrayed at the output ends of optical fibers in the combined laser source for the illumination unit to illuminate the DMD, a pattern forming apparatus that exhibits a higher output and a deeper focal depth may be attained. In addition, the higher output of the respective fiber array laser sources may lead to less number of fiber array laser sources required to take a necessary output as well as a lower cost of the pattern forming apparatus.

In addition, the clad diameter at the output ends of the optical fibers is smaller than the clad diameter at the input ends, therefore, the diameter at emitting sites is reduced still, resulting in higher luminance of the fiber array laser source. Consequently, pattern forming apparatuses provided with a deeper focal depth may be achieved. For example, a sufficient focal depth may be obtained even for the extremely high resolution exposure such that the beam diameter is 1 μm or less and the resolution is 0.1 μm or less, thereby enabling rapid and precise exposure. Accordingly, the pattern forming apparatus is appropriate for the exposure of thin film transistor (TFT) that requires high resolution.

The illumination unit is not limited to the fiber array laser source that is equipped with plural combined laser sources; for example, such a fiber array laser source may be employed that is equipped with one fiber laser source, and the fiber laser source is constructed by one arrayed optical fiber that outputs a laser beam from one semiconductor laser having an emitting site.

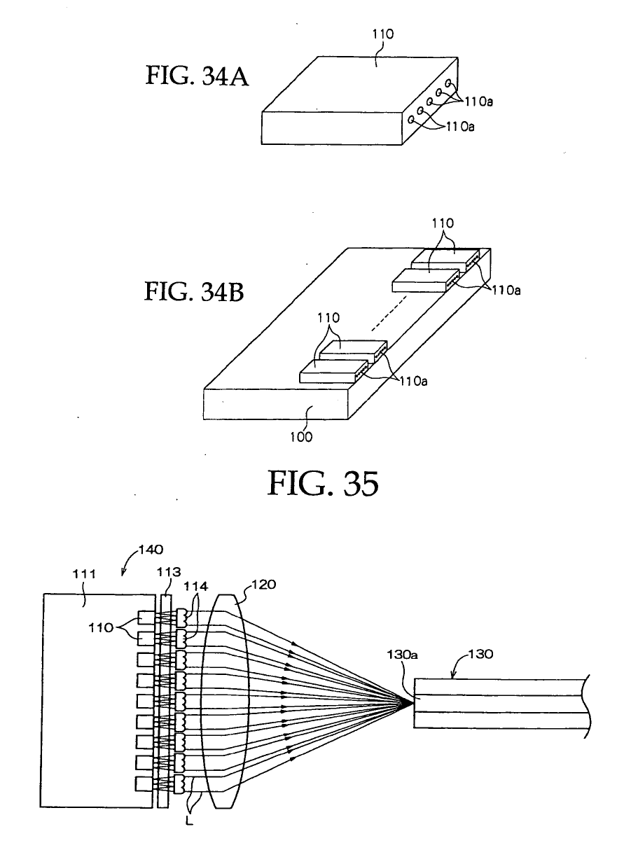

Further, as for the illumination unit having plural emitting sites, such a laser array may be employed that contains plural (e.g. seven) tip-like semiconductor lasers LD1 to LD7 disposed on heat block 100 as shown in FIG. 33. In addition, multi cavity laser 110 is known which contains plural (e.g. five) emitting sites 110a disposed in a certain direction as shown in FIG. 34A. In the multi cavity laser 110, the emitting sites can be arrayed with higher dimensional accuracy as compared to arraying tip-like semiconductor lasers, thus laser beams emitted from the respective emitting sites can be easily combined. Preferably, the number of emitting sites 110a is five or less because deflection tends to arise on multi cavity laser 110 at the laser production process when the number increases.

Concerning the illumination unit, the multi cavity laser 110 set forth above, or the multi cavity array disposed such that plural multi cavity lasers 110 are arrayed in the same direction as emitting sites 110a of each tip as shown in FIG. 34B may be employed for the laser source.

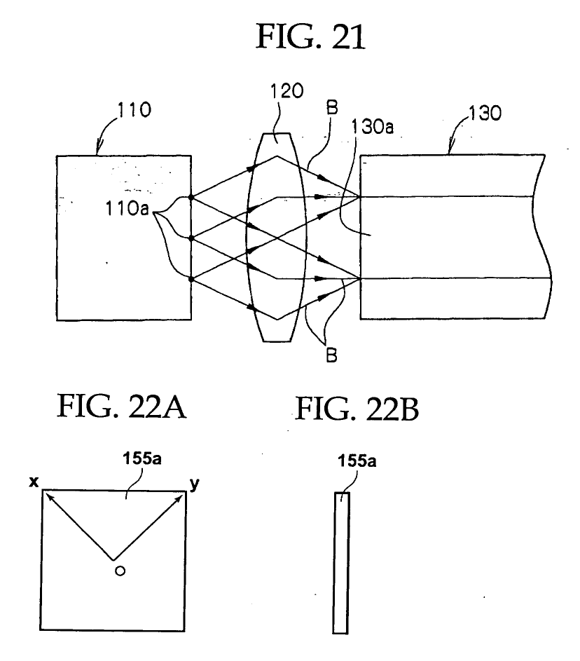

The combined laser source is not limited to the types that combine plural laser beams emitted from plural tip-like semiconductor lasers. For example, such a combined laser source is available that contains tip-like multi cavity laser 110 having plural (e.g. three) emitting sites 110a as shown in FIG. 21. The combined laser source is equipped with multi cavity laser 110, one multimode optical fiber 130, and collecting lens 120. The multi cavity laser 110 may be constructed from GaN laser diodes having an oscillating wavelength of 405 nm, for example.

In the above noted construction, each laser beam B emitted from each of plural emitting sites 110a of multi cavity laser 110 is collected by collective lens 120 and enters into core 130a of multimode optical fiber 130. The laser beams entered into core 130a propagate inside the optical fiber and combine as one laser beam then output from the optical fiber.

The connection efficiency of laser beam B to multimode optical fiber 130 may be enhanced by way of arraying plural emitting sites 110a of multi cavity laser 110 into a width that is approximately the same as the core diameter of multimode optical fiber 130, and employing a convex lens having a focal length of approximately the same as the core diameter of multimode optical fiber 130, and also employing a rod lens that collimates the output beam from multi cavity laser 110 at only within the surface perpendicular to the active layer.

In addition, as shown in FIG. 35, a combined laser source may be employed which is equipped with laser array 140 formed by arraying on heat block 111 plural (e.g. nine) multi cavity lasers 110 with an identical space between them by employing multi cavity lasers 110 equipped with plural (e.g. three) emitting sites. The plural multi cavity lasers 110 are arrayed and fixed in the same direction as emitting sites 110a of the respective tips.

The combined laser source is equipped with laser array 140, plural lens arrays 114 that are disposed correspondingly to the respective multi cavity lasers 110, one rod lens 113 that is disposed between laser array 140 and plural lens arrays 114, one multimode optical fiber 130, and collective lens 120. Lens arrays 114 are equipped with plural micro lenses each corresponding to emitting sites of multi cavity lasers 110.

In the above noted construction, laser beams B that are emitted from plural emitting sites 110a of plural multi cavity lasers 110 are collected in a certain direction by rod lens 113, then are paralleled by the respective microlenses of microlens arrays 114. The paralleled laser beams L are collected by collective lens 120 and are input into core 130a of multimode optical fiber 130. The laser beams entered into core 130a propagate inside the optical fiber and combine as one beam then output from the optical fiber.

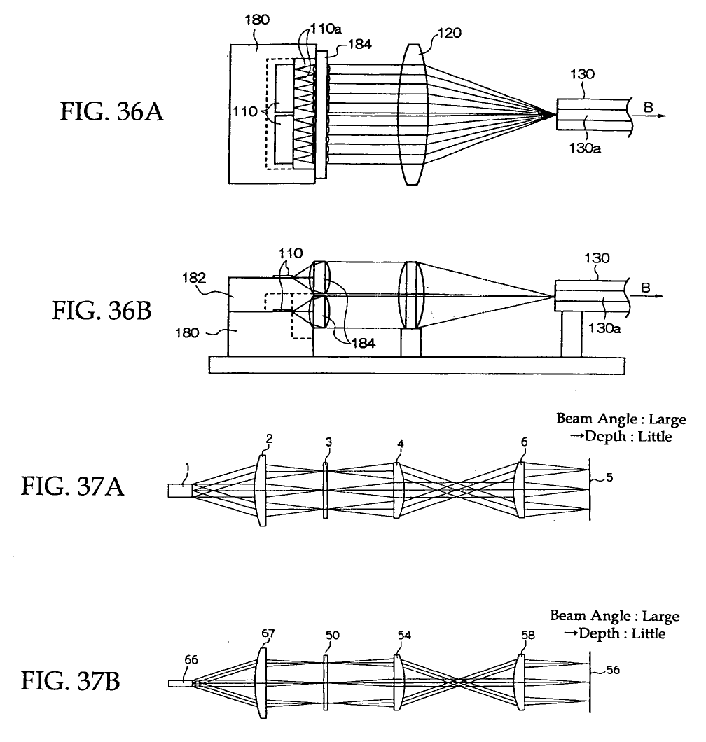

Another combined laser source will be exemplified in the following. In the combined laser source, heat block 182 having a cross section of L-shape in the optical axis direction is installed on rectangular heat block 180 as shown in FIGS. 36A and 36B, and a housing space is formed between the two heat blocks. On the upper surface of L-shape heat block 182, plural (e.g. two) multi cavity lasers 110, in which plural (e.g. five) emitting sites are arrayed, are disposed and fixed with an identical space between them in the same direction as the aligning direction of respective tip-like emitting sites.

A concave portion is provided on the rectangular heat block 180; plural (e.g. two) multi cavity lasers 110 are disposed on the upper surface of heat block 180, plural emitting sites (e.g. five) are arrayed in each multi cavity laser 110, and the emitting sites are situated at the same vertical surface as the surface where are situated the emitting sites of the laser tip disposed on the heat block 182.

At the laser beam output side of multi cavity laser 110, collimate lens arrays 184 are disposed such that collimate lenses are arrayed correspondingly with the emitting sites 110a of the respective tips. In the collimate lens arrays 184, the length direction of each collimate lens coincides with the direction at which the laser beam represents wider divergence angle or the fast axis direction, and the width direction of each collimate lens coincides with the direction at which the laser beam represents less divergence angle or the slow axis direction. The integration by arraying the collimate lenses may increase the space efficiency of laser beam, thus the output power of the combined laser source may be enhanced, and also the number of parts may be reduced, resulting advantageously in lower production cost.

At the laser beam output side of collimate lens arrays 184, disposed are one multimode optical fiber 130 and collective lens 120 that collects laser beams at the input end of multimode optical fiber 130 and combines them.

In the above noted construction, the respective laser beams B emitted from the respective emitting sites 110a of plural multi cavity lasers 110 disposed on laser blocks 180, 182 are paralleled by collimate lens array, are collected by collective lens 120, then entered into core 130a of multimode optical fiber 130. The laser beams entered into core 130a propagate inside the optical fiber and combine as one beam then output from the optical fiber.

The combined laser source may be made into a higher output power source by multiple arrangement of the multi cavity lasers and the array of collimate lenses in particular. The combined laser source allows to construct a fiber array laser source and a bundle fiber laser source, thus is appropriate for the fiber laser source to construct the laser source of the pattern forming apparatus in the present invention.

A laser module may be constructed by housing the respective combined laser sources into a casing, and drawing out the output end of multimode optical fiber 130.

In the explanations set forth above, the higher luminance of fiber array laser source is exemplified that the output end of the multimode optical fiber of the combined laser source is connected to another optical fiber that has the same core diameter as that of the multimode optical fiber and a clad diameter smaller than that of the multimode optical fiber; alternatively a multimode optical fiber having a clad diameter of 125 nm, 80 μm, 60 μm or the like may be utilized without connecting another optical fiber at the output end, for example.

The pattern forming process according to the present invention will be explained further.

As shown in FIG. 29, in each exposing head 166 of scanner 162, the respective laser beams B1, B2, B3, B4, B5, B6, and B7, emitted from GaN semiconductor lasers LD1 to LD 7 that constitute the combined laser source of fiber array laser source 66, are paralleled by the corresponding collimator lenses 11 to 17. The paralleled laser beams B1 to B7 are collected by collective lens 20 and converge at the input end surface of core 30a of multimode optical fiber 30.

In this example, the collective optical system is constructed from collimator lenses 11 to 17 and collective lens 20, and the combined optical system is constructed from the collective optical system and multimode optical fiber 30. Namely, laser beams B1 to B7 that are collected by collective lens 20 enter into core 30a of multimode optical fiber 30 and propagate inside the optical fiber, combine into one laser beam B, then output from optical fiber 31 that is connected at the output end of multimode optical fiber 30.

In each laser module, when the coupling efficiency of laser beams B1 to B7 with multimode optical fiber 30 is 0.85 and each output of GaN semiconductor lasers LD1 to LD7 is 30 mW, each optical fiber disposed in an array can take combined laser beam B of output 180 mW (=30 mW×0.85×7). Accordingly, the output is about 1 W (=180 mW×6) at laser emitting portion 68 of the array of six optical fibers 31.

Laser emitting portions 68 of fiber array source 66 are arrayed such that the higher luminous emitting sites are aligned along the main scanning direction. The conventional fiber laser source that connects laser beam from one semiconductor laser to one optical fiber is of lower output, therefore, a desirable output cannot be attained unless many lasers are arrayed; whereas the combined laser source of lower number (e.g. one) array can produce the desirable output because the combined laser source may generate a higher output.

For example, in the conventional fiber where one semiconductor laser and one optical fiber are connected, a semiconductor laser of about 30 mW output is usually employed, and a multimode optical fiber that has a core diameter of 50 μm, a clad diameter of 125 μm, and a numerical aperture of 0.2 is employed as the optical fiber. Therefore, in order to take an output of about 1 W (Watt), 48 (8×6) multimode optical fibers are necessary; since the area of emitting region is 0.62 mm² (0.675 mm×0.925 mm), the luminance at laser emitting portion 68 is 1.6×10⁶ (W/m²), and the luminance per one optical fiber is 3.2×10⁶ (W/m²).

In contrast, when the laser emitting unit is one capable of emitting the combined laser, six multimode optical fibers can produce the output of about 1 W. Since the area of the emitting region in laser emitting portion 68 is 0.0081 mm² (0.325 mm×0.025 mm), the luminance at laser emitting portion 68 is 123×10⁶ (W/m²), which corresponds to about 80 times the luminance of conventional units. The luminance per one optical fiber is 90×10⁶ (W/m²), which corresponds to about 28 times the luminance of conventional unit.

The difference of focal depth between the conventional exposing head and the exposing head in the present invention will be explained with reference to FIGS. 37A and 37B. For example, the diameter of exposing head is 0.675 mm in the sub-scanning direction of the emitting region of the bundle-like fiber laser source, and the diameter of exposing head is 0.025 mm in the sub-scanning direction of the emitting region of the fiber array laser source. As shown in FIG. 37A, in the conventional exposing head, the emitting region of illuminating unit or bundle-like fiber laser source 1 is larger, therefore, the angle of laser bundle that enters into DMD3 is larger, resulting in larger angle of laser bundle that enters into scanning surface 5. Therefore, the beam diameter tends to increase in the collecting direction, resulting in a deviation in focus direction.

In the meanwhile, as shown in FIG. 37B, the exposing head of the pattern forming apparatus in the present invention has a smaller diameter of the emitting region of fiber array laser source 66 in the sub-scanning direction, therefore, the angle of laser bundle that enters into DMD 50 through lens system 67 is smaller, resulting in lower angle of laser bundle that enters into scanning surface 56, i.e. larger focal depth. In this example, the diameter of the emitting region is about 30 times the diameter of prior art in the sub-scanning direction, thus the focal depth approximately corresponding to the limited diffraction may be obtained, which is appropriate for the exposing at extremely small spots. The effect on the focal depth is more significant as the optical quantity required at the exposing head comes to larger. In this example, the size of one imaging portion projected on the exposing surface is 10 μm×10 μm. The DMD is a spatial light modulator of reflected type; in FIGS. 37A and 37B, it is shown as developed views to explain the optical relation.

The pattern information corresponding to the exposing pattern is input into a controller (not shown) connected to DMD 50, and is memorized once to a flame memory within the controller. The pattern information is the data that expresses the concentration of each imaging portion that constitutes the pixels by means of binary i.e. presence or absence of the dot recording.

Stage 152 that absorbs pattern forming material 150 on the surface is conveyed from upstream to downstream of gate 160 along guide 158 at a constant velocity by a driving device (not shown). When the tip of pattern forming material 150 is detected by detecting sensor 164 installed at gate 160 while stage 152 passes under gate 160, the pattern information memorized at the flame memory is read plural lines by plural lines sequentially, and controlling signals are generated for each exposing head 166 based on the pattern information read by the data processing portion. Then, each micromirror of DMD 50 is subjected to on-off control for each exposing head 166 based on the generated controlling signals.

When a laser beam is applied from fiber array laser source 66 onto DMD 50, the laser beam reflected by the micromirror of DMD 50 at on-condition is imaged on exposed surface 56 of pattern forming material 150 by means of lens systems 54, 58. As such, the laser beams emitted from fiber array laser source 66 are subjected to on-off control for each imaging portion, and pattern forming material 150 is exposed by imaging portions or exposing area 168 of which the number is approximately the same as that of imaging portions employed in DMD 50. Further, through moving the pattern forming material 150 at a constant velocity along with stage 152, pattern forming material 150 is subjected to sub-scanning in the direction opposite to the stage moving direction by means of scanner 162, and band-like exposed region 170 is formed for each exposing head 166.

### [Other Steps]

The other steps are not particularly limited and may be suitably selected from among the steps in known pattern forming steps, and examples thereof include developing, etching, and plating. Each of these steps may be used alone or may be combined with two or more.

In the developing step, a photosensitive layer in the pattern forming material is exposed in the exposing step, exposed areas of the photosensitive layer are hardened, and unhardened portions are removed, thereby developing the photosensitive layer surface to form a pattern.

The method of removing unhardened portions is not particularly limited and may be suitably selected in accordance with the intended use. Examples thereof include a method in which unhardened portions are removed using a developer.

The developer is not particularly limited and may be suitably selected in accordance with the intended use; examples of the developers include alkaline aqueous solutions, aqueous developing liquids, and organic solvents; among these, weak alkali aqueous solutions are preferable. The basic components of the weak alkali aqueous solutions are exemplified by lithium hydroxide, sodium hydroxide, potassium hydroxide, lithium carbonate, sodium carbonate, potassium carbonate, lithium hydrogencarbonate, sodium hydrogencarbonate, potassium hydrogencarbonate, sodium phosphate, potassium phosphate, sodium pyrophosphate, potassium pyrophosphate, and borax.

The weak alkali aqueous solution preferably exhibits a pH of about 8 to 12, more preferably about 9 to 11. Examples of such a solution are aqueous solutions of sodium carbonate and potassium carbonate at a concentration of 0.1% by mass to 5% by mass. The temperature of the developer may be properly selected depending on the developing ability of the developer; for example, the temperature of the developer is about 25 to 40° C.

The developer may be combined with surfactants, defoamers; organic bases such as ethylene diamine, ethanol amine, tetramethylene ammonium hydroxide, diethylene triamine, triethylene pentamine, morpholine, and triethanol amine; organic solvents to promote developing such as alcohols, ketones, esters, ethers, amides, and lactones. The developer set forth above may be an aqueous developer selected from aqueous solutions, aqueous alkali solutions, combined solutions of aqueous solutions and organic solvents, or an organic developer. The etching may be carried out by a method selected properly from conventional etching method.

The etching liquid in the etching method is not particularly limited and may be suitably selected in accordance with the intended use; when the metal layer set forth above is formed of copper, exemplified are cupric chloride solution, ferric chloride solution, alkali etching solution, and hydrogen peroxide solution for the etching liquid; among these, ferric chloride solution is preferred in light of the etching factor.

The etching treatment and the removal of the pattern forming material may form a permanent pattern on the substrate. The permanent pattern is not particularly limited and may be suitably selected in accordance with the intended use; for example, the pattern is of interconnection.

The plating step may be performed by a method selected from conventional plating treatment methods.

Examples of the plating treatment include copper plating such as copper sulfate plating and copper pyrophosphate plating, solder plating such as high flow solder plating, nickel plating such as watt bath (nickel sulfate-nickel chloride) plating and nickel sulfamate plating, and gold plating such as hard gold plating and soft gold plating.

A permanent pattern may be formed by performing a plating treatment in the plating step, followed by removing the pattern forming material and optional etching treatment on unnecessary portions.

### (Laminate)

Exposure is carried out to a photosensitive layer of a laminate in which a pattern forming material is formed in a laminate structure on the substrate. The pattern forming material having the photosensitive layer is not particularly limited and may be suitably selected in accordance with the intended use.

### [Pattern Forming Material]

The pattern forming material is not particularly limited and may be suitably selected in accordance with the intended use as long as the pattern forming material contains a photosensitive layer on a substrate. The photosensitive layer is preferably formed on a substrate. A cushion layer may be formed between the substrate and the photosensitive layer, or a protective film may be formed on a surface of the photosensitive layer. The pattern forming material may contains other layers suitably selected depending on the application.

### <Photosensitive Layer>

The photosensitive layer is not particularly limited and may be suitably selected from among pattern forming materials known in the art, however, preferably, the photosensitive layer contains a polymerizable compound, a photopolymerization initiator, and other components suitably selected depending on the application.

### <<Binder>>

### —Binder—

Preferably, the binder is swellable in alkaline liquids, more preferably, the binder is soluble in alkaline liquids. The binders that are swellable or soluble in alkaline liquids are those having an acidic group, for example.

The acidic group may be properly selected depending on the application without particular limitations; examples thereof include carboxyl group, sulfonic acid group, phosphoric acid group, and the like. Among these groups, a carboxyl group is preferable.

Examples of the binders that contain a carboxyl group include vinyl copolymers, polyurethane resins, polyamide acid resins, and modified epoxy resins that contain a carboxyl group. Among these, vinyl copolymers containing a carboxyl group are preferable from the viewpoints of solubility in coating solvents, solubility in alkaline developers, ability to be synthesized, easiness to adjust film properties, and the like.

The vinyl copolymers containing a carboxyl group may be synthesized by copolymerizing at least (i) a vinyl polymer containing a carboxyl group, and (ii) a monomer capable of copolymerizing with the vinyl monomer.

Examples of vinyl polymers containing a carboxyl group include (meth)acrylic acid, vinyl benzoic acid, maleic acid, maleic acid monoalkylester, fumaric acid, itaconic acid, crotonic acid, cinnamic acid, acrylic acid dimer, adducts of a monomer containing a hydroxy group such as 2-hydroxyethyl(meth)acrylate and a cyclic anhydride such as maleic acid anhydride, phthalic acid anhydride, and cyclohexane dicarbonic acid anhydride, and co-carboxy-polycaprolactone mono(meth)acrylate. Among these, (meth)acrylic acid is preferable in particular from the view points of copolymerizing ability, cost, solubility, and the like.

In addition, as for the precursor of carboxyl group, monomers containing anhydride such as maleic acid anhydride, itaconic acid anhydride, and citraconic acid anhydride may be employed.

The monomer capable of copolymerizing may be properly selected depending on the application; examples thereof include (meth)acrylate esters, crotonate esters, vinyl esters, maleic acid diesters, fumaric acid diesters, itaconic acid diesters, (meth)acrylic amides, vinyl ethers, vinyl alcohol esters, styrenes, metacrylonitrile; heterocyclic compounds with a substituted vinyl group such as vinylpyridine, vinylpyrrolidone, and vinylcarbazole; N-vinyl formamide, N-vinyl acetamide, N-vinyl imidazole, vinyl caprolactone, 2-acrylamide-2-methylpropane sulfonic acid, phosphoric acid mono(2-acryloyloxyethylester), phosphoric acid mono(1-methyl-2-acryloyloxyethylester), and vinyl monomers containing a functional group such as a urethane group, urea group, sulfonic amide group, phenol group, and imide group.

Examples of (meth)acrylate esters include methyl(meth)acrylate, ethyl(meth)acrylate, n-propyl(meth)acrylate, isopropyl(meth)acrylate, n-butyl(meth)acrylate, isobutyl(meth)acrylate, t-butyl(meth)acrylate, n-hexyl(meth)acrylate, cyclohexyl(meth)acrylate, t-butyl cyclohexyl(meth)acrylate, 2-ethylhexyl(meth)acrylate, t-octyl(meth)acrylate, dodecyl(meth)acrylate, octadecyl(meth)acrylate, acetoxyethyl(meth)acrylate, phenyl(meth)acrylate, 2-hydroxyethyl(meth)acrylate, 2-methoxyethyl(meth)acrylate, 2-ethoxyethyl(meth)acrylate (meth)acrylate, 2-(2-methoxyethoxy)ethyl (meth)acrylate, 3-phenoxy-2-hydroxypropyl(meth)acrylate, benzil(meth)acrylate, diethyleneglycol monomethylether (meth)acrylate, diethyleneglycol monoethylether (meth)acrylate, diethyleneglycol monophenylether (meth)acrylate, triethyleneglycol monomethylether (meth)acrylate, triethyleneglycol monoethylether (meth)acrylate, polyethyleneglycol monomethylether (meth)acrylate, polyethyleneglycol monoethylether (meth)acrylate, β-phenoxyethoxyethyl(meth)acrylate, nonylphenoxy polyethyleneglycol (meth)acrylate, dicyclopentanyl(meth)acrylate, dicyclopentenyl oxyethyl (meth)acrylate, trifluoroethyl(meth)acrylate, octafluoropentyl(meth)acrylate, perfluorooctylethyl(meth)acrylate, tribromophenyl(meth)acrylate, and tribromophenyloxyethyl(meth)acrylate.

Examples of crotonate esters include butyl crotonate, and hexyl crotonate.

Examples of vinyl esters include vinyl acetate, vinyl propionate, vinyl butyrate, vinylmethoxy acetate, and vinyl benzoate.

Examples of maleic acid diesters include dimethyl maleate, diethyl maleate, and dibutyl maleate.

Examples of fumaric acid diesters include dimethyl fumarate, diethyl fumarate, and dibutyl fumarate.

Examples of itaconic acid diesters include dimethyl itaconate, diethyl itaconate, and dibutyl itaconate.

Examples of (meth)acrylic amides include (meth)acrylamide, N-methyl (meth)acrylamide, N-ethyl(meth)acrylamide, N-propyl(meth)acrylamide, N-isopropyl(meth)acrylamide, N-n-butyl(meth)acrylamide, N-t-butyl (meth)acrylamide, N-cyclohexyl(meth)acrylamide, N-(2-methoxyethyl) (meth)acrylamide, N,N-dimethyl(meth)acrylamide, N,N-diethyl (meth)acrylamide, N-phenyl(meth)acrylamide, N-benzil (meth)acrylamide, (meth)acryloyl morpholine, and diacetone acrylamide.

Examples of the styrenes include styrene, methylstyrene, dimethylstyrene, trimethylstyrene, ethylstyrene, isopropylstyrene, butylstyrene, hydroxystyrene, methoxystyrene, butoxystyrene, acetoxystyrene, chlorostyrene, dichlorostyrene, bromostyrene, chloromethylstyrene; hydroxystyrene with a protective group such as t-Boc capable of being de-protected by an acid substance; vinylmethyl benzoate, and α-methylstyrene.

Examples of vinyl ethers include methyl vinylether, butyl vinylether, hexyl vinylether, and methoxyethyl vinylether.

The process to synthesize the vinyl monomer containing a functional group is an addition reaction of an isocyanate group and a hydroxy group or amino group for example; specifically, an addition reaction between a monomer containing an isocyanate group and a compound containing one hydroxyl group or a compound containing one primary or secondary amino group, and an addition reaction between a monomer containing a hydroxy group or a monomer containing a primary or secondary amino group and a mono isocyanate are exemplified.

Examples of the monomers containing an isocyanate group include the compounds expressed by the following formulas (1) to (3).

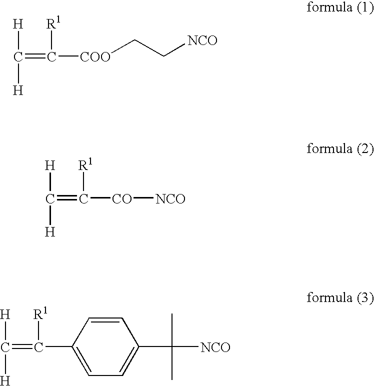

In the above formulas (1) to (3), R¹ represents a hydrogen atom or a methyl group.

Examples of mono isocyanates set forth above include cyclohexyl isocyanate, n-butyl isocyanate, toluic isocyanate, benzil isocyanate, and phenyl isocyanate.

Examples of the monomers containing a hydroxyl group include the compounds expressed by the following formulas (4) to (12).

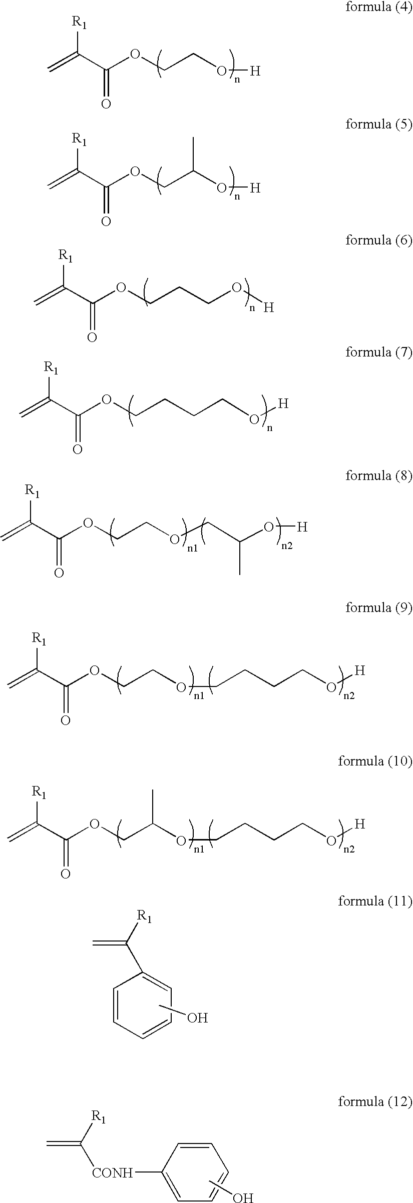

In the above formulas (4) to (12), R₁ represents a hydrogen atom or a methyl group, and “n” represents an integer of one or more.

Examples of the compounds containing one hydroxyl group include alcohols such as methanol, ethanol, n-propanol, i-propanol, n-butanol, sec-butanol, t-butanol, n-hexanol, 2-ethylhexanol, n-decanol, n-dodecanol, n-octadecanol, cyclopentanol, cyclohexanol, benzil alcohol, and phenylethyl alcohol; phenols such as phenol, cresol, and naphthol; examples of the compounds containing additionally a substituted group include fluoroethanol, trifluoroethanol, methoxyethanol, phenoxyethanol, chlorophenol, dichlorophenol, methoxyphenol, and acetoxyphenol.

Examples of monomers containing a primary or secondary amino group set forth above include vinylbenzil amine.

Examples of compounds containing a primary or secondary amino group include alkylamines such as methylamine, ethylamine, n-propylamine, i-propylamine, n-butylamine, sec-butylamine, t-butylamine, hexylamine, 2-ethylhexylamine, decylamine, dodecylamine, octadecylamine, dimethylamine, diethylamine, dibutylamine, and dioctylamine; cyclic alkylamines such as cyclopentylamine and cyclohexylamine; aralkylamines such as benzilamine and phenethylamine; arylamines such as aniline, toluicamine, xylylamine, and naphthylamine; combination thereof such as N-methyl-N-benzilamine; and amines containing a substituted group such as trifluoroethylamine, hexafluoro isopropylamine, methoxyaniline, and methoxy propylamine.

Examples of the copolymerizable monomers other than set forth above include methyl(meth)acrylate, ethyl(meth)acrylate, butyl(meth)acrylate, benzil (meth)acrylate, 2-ethylhexyl(meth)acrylate, styrene, chlorostyrene, bromostyrene, and hydroxystyrene.

The above noted copolymerizable monomers may be used alone or in combination.

The vinyl copolymers set forth above may be prepared by copolymerizing the appropriate monomers in accordance with conventional processes; for example, such a solution polymerization process is available as dissolving the monomers into an appropriate solvent, adding a radical polymerization initiator, thereby causing a polymerization in the solvent; alternatively such a so-called emulsion polymerization process is available as polymerizing the monomers under the condition that the monomers are dispersed in an aqueous solvent.

The solvent utilized in the solution polymerization process may be properly selected depending on the monomers, solubility of the resultant copolymer and the like; examples of the solvents include methanol, ethanol, propanol, isopropanol, 1-methoxy-2-propanol, acetone, methyl ethyl ketone, methylisobutylketone, methoxypropyl acetate, ethyl lactate, ethyl acetate, acetonitrile, tetrahydrofuran, dimethylformamide, chloroform, and toluene. These solvents may be used alone or in combination.

The radical polymerization initiator set forth above may be properly selected without particular limitations; examples thereof include azo compounds such as 2,2′-azobis(isobutyronitrile) (AIBN) and 2,2′-azobis-(2,4′-dimethylvaleronitrile); peroxides such as benzoyl peroxide; persulfates such as potassium persulfate and ammonium persulfate.

The content of the polymerizable compound having a carboxyl group in the vinyl copolymers set forth above may be properly selected without particular limitations; preferably, the content is 5 to 50 mole %, more preferably is 10 to 40 mole %, and still more preferably is 15 to 35 mole %.

When the content is less than 5 mole %, the developing ability in alkaline solution may be insufficient, and when the content is more than 50 mole %, the durability of the hardening portion or imaging portion is insufficient against the developing liquid.

The molecular weight of the binder having a carboxyl group set forth above may be properly selected without particular limitations; preferably the weight-averaged molecular weight is 2000 to 300000, more preferably is 4000 to 150000.

When the weight-averaged molecular weight is less than 2000, the film strength is likely to be insufficient, and also the production process tends to be unstable, and when the weight-averaged molecular weight is more than 300000, the developing ability tends to decrease.

The binder having a carboxyl group set forth above may be used alone or in combination. As for the combination of two or more of the binders, such combination may be exemplified as two or more of binders having different copolymer components, two or more of binders having different weight-averaged molecular weight, and two or more of binders having different dispersion levels.

In the binder having a carboxyl group set forth above, a part or all of the carboxyl groups may be neutralized by a basic substance. Further, the binder may be combined with a resin of different type selected from polyester resins, polyamide resins, polyurethane resins, epoxy resins, polyvinyl alcohols, gelatin, and the like.

In addition, the binder having a carboxyl group set forth above may be a resin soluble in an alkaline aqueous solution as described in Japanese Patent No. 2873889.

The content of the binder in the photosensitive layer set forth above may be properly selected without particular limitations; preferably the content is 10 to 90% by mass, more preferably is 20 to 80% by mass, and still more preferably is 40 to 80% by mass.

When the content is less than 10% by mass, the developing ability in alkaline solutions or the adhesive property with substrates for forming printed wiring boards such as a cupper laminated board tends to decrease, and when the content is more than 90% by mass, the stability of developing period or the strength of the hardening film or the tenting film may be insufficient. The content of the binder may be considered as the sum of the binder content and the additional polymer binder content combined depending on requirements.

The acid value of the binder may be properly selected depending on the application; preferably the acid value is 70 to 250 mgKOH/g, more preferably is 90 to 200 mgKOH/g, still more preferably is 100 to 180 mgKOH/g.

When the acid value is less than 70 mgKOH/g, the developing ability may be insufficient, the resolving property may be poor, or the permanent pattern such as interconnection patterns cannot be formed precisely, and when the acid value is more than 250 mgKOH/g, the durability of pattern against the developer and/or adhesive property of pattern tends to degrade, thus the permanent pattern such as interconnection patterns cannot be formed precisely.

### <<Polymerizable Compound>>

The polymerizable compound may be properly selected without particular limitations; preferably, the polymerizable compound is the monomer or oligomer that contains a urethane group and/or an aryl group; preferably, the polymerizable compound contains two or more types of polymerizable group.

Examples of the polymerizable group include ethylenically unsaturated bonds such as (meth)acryloyl groups, (meth)acrylamide groups, styryl groups, vinyl groups (e.g. of vinyl esters, vinyl ethers), and allyl groups (e.g. of allyl ethers, allyl esters); and polymerizable cyclic ether groups such as epoxy groups and oxetane group. Among these, the ethylenically unsaturated bond is preferable.

### —Monomer Containing Urethane Group—

The monomer containing a urethane group set forth above may be properly selected without particular limitations; examples thereof include those described in Japanese Patent Application Publication (JP-B) No. 4841708, Japanese Patent Application Laid-Open (JP-A) No. 51-37193, JP-B Nos. 5-50737, 7-7208, and JP-A Nos. 2001-154346, 2001-356476; specifically, the adducts may be exemplified between polyisocyanate compounds having two or more isocyanate groups in the molecule and vinyl monomers having a hydroxyl group in the molecule.

Examples of the polyisocyanate compounds having two or more isocyanate groups in the molecule set forth above include diisocyanates such as hexamethylene diisocyanate, trimethyl hexamethylene diisocyanate, isophorone diisocyanate, xylene diisocyanate, toluene diisocyanate, phenylene diisocyanate, norbornene diisocyanate, diphenyl diisocyanate, diphenylmethane diisocyanate, and 3,3′-dimethyl-4,4′-diphenyl diisocyanate; polyaddition products of these diisocyanates and two-functional alcohols wherein each of both ends of the polyaddition product is an isocyanate group; trimers such as buret of the diisocyanates or isocyanurates; adducts obtained from the diisocyanate of diisocyanates and polyfunctional alcohols such as trimethylolpropane, pentaerythritol, and glycerin or polyfunctional alcohols of adducts with ethylene oxide.

Examples of vinyl monomers having a hydroxyl group in the molecule set forth above include 2-hydroxyethyl(meth)acrylate, 2-hydroxypropyl (meth)acrylate, 4-hydroxybutyl(meth)acrylate, diethyleneglycol mono(meth)acrylate, triethyleneglycol mono(meth)acrylate, tetraethyleneglycol mono(meth)acrylate, octaethyleneglycol mono(meth)acrylate, polyethyleneglycol mono(meth)acrylate, dipropyleneglycol mono(meth)acrylate, tripropyleneglycol mono(meth)acrylate, tetrapropyleneglycol mono(meth)acrylate, octapropyleneglycol mono(meth)acrylate, polypropyleneglycol mono(meth)acrylate, dibutyleneglycol mono(meth)acrylate, tributyleneglycol mono(meth)acrylate, tetrabutyleneglycol mono(meth)acrylate, octabutyleneglycol mono(meth)acrylate, polybutyleneglycol mono(meth)acrylate, trimethylolpropane (meth)acrylate, and pentaerythritol (meth)acrylate. Further, such a vinyl monomer may be exemplified that has a (meth)acrylate component at one end of diol molecule having different alkylene oxides such as of random or block copolymer of ethylene oxide and propylene oxide for example.

Examples of the monomers containing a urethane group set forth above include the compounds having an isocyanurate ring such as tri(meth)acryloyloxyethyl isocyanurate, di(meth)acrylated isocyanurate, and tri(meth)acrylate of ethylene oxide modified isocyanuric acid. Among these, the compounds expressed by formula (13) or formula (14) are preferable; at least the compounds expressed by formula (14) are preferably included in particular from the view point of tenting property. These compounds may be used alone or in combination.

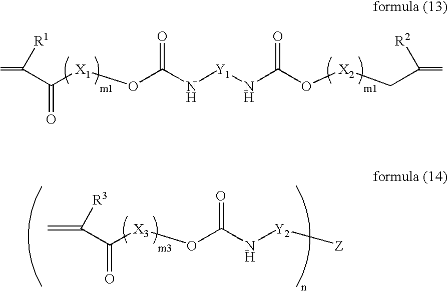

In the formulas (13) and (14), R¹ to R³ represent a hydrogen atom or a methyl group respectively; X₁ to X₃ represent alkylene oxide groups, which may be identical or different each other.

Examples of the alkylene oxide group include ethylene oxide group, propylene oxide group, butylene oxide group, pentylene oxide group, hexylene oxide group, and combined groups thereof in random or block. Among these, ethylene oxide group, propylene oxide group, butylene oxide group, and combined groups thereof are preferable; and ethylene oxide group and propylene oxide group are more preferable.

In the formulas (13) and (14), m1 to m3 represent integers of 1 to 60 respectively, preferably is 2 to 30, and more preferably is 4 to 15.

In the formulas (13) and (14), each of Y¹ and Y² represents a divalent organic group having 2 to 30 carbon atoms such as alkylene group, arylene group, alkenylene group, alkynylene group, carbonyl group (—CO—), oxygen atom, sulfur atom, imino group (—NH—), substituted imino group wherein a hydrogen atom on the imino group is substituted by a monovalent hydrocarbon group, sulfonyl group (—SO₂—), and combination thereof; among these, an alkylene group, arylene group, and combination thereof are preferable.

The alkylene group set forth above may be of branched or cyclic structure; examples of the alkylene group include methylene group, ethylene group, propylene group, isopropylene group, butylene group, isobutylene group, pentylene group, neopentylene group, hexylene group, trimethylhexylene group, cyclohexylene group, heptylene group, octylene group, 2-ethylhexylene group, nonylene group, decylene group, dodecylene group, octadecylene group, and the groups expressed by the following formulas.

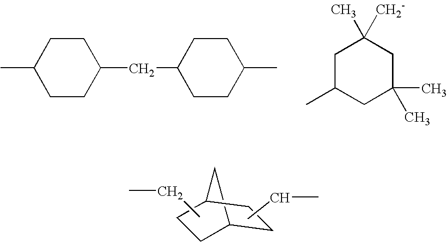

The arylene group may be substituted by a hydrocarbon group; examples of the arylene group include phenylene group, thrylene group, diphenylene group, naphthylele group, and the following group.

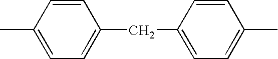

The group of combination thereof set forth above is exemplified by xylylene group.

The alkylene group, arylene group, and combination thereof set forth above may contain a substituted group additionally; examples of the substituted group include halogen atoms such as fluorine atom, chlorine atom, bromine atom, and iodine atom; aryl groups; alkoxy groups such as methoxy group, ethoxy group, and 2-ethoxyethoxy group; aryloxy groups such as phenoxy group; acyl groups such as acetyl group and propionyl group; acyloxy groups such as acetoxy group and butylyloxy group; alkoxycarbonyl groups such as methoxycarbonyl group and ethoxycarbonyl group; and aryloxycarbonyl groups such as phenoxycarbonyl group.

In the formulas (13) and (14), “n” represents an integer of 3 to 6, preferably, “n” is 3, 4, or 6 from the view point of the available feedstock for synthesizing the polymerizable monomer.

In the formulas (13) and (14), “n” represents an integer of 3 to 6; Z represents a connecting group of “n” valences (n=3 to 6), examples of Z include the following groups.

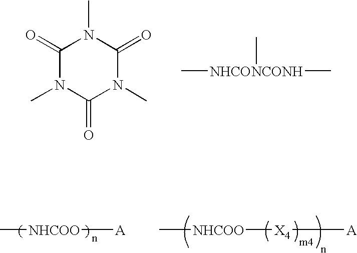

In the above formulas, X4 represents an alkylene oxide; m4 represents an integer of 1 to 20; “n” represents an integer of 3 to 6; and A represents an organic group having “n” valences (n=3 to 6).

Example of A of the organic group set forth above include n-valence aliphatic groups, n-valence aromatic groups, and combinations of these groups and alkylene groups, arylene groups, alkenylene groups, alkynylene groups, carbonyl group, oxygen atom, sulfur atom, imino group, substituted imino groups wherein a hydrogen atom on the imino group is substituted by a monovalent hydrocarbon group, and sulfonyl group (—SO₂—); more preferably are n-valence aliphatic groups, n-valence aromatic groups, and combinations of these groups and alkylene groups, arylene groups, or an oxygen atom; particularly preferable are n-valence aliphatic groups, and combinations of n-valence aliphatic groups and alkylene groups or an oxygen atom.

The number of carbon atoms in the A of the organic group set forth above is preferably 1 to 100, more preferably is 1 to 50, and most preferably is 3 to 30.

The n-valence aliphatic group set forth above may be of branched or cyclic structure. The number of carbon atoms in the aliphatic group is preferably 1 to 30, more preferably is 1 to 20, and most preferably is 3 to 10.

The number of carbon atoms in the aromatic group set forth above is preferably 6 to 100, more preferably is 6 to 50, and most preferably is 6 to 30.

The n-valence aliphatic group and the n-valence aromatic group may contain a substituted group additionally; examples of the substituted group include hydroxyl group, halogen atoms such as fluorine atom, chlorine atom, bromine atom, and iodine atom; aryl groups; alkoxy groups such as methoxy group, ethoxy group, and 2-ethoxyethoxy group; aryloxy groups such as phenoxy group; acyl groups such as acetyl group and propionyl group; acyloxy groups such as acetoxy group and butylyloxy group; alkoxycarbonyl groups such as methoxycarbonyl group and ethoxycarbonyl group; and aryloxycarbonyl groups such as phenoxycarbonyl group.

The alkylene group set forth above may be of branched or cyclic structure. The number of carbon atoms in the alkylene group is preferably 1 to 18, and more preferably is 1 to 10.

The arylene group set forth above may be further substituted by a hydrocarbon group. The number of carbon atoms in the arylene group is preferably 6 to 18, and more preferably is 6 to 10.

The number of carbon atoms in the hydrocarbon group of the substituted imino group set forth above is preferably 1 to 18, and more preferably is 1 to 10.

Preferable examples of A of the organic group set forth above are as follows.

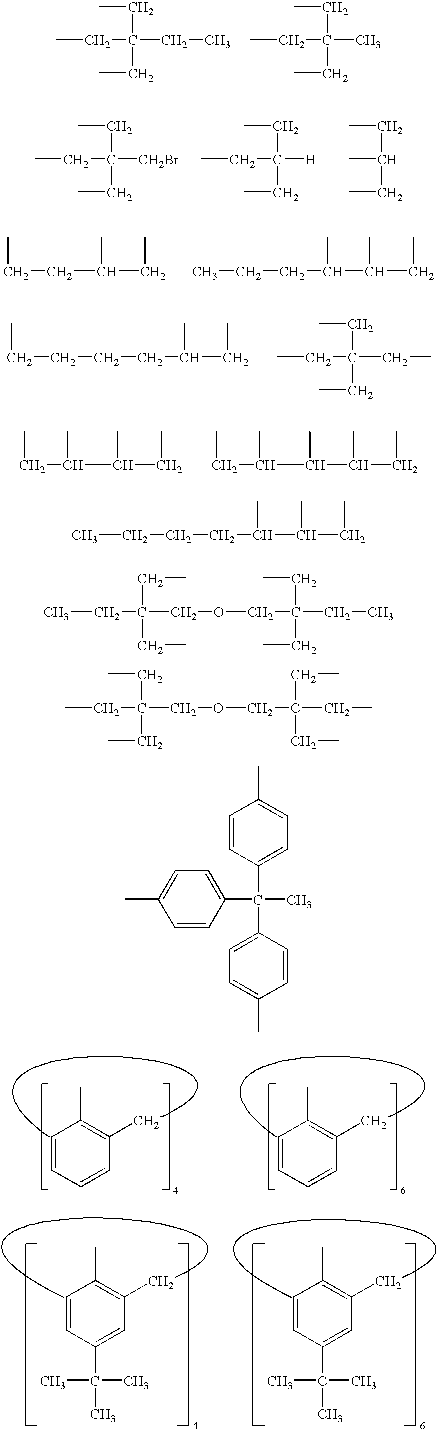

The compounds expressed by the formulas (13) and (14) are exemplified specifically by the following formulas (15) to (37).

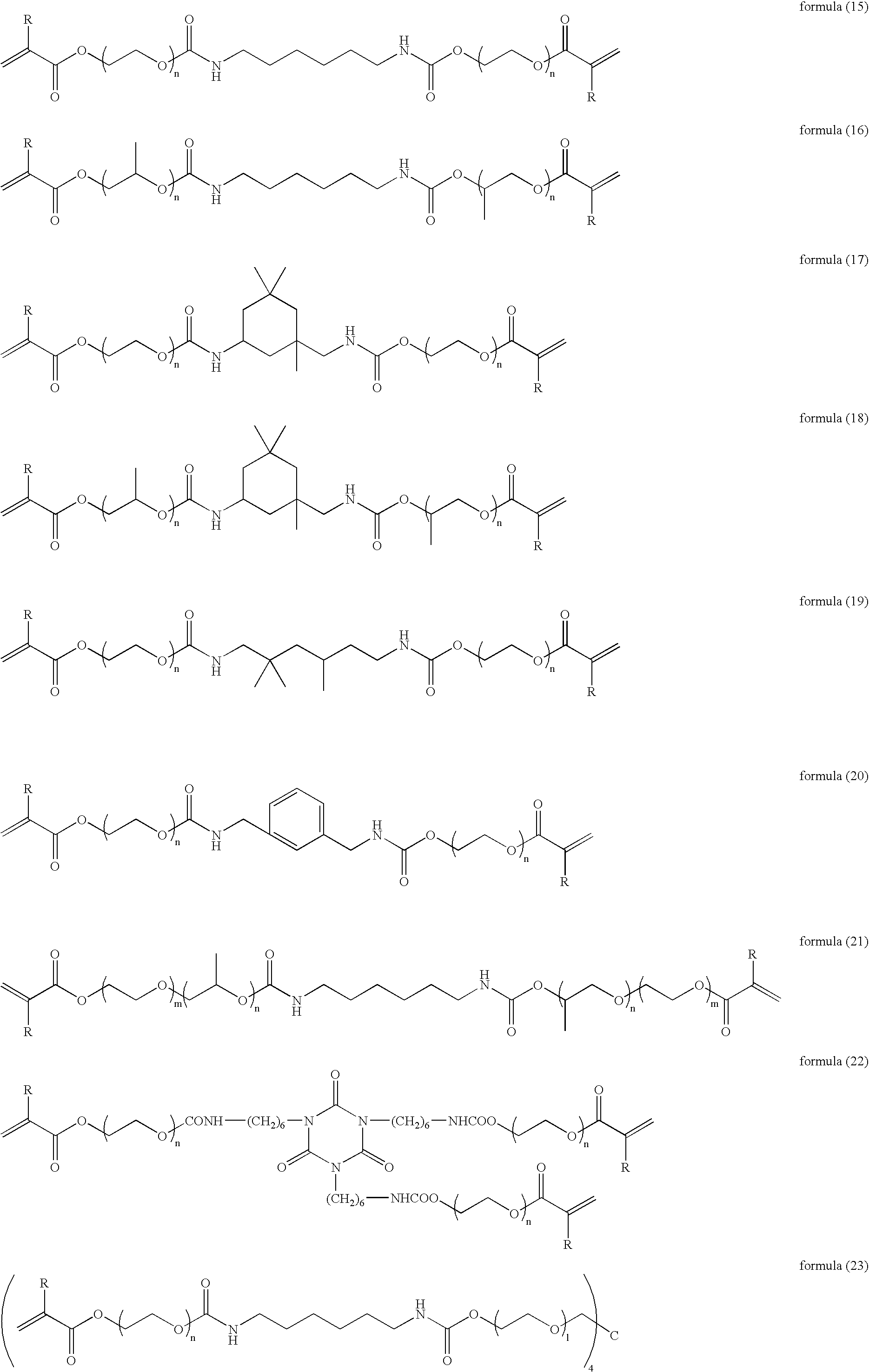

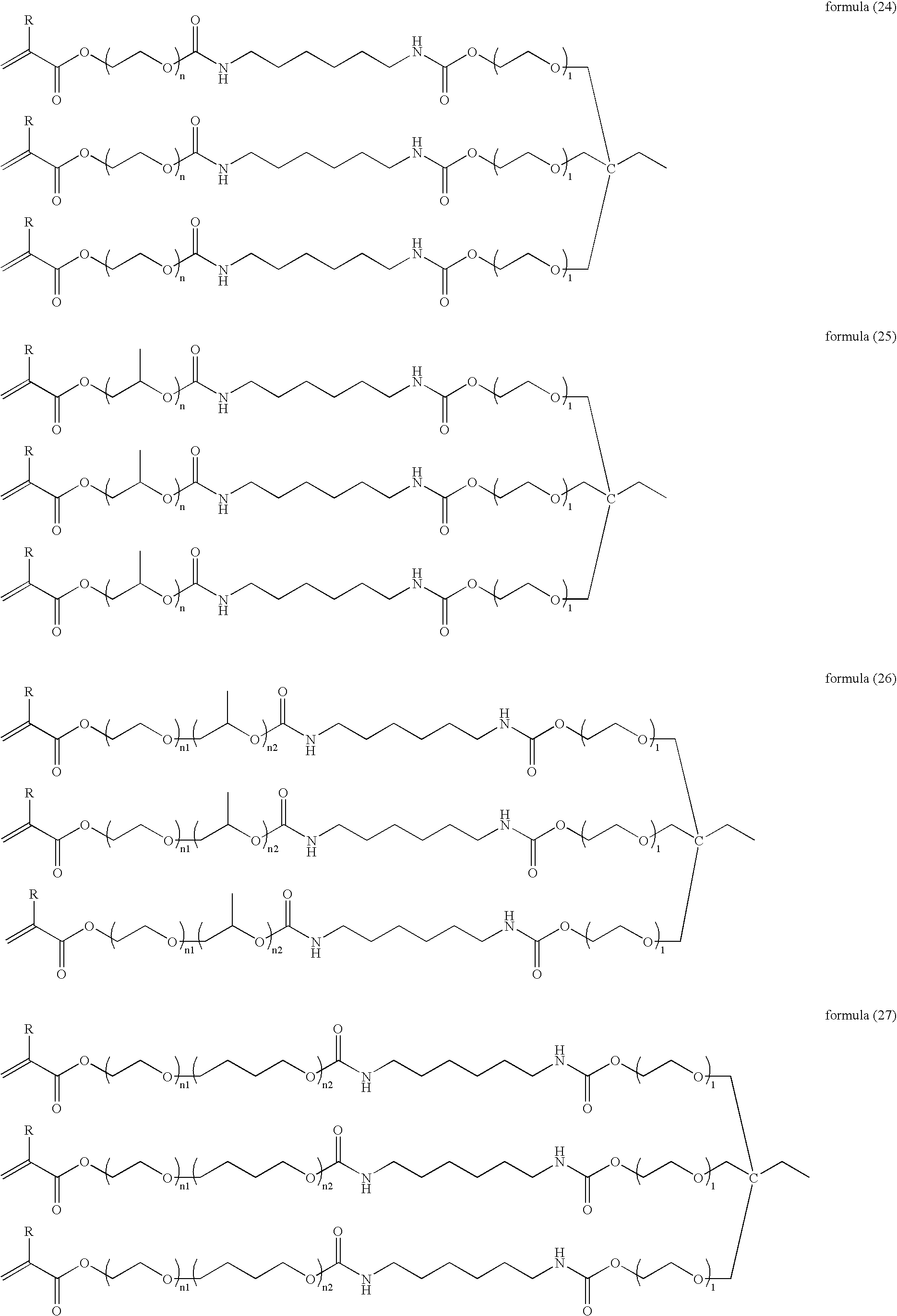

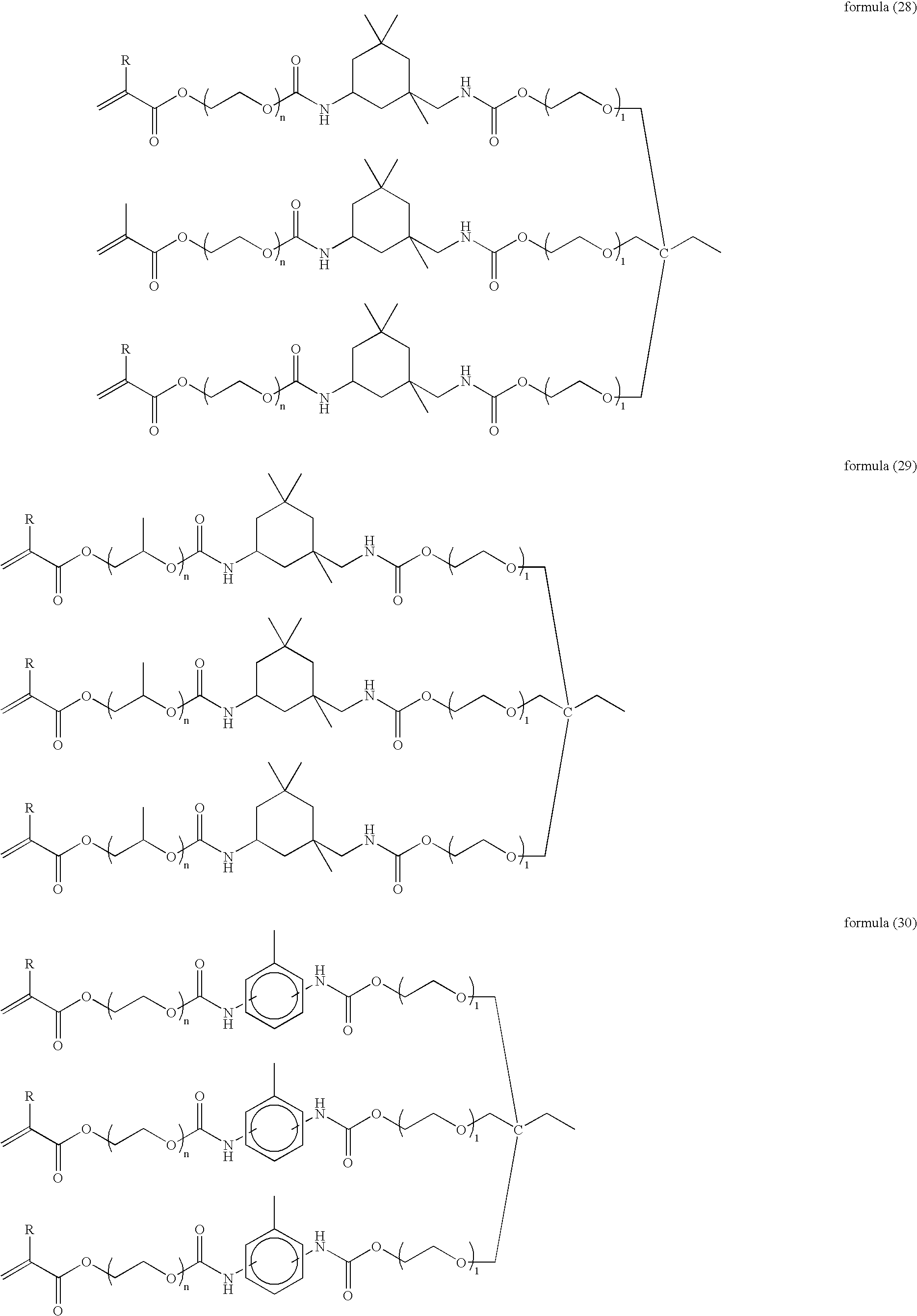

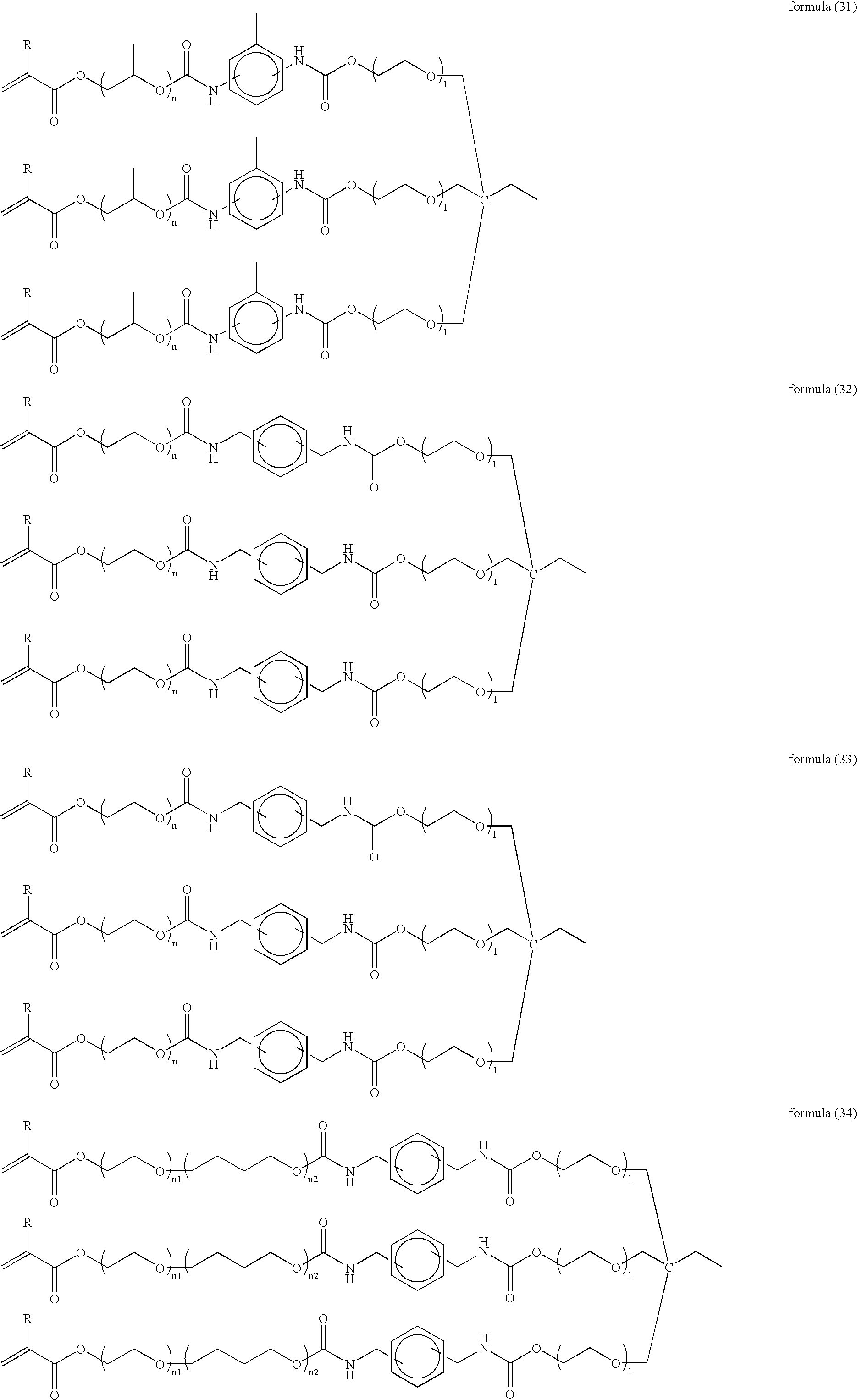

In the above formulas (15) to (34), each of “n”, n1, n2, and “m” represents an integer of 1 to 60; “1” represents an integer of 1 to 20; and R represents a hydrogen atom or a methyl group.

### —Monomer Containing Aryl Group—

The monomers containing an aryl group set forth above may be properly selected as long as the monomer contains an aryl group; examples of the monomers containing an aryl group include esters and amides between at least one of polyvalent alcohol compounds, polyvalent amine compounds, and polyvalent amino alcohol compounds containing an aryl group and at least one of unsaturated carboxylic acids.

Examples of the polyvalent alcohol compounds, polyvalent amine compounds, and polyvalent amino alcohol compounds containing an aryl group include polystyrene oxide, xylylenediol, di(β-hydroxyethoxy)benzene, 1,5-dihydroxy-1,2,3,4-tetrahydronaphthalene, 2,2-diphenyl-1,3-propanediol, hydroxybenzyl alcohol, hydroxyethyl resorcinol, 1-phenyl-1,2-ethanediol, 2,3,5,6-tetramethyl-p-xylene-α,α′-diol, 1,1,4,4-tetraphenyl-1,4-butanediol, 1,1,4,4-tetraphenyl-2-butine-1,4-diol, 1,1′-bi-2-naphthol, dihydroxynaphthalene, 1,1′-methylene-di-2-naphthol, 1,2,4-benzenetriol, biphenol, 2,2′-bis(4-hydroxyphenyl)butane, 1,1-bis(4-hydroxyphenyl)cyclohexane, bis(hydroxyphenyl)methane, catechol, 4-chlororesorcinol, hydroquinone, hydroxybenzyl alcohol, methylhydroquinone, methylene-2,4,6-trihydroxybenzoate, fluoroglucinol, pyrogallol, resorcinol, α-(1-aminoethyl)-p-hydroxybenzyl alcohol, and 3-amino-4-hydroxyphenyl sulfone. In addition, xylylene-bis-(meth)acrylamide; adducts of novolac epoxy resins or glycidyl compounds such as bisphenol A diglycidylether and α,β-unsaturated carboxylic acids; ester compounds from acids such as phthalic-acid and trimellitic acids and vinyl monomers containing a hydroxide group; diallyl phthalate, triallyl trimellitate, diallyl benzene sulfonate, cationic polymerizable divinylethers as a polymerizable monomer such as bisphenol A divinylether; epoxy compounds such as novolac epoxy resins and bisphenol A diglycidylethers; vinyl esters such as divinyl phthalate, divinyl terephthalate, and divinylbenzene-1,3-disulfonate; and styrene compounds such as divinyl benzene, p-allyl styrene, and p-isopropene styrene. Among these, the compounds expressed by the following formula (38) are preferable.

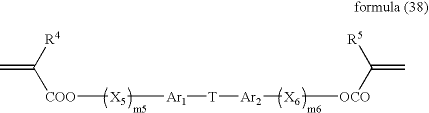

In the above formula (38), R⁴ and R⁵ represent respectively a hydrogen atom or an alkyl group.

In the above formula (38), X5 and X6 represent an alkylene oxide group respectively, the alkylene oxide group may be one species or two or more species. Examples of the alkylene oxide group include ethylene oxide group, propylene oxide group, butylene oxide group, pentylene oxide group, hexylene oxide group, and combined groups in random or block thereof. Among these, ethylene oxide group, propylene oxide group, butylene oxide group, and combined groups thereof are preferable; and ethylene oxide group and propylene oxide group are more preferable.

In the formula (38), m5 and m6 represent respectively an integer of 1 to 60, preferably is 2 to 30, and more preferably is 4 to 15.

In the formula (38), T represents a divalent connecting group such as methylene group, ethylene group, MeCMe, CF₃CCF₃, CO, and SO₂.

In the formula (38), Ar₁ and Ar₂ represent respectively an aryl group that may contain a substituted group; examples of Ar₁ and Ar₂ include phenylene and naphthyene; and examples of the substituted group include alkyl groups, aryl groups, aralkyl groups, halogen groups, alkoxy groups, and combinations thereof.

Specific examples of the monomer containing an aryl group set forth above include 2,2-bis[4-(3-(meth)acryloxy-2-hydroxypropoxy)phenyl]propane, 2,2-bis[4-((meth)acryloxyethoxy)phenyl]propane; 2,2-bis[4-((meth)acryloyloxypolyethoxy)phenyl]propane in which the number of ethoxy groups substituted for one phenolic OH group is 2 to 20 such as 2,2-bis[4-((meth)acryloyloxydiethoxy)phenyl]propane, 2,2-bis[4-((meth)acryloyloxytetraethoxy)phenyl]propane, 2,2-bis[4-((meth)acryloyloxypentaethoxy)phenyl]propane, 2,2-bis[4-((meth)acryloyloxydecaethoxy)phenyl]propane, and 2,2-bis[4-((meth)acryloyloxypentadecaethoxy)phenyl]propane; 2,2-bis[4-((meth)acryloxypropoxy)phenyl]propane, 2,2-bis[4-((meth)acryloyloxypolypropoxy)phenyl]propane in which the number of ethoxy groups substituted for one phenolic OH group is 2 to 20 such as 2,2-bis[4-((meth)acryloyloxydipropoxy)phenyl]propane, 2,2-bis[4-((meth)acryloyloxytetrapropoxy)phenyl]propane, 2,2-bis[4-((meth)acryloyloxypentapropoxy)phenyl]propane, 2,2-bis[4-((meth)acryloyloxydecapropoxy)phenyl]propane, 2,2-bis[4-((meth)acryloyloxypentadecapropoxy)phenyl]propane; compounds having a polyethylene oxide skeleton as well as a polypropylene skeleton in one molecule as the ether site of these compounds such as described in International Publication No WO 01/98832 and commercial products of BPE-200, BPE-500, and BPE-1000 (by Shin-nakamura Chemical Co.); and polymerizable compounds having a polyethylene oxide skeleton as well as a polypropylene skeleton. In these compounds, the site resultant from bisphenol A may be changed into the site resultant from bisphenol F, bisphenol S, or the like.

Examples of the polymerizable compounds having a polyethylene oxide skeleton as well as a polypropylene skeleton include the adducts of bisphenols and ethylene oxides or propylene oxides, and the compounds having a hydroxyl group at the end wherein the compound is formed as a polyaddition product and the compound has an isocyanate group and a polymerizable group such as 2-isocyanate ethyl(meth)acrylate and α,α-dimethylviny benzilisocyanate, and the like.

### —Other Polymerizable Monomer—

In the pattern forming process according to the present invention, the polymerizable monomers other than the monomers having a urethane group or an aryl group set forth above may be employed together within a range that the properties of the pattern forming material are not deteriorated.

Examples of monomers other than the monomers having a urethane group or an aromatic ring include the esters between unsaturated carboxylic acids such as acrylic acid, methacrylic acid, itaconic acid, crotonic acid, and isocrotonic acid and aliphatic polyvalent alcohols, and amides between unsaturated carboxylic acids and polyvalent amines.

Examples of the esters between unsaturated carboxylic acids and aliphatic polyvalent alcohols set forth above include, as (meth)acrylate esters, ethylene glycol di(meth)acrylate, polyethylene glycol di(meth)acrylate having 2 to 18 ethylene groups such as diethylene glycol di(meth)acrylate, triethylene glycol di(meth)acrylate, tetraethylene glycol di(meth)acrylate, nonaethylene glycol di(meth)acrylate, dodecaethylene glycol di(meth)acrylate, and tetradecaethylene glycol di(meth)acrylate; propylene glycol di(meth)acrylate having 2 to 18 propylene groups such as dipropylene glycol di(meth)acrylate, tripropylene glycol di(meth)acrylate, tetrapropylene glycol di(meth)acrylate, and dodecapropylene glycol di(meth)acrylate; neopentyl glycol di(meth)acrylate, ethyleneoxide modified neopentyl glycol di(meth)acrylate, propyleneoxide modified neopentyl glycol di(meth)acrylate, trimethylolpropane tri(meth)acrylate, trimethylolpropane di(meth)acrylate, trimethylolpropane tri(meth)acryloyloxypropyl ether, trimethylolethane tri(meth)acrylate, 1,3-propanediol di(meth)acrylate, 1,3-butanediol di(meth)acrylate, 1,4-butanediol di(meth)acrylate, 1,6-hexanediol di(meth)acrylate, tetramethylene glycol di(meth)acrylate, 1,4-cyclohexanediol di(meth)acrylate, 1,2,4-butanetriol tri(meth)acrylate, 1,5-pentanediol (meth)acrylate, pentaerythritol di(meth)acrylate, pentaerythritol tri(meth)acrylate, pentaerythritol tetra(meth)acrylate, dipentaerythritol penta(meth)acrylate, dipentaerythritol hexa(meth)acrylate, sorbitol tri(meth)acrylate, sorbitol tetra(meth)acrylate, sorbitol penta(meth)acrylate, sorbitol hexa(meth)acrylate, dimethylol dicyclopentane di(meth)acrylate, tricyclodecan di(meth)acrylate, neopentylglycol modified trimethylolpropane di(meth)acrylate; di(meth)acrylates of alkyleneglycol chains having at least each one of ethyleneglycol chain and propyleneglycol chain such as those compounds described in International Publication No. WO 01/98832; tri(meth)acrylate of trimethylolpropane added by at least one of ethylene oxide and propylene oxide; polybutylene glycol di(meth)acrylate, glycerin di(meth)acrylate, glycerin tri(meth)acrylate, and xylenol di(meth)acrylate.

Among the (meth)acrylates set forth above, preferable in light of easy availability are ethylene glycol di(meth)acrylate, polyethylene glycol di(meth)acrylate, propylene glycol di(meth)acrylate, polypropylene glycol di(meth)acrylate, di(meth)acrylates of alkyleneglycol chains having at least each one of ethyleneglycol chain and propyleneglycol chain, trimethylolpropane tri(meth)acrylate, pentaerythritol tetra(meth)acrylate, pentaerythritol triacrylate, pentaerythritol di(meth)acrylate, dipentaerythritol penta(meth)acrylate, dipentaerythritol hexa(meth)acrylate, glycerin tri(meth)acrylate, glycerin di(meth)acrylate, 1,3-propanediol di(meth)acrylate, 1,2,4-butanetriol tri(meth)acrylate, 1,4-cyclohexanediol di(meth)acrylate, 1,5-pentanediol (meth)acrylate, neopentyl glycol di(meth)acrylate, and tri(meth)acrylate of trimethylolpropane added by ethylene oxide.

Examples of the esters between the itaconic acid and the aliphatic polyvalent alcohol compounds i.e. itaconate set forth above include ethylene glycol diitaconate, propylene glycol diitaconate, 1,3-butanediol diitaconate, 1,4-butanediol diitaconate, tetramethylene glycol diitaconate, pentaerythritol diitaconate, and sorbitol tetraitaconate.

Examples of the esters between the crotonic acid and the aliphatic polyvalent alcohol compounds i.e. crotonate set forth above include ethylene glycol dicrotonate, tetramethylene glycol dicrotonate, pentaerythritol dicrotonate, and sorbitol tetradicrotonate.

Examples of the esters between the isocrotonic acid and the aliphatic polyvalent alcohol compounds i.e. isocrotonate set forth above include ethylene glycol diisocrotonate, pentaerythritol diisocrotonate, and sorbitol tetraisocrotonate.

Examples of the esters between the maleic acid and the aliphatic polyvalent alcohol compounds i.e. maleate set forth above include ethylene glycol dimaleate, triethylene glycol dimaleate, pentaerythritol dimaleate, and sorbitol tetramaleate.

Examples of the amides derived from the polyvalent amine compounds and the unsaturated carboxylic acids set forth above include methylenebis(meth)acrylamide, ethylenebis(meth)acrylamide, 1,6-hexamethylenebis(meth)acrylamide, octamethylenebis(meth)acrylamide, diethylenetriamine tris(meth)acrylamide, and diethylenetriamine bis(meth)acrylamide.

As for the polymerizable monomers set forth above, the following compounds may be exemplified additionally: compounds that are obtained by adding α,β-unsaturated carboxylic acids to compounds containing a glycidyl group such as butanediol-1,4-diglycidylether, cyclohexane dimethanol glycidylether, ethyleneglycol diglycidylether, diethyleneglycol diglycidylether, dipropyleneglycol diglycidylether, hexanediol diglycidylether, trimethylolpropane triglycidylether, pentaerythritol tetraglycidylether, and glycerin triglycidylether; polyester acrylates and polyester (meth)acrylate oligomers described in JP-A No. 48-64183, and JP-B Nos. 49-43191 and 52-30490; multifunctional acrylate or methacrylate such as epoxy acrylates obtained from the reaction between methacrylic acid epoxy compounds such as butanediol-1,4-diglycidylether, cyclohexane dimethanol glycidylether, diethyleneglycol diglycidylether, dipropyleneglycol diglycidylether, hexanediol diglycidylether, trimethylolpropane triglycidylether, pentaerythritol tetraglycidylether, and glycerin triglycidylether; photocurable monomers and oligomers described in Journal of Adhesion Society of Japan, Vol. 20, No. 7, pp. 300-308 (1984); allyl esters such as diallyl phthalate, diallyl adipate, and diallyl malonate; diallyl amides such as diallyl acetamide; cationic polymerizable divinylethers such as butanediol-1,4-divinylether, cyclohexane dimethanol divinylether, ethyleneglycol divinylether, diethyleneglycol divinylether, dipropyleneglycol divinylether, hexanediol divinylether, trimethylolpropane trivinylether, pentaerythritol tetravinylether, and glycerin vinylether; epoxy compounds such as butanediol-1,4-diglycidylether, cyclohexane dimethanol glycidylether, ethyleneglycol diglycidylether, diethyleneglycol diglycidylether, dipropyleneglycol diglycidylether, hexanediol diglycidylether, trimethylolpropane triglycidylether, pentaerythritol tetraglycidylether, and glycerin triglycidylether; oxetanes such as 1,4-bis[(3-ethyl-3-oxetanylmethoxy)methyl]benzene and those described in International Publication No. WO 01/22165; compounds having two or more of ethylenically unsaturated double bonds of different types such as N-p-hydroxyethyl-β-methacrylamide ethylacrylate, N,N-bis(β-methacryloxyethyl)acrylamide, acrylmethacrylate.

Examples of vinyl esters set forth above include divinyl succinate and divinyl adipate.

These polyfunctional monomers or oligomers may be used alone or in combination.

The polymerizable monomers set forth above may be combined with a polymerizable compound having one polymerizable group in the molecule, i.e. monofunctional monomer.

Examples of the mono functional monomers include the compounds exemplified as the raw materials for the binder set forth above, dibasic monofunctional monomer such as mono-(meth)acryloyloxyalkylester, mono-hydroxyalkylester, and γ-chloro-β-hydroxypropyl-β′-methacryloyloxyethyl-o-phthalate, and the compounds described in JP-A No. 06-236031, JP-B Nos. 2744643 and 2548016, and International Publication No. WO 00/52529.

Preferably, the content of the polymerizable compound in the photosensitive layer is 5 to 60% by mass, more preferably is 15 to 60% by mass, and still more preferably is 20 to 50% by mass.

When the content is less than 5% by mass, the strength of the tent film may be lower, and when the content is more than 90% by mass, the edge fusion at storage period is insufficient and bleeding trouble may be induced.

The content of the polyfunctional monomer having two or more polymerizable groups set forth above in the molecule is preferably 5 to 100% by mass, more preferably is 20 to 100% by mass, still more preferably is 40 to 100% by mass.

### <<Photopolymerization Initiator>>

The photopolymerization initiator may be properly selected from conventional ones without particular limitations as long as having the property to initiate polymerization; preferably is the initiator that exhibits photosensitivity from ultraviolet rays to visual lights. The initiator may be an active substance that generates a radical due to an effect with a photo-exited photosensitizer, or a substance that initiates cation polymerization depending on the monomer species.

Preferably, the photopolymerization initiator contains at least one component that has a molecular extinction coefficient of about 50 M⁻¹cm⁻¹ in a range of about 300 nm to 800 nm, more preferably about 330 nm to 500 nm.

Examples of the photopolymerization initiator include halogenated hydrocarbon derivatives such as having a triazine skeleton or an oxadiazole skeleton, hexaaryl-biimidazols, oxime derivatives, organic peroxides, thio compounds, ketone compounds, aromatic onium salts, acylphosphine oxides, and metallocenes. Among these compounds, halogenated hydrocarbon compounds having a triazine skeleton, oxime derivatives, ketone compounds, and hexaaryl-biimidazol compounds are preferable from the view points of sensitivity of photosensitive layers, self stability, adhesive ability between the photosensitive layers and substrates for printed wiring boards.

Examples of the hexaaryl-biimidazol compounds include
2,2′-bis(2-chlorophenyl)-4,4′,5,5′-tetraphenyl-biimidazole,
2,2′-bis(o-fluorophenyl)-4,4′,5,5′-tetraphenyl-biimidazole,
2,2′-bis(o-bromophenyl)-4,4′,5,5′-tetraphenyl-biimidazole,
2,2′-bis(2,4-dichlorophenyl)-4,4′,5,5′-tetraphenyl-biimidazole,
2,2′-bis(2-chlorophenyl)-4,4′,5,5′-tetra(3-methoxyphenyl)biimidazole,
2,2′-bis(2-chlorophenyl)-4,4′,5,5′-tetra(4-methoxyphenyl)biimidazole,
2,2′-bis(4-methoxyphenyl)-4,4′,5,5′-tetraphenyl-biimidazole,
2,2′-bis(2,4-dichlorophenyl)-4,4′,5,5′-tetraphenyl-biimidazole,
2,2′-bis(2-nitrophenyl)-4,4′,5,5′-tetraphenyl-biimidazole,
2,2′-bis(2-methylphenyl)-4,4′,5,5′-tetraphenyl-biimidazole,
2,2′-bis(2-trifluoromethylphenyl)-4,4′,5,5′-tetraphenyl-biimidazole, and the compounds described in International Publication No. WO 00/52529.

The biimidazoles set forth above can be easily prepared by the methods described, for example, in Bulletin of the Chemical Society of Japan, 33, 565 (1960) and Journal of Organic Chemistry, 36, [16], 2262 (1971).

Examples of the halogenated hydrocarbon compounds having a triazine skeleton include the compounds described in Bulletin of the Chemical Society of Japan, by Wakabayasi, 42, 2924 (1969); GB Pat. No. 1388492; JP-A No. 53-133428; DE Pat. No. 3337024; Journal of Organic Chemistry, by F. C. Schaefer et. al. 29, 1527 (1964); JP-A Nos. 62-58241, 5-281728, and 5-34920; and U.S. Pat. No. 4,212,976.

Examples of the compounds described in Bulletin of the Chemical Society of Japan, by Wakabayasi, 42, 2924 (1969) set forth above include
2-phenyl-4,6-bis(trichloromethyl)-1,3,5-triazine,
2-(4-chlorophenyl)-4,6-bis(trichloromethyl)-1,3,5-triazine,
2-(4-tolyl)-4,6-bis(trichloromethyl)-1,3,5-triazine,
2-(4-methoxyphenyl)-4,6-bis(trichloromethyl)-1,3,5-triazine,
2-(2,4-dichlorophenyl)-4,6-bis(trichloromethyl)-1,3,5-triazine,
2,4,6-tris(trichloromethyl)-1,3,5-triazine,
2-methyl-4,6-bis(trichloromethyl)-1,3,5-triazine,
2-n-nonyl-4,6-bis(trichloromethyl)-1,3,5-triazine, and
2-(α,α,β-trichloroethyl)-4,6-bis(trichloromethyl)-1,3,5-triazine.

Examples of the compounds described in GB Pat. No. 1388492 set forth above include 2-styryl-4,6-bis(trichloromethyl)-1,3,5-triazine, 2-(4-methylstyryl)-4,6-bis(trichloromethyl)-1,3,5-triazine, 2-(4-methoxystyryl)-4,6-bis(trichloromethyl)-1,3,5-triazine, and 2-(4-methoxystyryl)-4-aminotrichloromethyl-1,3,5-triazine.

Examples of the compounds described in JP-A No. 53-133428 set forth above include 2-(4-methoxynaphtho-1-yl)-4,6-bistrichloromethyl-1,3,5-triazine, 2-(4-ethoxynaphtho-1-yl)-4,6-bistrichloromethyl-1,3,5-triazine, 2-[4-(2-ethoxyethyl)-naphtho-1-yl]-4,6-bistrichloromethyl-1,3,5-triazine, 2-(4,7-dimethoxynaptho-1-yl)-4,6-bistrichloromethyl-1,3,5-triazine, and 2-(acenaphtho-5-yl)-4,6-bistrichloromethyl-1,3,5-triazine.

Examples of the compounds described in DE Pat. No. 3337024 set forth above include 2-(4-styrylphenyl)-4,6-bis(trichloromethyl)-1,3,5-triazine, 2-(4-(4-methoxystyryl)phenyl)-4,6-bis(trichloromethyl)-1,3,5-triazine, 2-(1-naphthylvinylenephenyl)-4,6-bis(trichloromethyl)-1,3,5-triazine, 2-chlorostyrylphenyl-4,6-bis(trichloromethyl)-1,3,5-triazine, 2-(4-thiophene-2-vinylenephenyl)-4,6-bis(trichloromethyl)-1,3,5-triazine, 2-(4-thiophene-3-vinylenephenyl)-4,6-bis(trichloromethyl)-1,3,5-triazine, 2-(4-furan-2-vinylenephenyl)-4,6-bis(trichloromethyl)-1,3,5-triazine, and 2-(4-benzofuran-2-vinylenephenyl)-4,6-bis(trichloromethyl)-1,3,5-triazine.

Examples of the compounds described in Journal of Organic Chemistry, by F. C. Schaefer et. al. 29, 1527 (1964) set forth above include
2-methyl-4,6-bis(tribromomethyl)-1,3,5-triazine,
2,4,6-tris(tribromomethyl)-1,3,5-triazine, 2,4,6-tris(dibromomethyl)-1,3,5-triazine,
2-amino-4-methyl-6-tribromomethyl-1,3,5-triazine and
2-methoxy-4-methyl-6-trichloromethyl-1,3,5-triazine.

Examples of the compounds described in JP-A No. 62-58241 set forth above include 2-(4-phenylethylphenyl)-4,6-bis(trichloromethyl)-1,3,5-triazine, 2-(4-naphthyl-1-ethynylphenyl)-4,6-bis(trichloromethyl)-1,3,5-triazine, 2-(4-(4-triethynyl)phenyl-4,6-bis(trichloromethyl)-1,3,5-triazine, 2-(4-(4-methoxyphenyl)ethynylphenyl)-4,6-bis(trichloromethyl)-1,3,5-triazine, 2-(4-(4-isopropylphenylethynyl)phenyl)-4,6-bis(trichloromethyl)-1,3,5-triazine, and 2-(4-(4-ethylphenylethynyl)phenyl)-4,6-bis(trichloromethyl)-1,3,5-triazine.

Examples of the compounds described in JP-A No. 05-281728 set forth above include 2-(4-trifluoromethylphenyl)-4,6-bis(trichloromethyl)-1,3,5-triazine, 2-(2,6-difluorophenyl)-4,6-bis(trichloromethyl)-1,3,5-triazine, 2-(2,6-dichlorophenyl)-4,6-bis(trichloromethyl)-1,3,5-triazine, and 2-(2,6-dibromophenyl)-4,6-bis(trichloromethyl)-1,3,5-triazine.

Examples of the compounds described in JP-A No. 5-34920 set forth above include 2,4-bis(trichloromethyl)-6-[4-(N,N-diethoxycarbonylmethylamino)-3-bromophenyl]-1,3,5-triazine, trihalomethyl-s-triazine compounds described in U.S. Pat. No. 4,239,850, and also 2,4,6-tris(trichloromethyl)-s-triazine, and 2-(4-chlorophenyl)-4,6-bis(tribromomethyl)-s-triazine.

Examples of the compounds described in U.S. Pat. No. 4,212,976 set forth above include the compounds having an oxadiazole skeleton such as
2-trichloromethyl-5-phenyl-1,3,4-oxadiazole,
2-trichloromethyl-5-(4-chlorophenyl)-1,3,4-oxadiazole,
2-trichloromethyl-5-(1-naphthyl)-1,3,4-oxadiazole,
2-trichloromethyl-5-(2-naphthyl)-1,3,4-oxadiazole,
2-tribromomethyl-5-phenyl-1,3,4-oxadiazole,
2-tribromomethyl-5-(2-naphthyl)-1,3,4-oxadiazole,
2-trichloromethyl-5-styryl-1,3,4-oxadiazole,
2-trichloromethyl-5-(4-chlorostyryl)-1,3,4-oxadiazole,
2-trichloromethyl-5-(4-methoxystyryl)-1,3,4-oxadiazole,
2-trichloromethyl-5-(1-naphthyl)-1,3,4-oxadiazole,
2-trichloromethyl-5-(4-n-butoxystyryl)-1,3,4-oxadiazole, and
2-tribromomethyl-5-styryl-1,3,4-oxadiazole.

Examples of the oxime derivatives set forth above include the compounds expressed by the following formulas (39) to (72).

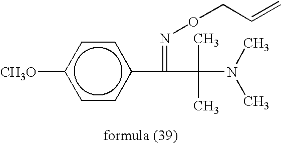

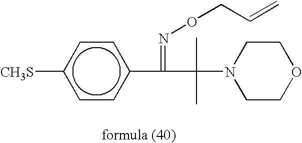

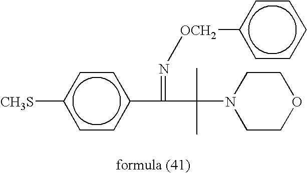

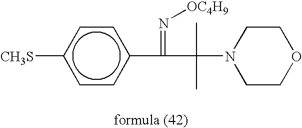

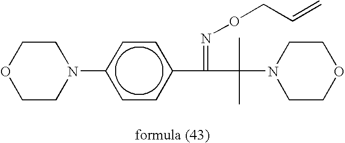

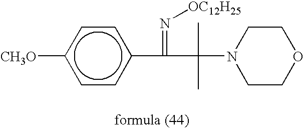

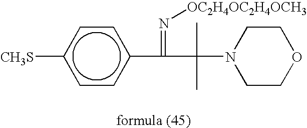

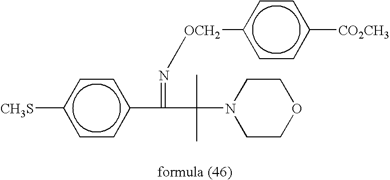

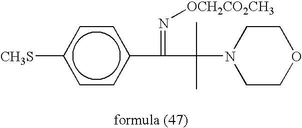

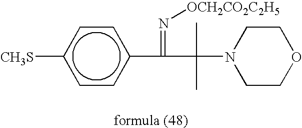

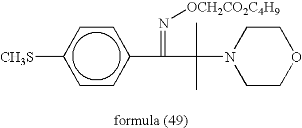

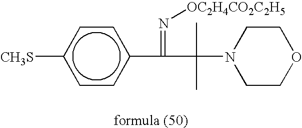

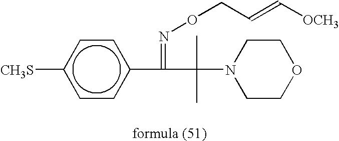

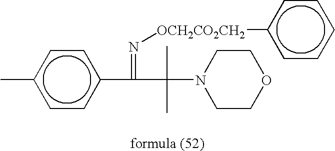

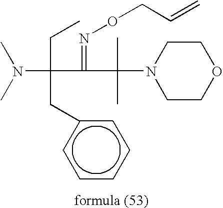

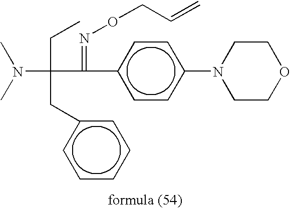

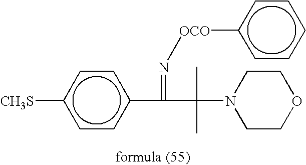

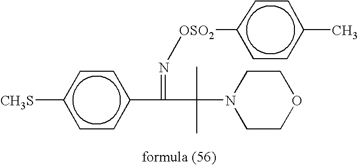

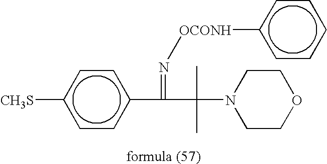

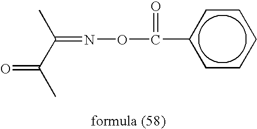

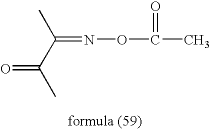

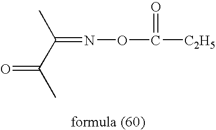

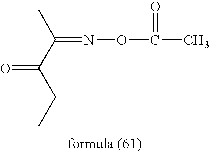

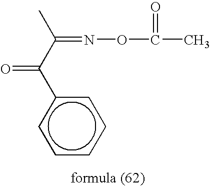

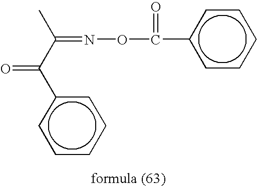

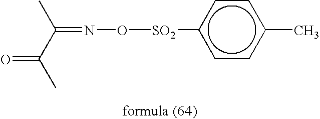

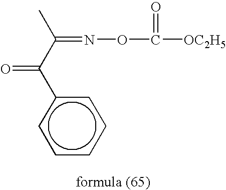

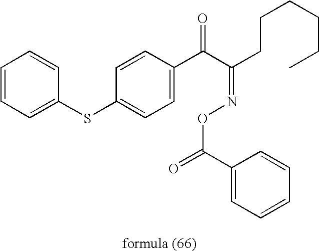

R

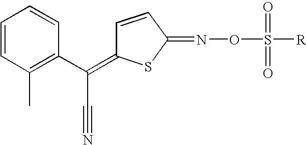

| | |
|---|---|
| formula (67) | n-₃H₇ |
| formula (68) | n-C₈H₁₇ |
| formula (69) | camphor |
| formula (70) | p-CH₃C₆H₄ |

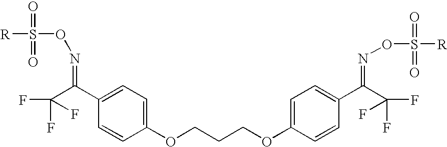

| | |
|---|---|
| formula (71) | n-C₃H₇ |
| formula (72) | p-CH₃C₆H₄ |

Examples of the ketone compounds set forth above include benzophenone, 2-methylbenzophenone, 3-methylbenzophenone, 4-methylbenzophenone, 4-methoxybenzophenone, 2-chlorobenzophenone, 4-chlorobenzophenone, 4-bromobenzophenone, 2-carboxybenzophenone, 2-ethoxycarbonylbenzophenone, benzophenone-tetracarboxylic acid and its tetramethyl ester; 4,4′-bis(dialkylamino)benzophenones such as 4,4′-bis(dimethylamino)benzophenone, 4,4′-bis(cyclohexylamino)benzophenone, 4,4′-bis(diethylamino)benzophenone, 4,4′-bis(dihydroxyethylamino)benzophenone, 4-methoxy-4′-dimethylaminobenzophenone, 4,4′-dimethoxybenzophenone, and 4-dimethylaminobenzophenone; 4-dimethylaminoacetophenone, benzyl, anthraquinone, 2-tert-butylanthraquinone, 2-methylanthraquinone, phenanthraquinone, xanthone, thioxanthone, 2-chlorothioxanthone, 2,4-diethylthioxanthone, fluorene, 2-benzyl-dimethylamino-1-(4-morpholinophenyl)-1-butanone, 2-methyl-1-[4-(methylthio)phenyl]-2-morpholino-1-propanone, 2-hydroxy-2-methyl-[4-(1-methylvinyl)phenyl]propanol oligomer, benzoin; benzoin ethers such as benzoin methylether, benzoin ethylether, benzoin propylether, benzoin isopropylether, benzoin phenylether, and benzyl dimethyl ketal; acridone, chloroacridone, N-methylacridone, N-butylacridone, and N-butylchloroacridone.

Examples of the metallocenes include bis(η5-2,4-cyclopentadiene-1-yl)-bis(2,6-difluoro-3-(1H-pyrrole-1-yl)-phenyl)titanium, η5-cyclopentadienyl-η6-cumenyl-iron(1+)-hexafluorophosphate(1−), and the compounds described in JP-A No. 53-133428, JP-B Nos. 57-1819 and 57-6096, and U.S. Pat. No. 3,615,455.

As for photopolymerization initiators other than set forth above, the following substances are further exemplified: acridine derivatives such as 9-phenyl acridine and 1,7-bis(9,9′-acridinyl)heptane; polyhalogenated compounds such as carbon tetrabromide, phenyltribromosulfone, and phenyltrichloromethylketone; coumarins such as 3-(2-benzofuroyl)-7-diethylaminocoumarin, 3-(2-benzofuroyl)-7-(1-pyrrolidinyl)coumarin, 3-benzoyl-7-diethylaminocoumarin, 3-(2-methoxybenzoyl)-7-diethylaminocoumarin, 3-(4-dimethylaminobenzoyl)-7-diethylaminocoumarin, 3,3′-carbonylbis(5,7-di-n-propoxycoumarin), 3,3′-carbonylbis(7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, and 7-benzotriazol-2-ylcoumarin, and also the coumarin compounds described in JP-A Nos. 5-19475, 7-271028, 2002-363206, 2002-363207, 2002-363208, and 2002-363209; amines such as ethyl 4-dimethylamibenzoate, n-butyl 4-dimethylamibenzoate, phenethyl 4-dimethylamibenzoate, 2-phthalimide 4-dimethylamibenzoate, 2-methacryloyloxyethyl-4-dimethylamibenzoate, pentamethylene-bis(4-dimethylaminobenzoate), phenethyl 3-dimethylamibenzoate, pentamethylene esters, 4-dimethylamino benzaldehyde, 2-chloro-4-dimethylamino benzaldehyde, 4-dimethylaminobenzyl alcohol, ethyl(4-dimethylaminobenzoyl)acetate, 4-piperidine acetophenone, 4-dimethyamino benzoin, N,N-dimethyl-4-toluidine, N,N-diethyl-3-phenetidine, tribenzylamine, dibenzylphenylamine, N-methyl-N-phenylbenzylamine, 4-bromo-N,N-diethylaniline, and tridodecyl amine; amino fluorans such as ODB and ODBII; leucocrystal violet; acylphosphine oxides such as bis(2,4,6-trimethylbenzoyl)phenylphosphine oxide, bis(2,6-dimethylbenzoyl)-2,4,4-trimethyl-pentylphenylphosphine oxide, and Lucirin TPO.

In addition, as for still other photopolymerization initiator, the following substances are exemplified: vicinal polyketaldonyl compounds as described in U.S. Pat. No. 2,367,660; acyloin ether compounds as described in U.S. Pat. No. 2,448,828; aromatic acyloin compounds substituted with an α-hydrocarbon as described in U.S. Pat. No. 2,722,512; polynucleic quinone compounds as described in US Pat. Nos. 3,046,127 and 2,951,758; various substances described in JP-A No. 2002-229194 such as organic boron compounds, radical generators, triarylsulfonium salts e.g. salts with hexafluoroantimony or hexafluorophosphate, phosphonium salts e.g. (phenylthiophenyl)diphenylsulfonium (effective as cation polymerization initiator), and onium salt compounds described in International Publication No. WO 01/71428.

These photopolymerization initiators may be used alone or in combination. The combination of two or more photopolymerization initiators may be for example the combination of hexaaryl-biimidazol compounds and 4-amino ketones described in U.S. Pat. No. 3,549,367; combination of benzothiazole compounds and trihalomethyl-s-triazine compounds as described in JP-B No. 5148516; combination of aromatic ketone compounds such as thioxanthone and hydrogen donating substance such as dialkylamino-containing compounds or phenol compounds; combination of hexaaryl-biimidazol compounds and titanocens; and combination of coumarins, tinanocens, and phenyl glycines.

The content of the photopolymerization initiator in the photosensitive layer is preferably 0.1 to 30% by mass, more preferably is 0.5 to 20% by mass, and still more preferably is 0.5 to 15% by mass.

### <<Other Components>>

As for the other components, photosensitizer, plasticizer, coloring agent, and colorant are exemplified; in addition, the other auxiliaries such as adhesion promoter on substrate surface, pigment, conductive particles, filler, defoamer, fire retardant, leveling agent, peeling promoter, antioxidant, perfume, thermocrosslinker, adjustor of surface tension, chain transfer agent, and the like may be utilized together with. By means of incorporating these components properly, desirable properties of the pattern forming material such as stability with time, photographic property, developing property, film property, and the like may be tailored.

### —Photosensitizer—

The photosensitizer may be properly selected depending on the types of laser beam utilized in the pattern forming process and the like.

The photosensitizer may be exited by active irradiation, and may generate a radical, an available acidic group and the like through interaction with other substances such as radical generators and acid generators by transferring energy or electrons.

The photosensitizer is not particularly limited and may be suitably selected from among those known in the art; examples of the photosensitizer include polynuclear aromatics such as pyrene, perylene, and triphenylene; xanthenes such as fluorescein, Eosine, erythrosine, rhodamine B, and Rose Bengal; cyanines such as indocarbocianine, thiacarbocianine, and oxacarbocianine; merocianines such as merocianine and carbomerocianine; thiazins such as thionine, methylene blue, and toluidine blue; acridines such as acridine orange, chloroflavine, and acriflavine; anthraquinones such as anthraquinone; scariums such as scarium; acridones such as acridone, chloroacridone, N-methylacridone, N-butylacridone, N-butyl-chloroacridone; coumarins such as 3-(2-benzofuroyl)-7-diethylaminocoumarin, 3-(2-benzofuroyl)-7-(1-pyrrolidinyl)coumarin, 3-benzofuroyl-7-diethylaminocoumarin, 3-(2-methoxybenzoyl)-7-diethylaminocoumarin, 3-(4-dimethylaminobenzoyl)-7-diethylaminocoumarin, 3,3′-carbonylbis(5,7-di-n-propoxycoumarin), 3,3′-carbonylbis(7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, and also the coumarin compounds described in JP-A Nos. 5-19475, 7-271028, 2002-363206, 2002-363207, 2002-363208, and 2002-363209.

As for the combination of the photopolymerization initiator and the photosensitizer, the initiating mechanism that involves electron transfer may be exemplified such as combinations of (1) an electron donating initiator and a photosensitizer dye, (2) an electron accepting initiator and a photosensitizer dye, and (3) an electron donating initiator, a photosensitizer dye, and an electron accepting initiator (ternary mechanism) as described in JP-A No. 2001-305734.

The content of the photosensitizer is preferably 0.05 to 30% by mass based on the entire composition of the photosensitive resin, more preferably is 0.1 to 20% by mass, and still more preferably is 0.2 to 10% by mass.

When the content is less than 0.05% by mass, the sensitivity toward the active energy ray may decrease, longer period may be required for exposing process, and the productivity tends to lower, and when the content is more than 30% by mass, the photosensitizer may precipitate from the photosensitive layer during preservation period.

### —Thermopolymerization Inhibitor—

The thermopolymerization inhibitor may be used for the photosensitive layer to prevent thermal polymerization and polymerization over time of the polymerizable compound in the photosensitive layer.

Examples of the thermopolymerization inhibitor include 4-methoxyphenol, hydroquinone, alkyl or aryl group-substituted hydroquinone, t-butyl catechol, pyrogallol, 2-hydroxybenzophenone, 4-methoxy-2-hydroxybenzophenone, cuprous chloride, phenothiazine, naphthylamine, β-naphthol, 2,6-di-t-butyl-4-cresol, 2,2′-methylenbis(4-methyl-6-t-butylphenol), pyridine, nitrobenzene, dinitrobenzene, picric acid, 4-toluidine, methylene blue, reactants between copper and organic chelate agent, methyl salicylate, phenothiazine, nitroso compounds, and chelates between nitroso compound and Al.

The content of the thermopolymerization inhibitor is preferably 0.001% by mass to 5% by mass relative to the polymerizable compound of the photosensitive layer, more preferably 0.005% by mass to 2% by mass, and particularly preferably 0.01% by mass to 1% by mass.

When the content of the thermopolymerization inhibitor is less than 0.001% by mass, the storage stability may be lowered. When the content is more than 5% by mass, the sensitivity to active energy line may be lowered.

### —Plasticizer—

The plasticizer set forth above may be incorporated into in order to adjust the film property i.e. flexibility of the photosensitive layer.

Examples of the plasticizer include phthalic acid esters such as dimethylphthalate, dibutylphthalate, diisobutylphthalate, diheptylphthalate, dioctylphthalate, dicyclohexylphthalate, ditridecylphthalate, butylbenzylphthalate, diisodecylphthalate, diphenylphthalate, diallylphthalate, and octylcaprylphthalate; glycol esters such as triethyleneglycol diacetate, tetraethyleneglycol diacetate, dimethylglycose phthalate, ethylphthalyl ethylglycolate, methylphthalyl ethylglycolate, buthylphthalyl buthylglycolate, triethylene glycol dicaprylate; phosphoric acid esters such as tricresylphosphate and triphenylphosphate; amides such as 4-toluenesulfone amide, benzenesulfone amide, N-n-butylsulfone amide, and N-n-aceto amide; aliphatic dibasic acid esters such as diisobutyl adipate, dioctyl adipate, dimethyl sebacate, dibutyl sebacate, dioctyl sebacate, and dibutyl maleate; triethyl citrate, tributyl citrate, glycerin triacetyl ester, butyl laurate, 4,5-diepoxy-cyclohexane-1,2-dicarboxylic acid dioctyl; and glycols such as polyethylene glycol and polypropylene glycol.

The content of the plasticizer set forth above is preferably 0.1 to 50% by mass, more preferably is 0.5 to 40% by mass, and still more preferably is 1 to 30% by mass.

### —Coloring Agent—

The coloring agent may be utilized to provide visible images or to afford developing property on the photosensitive layer set forth above after exposure.

Examples of the coloring agent include aminotriarylmethanes such as tris(4-dimethylaminophenyl)methane (leucocrystal violet), tris(4-diethylaminophenyl)methane, tris(4-dimethylamino-2-methylphenyl)methane, tris(4-diethylamino-2-methylphenyl)methane, bis(4-dibutylaminophenyl)-[4-(2-cyanoethyl)methylaminophenyl]methane, bis(4-dimethylaminophenyl)-2-quinolylmethane, and tris(4-dipropylaminophenyl)methane; aminoxanthenes such as 3,6-bis(diethylamino)-9-phenylxanthene and 3-amino-6-dimethylamino-2-methyl-9-(o-chlorophenyl)xanthene; aminothioxanthenes such as 3,6-bis(diethylamino)-9-(2-ethoxycarbonylphenyl)thioxanthene and 3,6-bis(dimethylamino)thioxanthene; amino-9,10-dihydroacridines such as 3,6-bis(diethylamino)-9,10-dihydro-9-phenylacridine and 3,6-bis(benzylamino)-9,10-dihydro-9-methylacridine; aminophenoxazines such as 3,7-bis(diethylamino)phenoxazines; aminophenothiazines such as 3,7-bis(ethylamino)phenothiazine; aminodihydrophenazines such as 3,7-bis(diethylamino)-5-hexyl-5,10-dihydrophenazine; aminophenylmethanes such as bis(4-dimethylaminophenyl)anilinomethane; aminohydrocinnamic acids such as 4-amino-4′-dimethylaminodiphenylamine and 4-amino-α,β-dicyanohydrocinnamate methyl ester; hydrazines such as 1-(2-naphthyl)-2-phenylhydrazine; amino-2,3-dihydroanthraquinones such as 1,4-bis(ethylamino)-2,3-dihydroanthraquinone; phenethylanilines such as N,N-diethyl-p-phenethylaniline; acyl derivatives of leuco dyes containing a basic NH group such as 10-acetyl-3,7-bis(dimethylamino)phenothiazine; leuco-like compounds with no oxidizable hydrogen and capable of being oxidized into colored compounds such as tris(4-diethylamino-2-tolyl)ethoxycarbonylmethane; leucoindigoid dyes; organic amines capable of being oxidized to colored forms as described in U.S. Pat. Nos. 3,042,515 and 3,042,517 such as 4,4′-ethylenediamine, diphenylamine, N,N-dimethylaniline, 4,4′-methylenediaminetriphenylamine, and N-vinylcarbazole. Among these coloring agents, triarylmethanes such as leucocrystal violet are preferable in particular.

In addition, it is known that the coloring agents set forth above may be combined with halogenated compounds in order to develop a color from the leuco compounds.

Examples of the halogenated compounds include halogenated hydrocarbons such as tetrabromocarbon, iodoform, ethylene bromide, methylene bromide, amyl bromide, isoamyl bromide, amyl iodide, isobutylene bromide, butyl iodide, diphenylmethyl bromide, hexachloromethane, 1,2-dibromoethane, 1,1,2,2-tetrabromoethane, 1,2-dibromo-1,1,2-trichloroethane, 1,2,3-tribromopropane, 1-bromo-4-chlorobutane, 1,2,3,4-tetrabromobutane, tetrachlorocyclopropene, hexachlorocyclopentadiene, dibromocyclohexane, and 1,1,1-trichloro-2,2-bis(4-chlorophenyl)ethane; halogenated alcohol compounds such as 2,2,2,-trichloroethanol, tribromoethanol, 1,3-dichloro-2-propanol, 1,1,1-trichloro-2-propanol, di(iodohexamethylene)aminoisopropanol, tribromo-tert-butyl alcohol, and 2,2,3-trichlorobutane-1,4-diol; halogenated carbonyl compounds such as 1,1-dichloroacetone, 1,3-dichloroacetone, hexachloroacetone, hexabromoacetone, 1,1,3,3-tetrachloroacetone, 1,1,1-trichloroacetone, 3,4-dibromo-2-butanone, and 1,4-dichloro-2-butanone-dibromocyclohexanone; halogenated ether compounds such as 2-bromoethyl methylether, 2-bromoethyl ethylether, di(2-bromoethyl)ether, and 1,2-dichloroethyl ethylether; halogenated ester compounds such as bromoethyl acetate, ethyl trichloroacetate, trichloroethyl trichloroacetate, homo- and co-polymers of 2,3-dibromopropyl acrylate, trichloroethyl dibromopropionate, and ethyl α,β-dichloroacrylate; halogenated amide compounds such as chloroacetamide, bromoacetamide, dichloroacetamide, trichloroacetamide, tribromoacetamide, trichloroethyltrichloroacetamide, 2-bromoisopropionamide, 2,2,2-trichloropropionamide, N-chlorosuccinimide, and N-bromosuccinimide; compounds containing a sulfur and/or phosphorus atom such as tribromomethyl phenylsulfone, 4-nitrophenyltribromo methylsulfone, 4-chlorophenyltribromo methylsulfone, tris(2,3-dibromopropyl)phosphate, and 2,4-bis(trichloromethyl)-6-phenyltriazole.

In the organic halogenated compounds, preferably are those containing two or more halogen atoms that are attached to one carbon atom, more preferably are those containing three halogen atoms that are attached to one carbon atom. The organic halogenated compounds may be used alone or in combination. Among these halogenated compounds, tribromomethyl phenylsulfone and 2,4-bis(trichloromethyl)-6-phenyltriazole are preferable.

The content of the coloring agent is preferably 0.01 to 20% by mass based on the total components in the photosensitive layer, more preferably is 0.05 to 10% by mass, and still more preferably is 0.1 to 5% by mass. The content of the halogenated compound is preferably 0.001 to 5% by mass based on the total components in the photosensitive layer, more preferably is 0.005 to 1% by mass.

### —Dye—

To the photosensitive layer set forth above, a dye may be incorporated into in order to add a color so as to make easy the handling or to enhance the storage stability.

Examples of the dye include Brilliant Green, eosin, Ethyl Violet, Erythrosine B, Methyl Green, Crystal Violet, Basic Fuchsine, phenolphthalein, 1,3-diphenyltriazine, Alizarin Red S, Thymolphthalein, Methyl Violet 2B, Quinaldine Red, Rose Bengale, Metanil-Yellow, Thymolsulfophthalein, Xylenol Blue, Methyl Orange, Orange IV, diphenyl thiocarbazone, 2,7-dichlorofluorescein, Para Methyl Red, Congo Red, Benzopurpurine 4B, α-Naphthyl Red, Nile Blue 2B, Nile Blue A, phenacetarin, Methyl Violet, Malachite Green, Para Fuchsine, Oil Blue #603 (produced by Orient Chemical Industry Co., Ltd.), Rhodamine B, Rhodamine 6G, and Victoria Pure Blue BOH. Among these dyes, preferably are cation dyes such as oxalate of Malachite Green and sulfate of Malachite Green. The pair anion of the cation dyes may be residues of organic acid or inorganic acid such as bromic acid, iodic acid, sulfuric acid, phosphoric acid, oxalic acid, methane sulfonic acid, and toluene sulfonic acid.

The content of the dye is preferably 0.001 to 10% by mass based on the total components in the photosensitive layer, more preferably is 0.01 to 5% by mass, and still more preferably is 0.1 to 2% by mass.

### —Adhesion Promoter—

In order to enhance the adhesion between layers or between the pattern forming material and the substrate, so-called adhesion promoters may be employed.

Examples of the adhesion promoters set forth above include those described in JP-A Nos. 5-11439, 5-341532, and 6-43638; specific examples of adhesion promoters include benzimidazole, benzoxazole, benzthiazole, 2-mercaptobenzimidazole, 2-mercaptobenzoxazole, 2-mercaptobenzthiazole, 3-morpholinomethyl-1-phenyl-triazole-2-thion, 3-morpholinomethyl-5-phenyl-oxadiazole-2-thion, 5-amino-3-morpholinomethyl-thiadiazole-2-thion, 2-mercapto-5-methylthio-thiadiazole, triazole, tetrazole, benzotriazole, carboxybenzotriazole, benzotriazole containing an amino group, and silane coupling agents.

The content of the adhesion promoter is preferably 0.001 to 20% by mass based on the total components in the photosensitive layer, more preferably is 0.01 to 10% by mass, and still more preferably is 0.1 to 5% by mass.

The photosensitive layer may contain, as described in “Light Sensitive Systems, chapter 5th, by J. Curser”, organic sulfur compounds, peroxides, redox compounds, azo or diazo compounds, photoreductive dyes, or organic halogen compounds.

Examples of the organic sulfur compounds include di-n-butyldisulfide, dibenzyldisulfide, 2-mercaptobenzthiazole, 2-mercaptobenzoxazole, thiophenol, ethyl trichloromethane sulfonate, and 2-mercaptobenzimidazole.

Examples of the peroxides include di-t-butyl peroxide, benzoyl peroxide, and methyethylketone peroxide.

The redox compounds set forth above are a combination of a peroxide and a reducer such as persulfate ion and ferrous ion, peroxide and ferric ion, or the like.

Examples of azo or diazo compound set forth above include diazoniums such as α,α′-azobis-isobutylonitrile, 2-azobis-2-methylbutylonitrile, and 4-aminodiphenylamine.

Examples of the photoreductive dye set forth above include Rose Bengale, Erythrosine, Eosine, acriflavine, riboflavin, and thionine.

### —Surfactant—

In order to improve surface nonuniformity generated at producing the pattern forming material in the present invention, conventional surfactants may be employed.

The surfactant may be properly selected from anionic surfactants, cationic surfactants, nonionic surfactants, ampholytic surfactants, fluorine-containing surfactant, and the like.

The content of the surfactant is preferably 0.001 to 10% by mass based on the solid content of the photosensitive composition.

When the content is less than 0.001% by mass, the effect to improve the nonuniformity may be insufficient, and when the content is more than 10% by mass, the adhesion ability may be deteriorated.

In addition, as for the surfactants, such polymer surfactants containing fluorine may be preferably exemplified as containing 40% by mass or more of fluorine atoms, having a carbon chain of 3 to 20 carbon atoms, and having a copolymerized component of acrylate or methacrylate containing an aliphatic group of which the hydrogen atoms bonded on the terminal carbon atom to the third of the carbon atom are substituted by fluorine atoms.

The thickness of the photosensitive layer may be properly selected without particular limitations; preferably, the thickness is 0.1 to 10 μm, more preferably is 2 to 50 μm, and still more preferably is 4 to 30 μm.

### [Production of Pattern Forming Material]

The pattern forming material can be produced, for example, as follows.

First, the above-noted various materials are dissolved in water or a solvent, and then emulsified or dispersed therein to prepare a photosensitive resin compound solution.

The solvent for the photosensitive resin composition solution is not particularly limited and may be suitably selected in accordance with the intended use. Examples thereof include alcohols such as methanol, ethanol, n-propanol, isopropanol, n-butanol, sec-butanol, and n-hexanol; ketones such as acetone, methylethylketone, methylisobutyl ketone, cyclohexanon, and diisobutyl ketone; esters such as ethyl acetate, butyl acetate, butyl acetate, acetate-n-amyl, methyl sulfate, ethyl propionate, dimethyl phthalate, ethyl benzoate, and methoxypropyl acetate; aromatic hydrocarbons such as toluene, xylene, benzene, and ethyl benzene; halogenated hydrocarbons such as carbon tetrachloride, trichloroethylene, chloroform, 1,1,1-trichloroethane, methylene chloride, and monochlorobenzene; ethers such as tetrahydrofuran, diethyl ether, ethylene glycol monomethyl ether, ethylene glycol monoethyl ether, and 1-methoxy-2-propanol; dimethylformamide, dimethylacetoamide, dimethylsulfoxide, and sulfolane. Each of these may be used alone or in combination with two or more. Surfactants known in the art may be added to the solvent.

Next, the photosensitive resin composition solution was applied on a surface of a support, and the support surface is dried to form a photosensitive layer on the support, thereby a pattern forming material can be produced.

The method for applying the photosensitive resin composition solution on a support surface is not particularly limited and may be suitably selected in accordance with the intended use. Examples thereof include various coating methods such as spraying method, roll coating method, rotation coating method, slit-coating method, extrusion coating method, curtain-coating method, dye-coating method, gravure coating method, wire-bar coating method, and knife-coating method.

The drying conditions vary depending on used components, type of solvent, usage ratio thereof, and the like, however, the support surface is typically dried at 60° C. to 110° C. for about 30 seconds to 15 minutes.

### <<Support>>

Preferably, the pattern forming material has the photosensitive layer which has been formed on a surface of the support. The support is not particularly limited and may be suitably selected in accordance with the intended use, however, a support which has an exfoliatable photosensitive layer and is excellent in light transmission is preferable, and a support which is further excellent in surface smoothness is more preferable.

Preferably, the support is formed from a transparent synthetic resin; examples of the synthetic resin include polyethylene terephthalate, polyethylene naphthalate, triacetyl cellulose, diacetyl cellulose, polyalkyl(meth)acrylate, poly(meth)acrylate copolymer, polyvinyl chloride, polyvinyl alcohol, polycarbonate, polystyrene, cellophane, polyvinylidene chloride copolymer, polyamide, polyimide, vinylchloride-vinylacetate copolymer, polytetrafluoroethylene, polytrifluoroethylene, cellulose film, and nylon film; among these resins, polyethylene terephthalate is particularly preferable. These resins may be used alone or in combination.

The thickness of the support may be properly selected depending on the application; preferably, the thickness is 2 μm to 150 μm, more preferably is 5 μm to 100 μm, and still more preferably is 8 μm to 50 μm.

The shape of the support may be properly selected depending on the application; preferably the support is formed in an elongated shape. The length of the elongated support is selected from 10 meters to 20,000 meters, for example.

### <<Cushion Layer>>

The pattern forming material may have a cushion layer between a support and a photosensitive layer. The cushion layer is not particularly limited and may be suitably selected in accordance with the intended use, and a cushion layer containing a thermoplastic resin is preferable, for example.

The cushion layer may be swellable in alkaline liquids or soluble in alkaline liquids.

When the cushion layer is swellable in alkaline liquids or soluble in alkaline liquids, the thermoplastic resin is preferably selected, for example, from saponified products of copolymers between ethylene and acrylic acid ester; saponified products of copolymers between styrene and (meth)acrylic acid ester; saponified products of copolymers between vinyltoluene and (meth)acrylic acid ester; poly(meth)acrylic acid ester, saponified products of acrylic acid ester copolymers such as from copolymers between butyl(meth)acrylate and vinyl acetate; copolymers between (meth)acrylic acid ester and (meth)acrylic acid; and copolymers of styrene with (meth)acrylic acid ester and (meth)acrylic acid.

The softening point (Vicat) of the thermoplastic resin is not particularly limited, may be suitably selected in accordance with the intended use, and it is preferably 80° C. or less, for example.

Examples of a thermoplastic resin having a softening point of 80° C. or less, besides the above-mentioned thermoplastic resins include thermoplastic resins that are soluble in alkaline liquids among from organic polymers having a softening point of about 80° C. described in “Handbook of Plastic Performance” (edited by Japan Plastic Forming Industry Association of The Japan Plastics Industry Association, issued on Oct. 25, 1968). Further, organic polymers having a softening point of 80° C. or more can be used after substantially reducing the softening point by adding various plasticizers soluble in the organic polymers.

When the cushion layer is insoluble in alkaline liquids, for the thermoplastic resin, copolymers having an essential component of ethylene as the primary component can be used.

The copolymer having an essential component of ethylene as the primary component is not particularly limited and may be suitably selected in accordance with the intended use. Examples thereof include ethylene-vinyl acetate copolymers (EVA), and ethylene-ethyl acrylate copolymers (EEA).

The thickness of the cushion layer is not particularly limited, may be suitably selected in accordance with the intended use, and for example, it is preferably 5 μm to 50 μm, more preferably 10 μm to 50 μm, and particularly preferably 15 μm to 40 μm.

When the thickness is less than 5 μm, a fine and precise permanent pattern may not be formed due to lowered convexoconcave following capability to concave and convex portions, air bubbles and the like on a surface of the substrate. When the thickness is more than 50 μm, it may cause problems such as increased burden from being dried in the course of production.

### <<Protective Film>>

In the pattern forming material, a protective film may be provided on the photosensitive layer. The material of the protective film may be those exemplified with respect to the support set forth above, and also may be paper, polyethylene, paper laminated with polypropylene, or the like. Among these materials, polyethylene film and polypropylene film are preferable.

The thickness of the protective film may be properly selected without particular limitations; preferably, the thickness is 5 μm to 100 μm, more preferably is 8 μm to 50 μm, and still more preferably is 10 μm to 30 μm.

When the protective film is used, it is preferable that an adhesion X between the photosensitive layer with the support and an adhesion Y between the photosensitive layer and the protective film satisfy the relation, adhesion X>adhesion Y.

The combinations of the support and the protective film, i.e. (support/protective film), are exemplified by (polyethylene terephthalate/polypropylene), (polyethylene terephthalate/polyethylene), (polyvinyl chloride/cellophane), (polyimide/polypropylene), and (polyethylene terephthalate/polyethylene terephthalate). Further, the surface treatment of the support and/or the protective film may result in the relation of the adhesive strength set forth above. The surface treatment of the support may be utilized for enhancing the adhesive strength with the photosensitive layer; examples of the surface treatment include deposition of under-coat layer, corona discharge treatment, flame treatment, UV-rays treatment, RF exposure treatment, glow discharge treatment, active plasma treatment, and laser beam treatment.

The static friction coefficient between the support and the protective film is preferably 0.3 to 1.4, more preferably is 0.5 to 1.2.

When the static friction coefficient is less than 0.3, winding displacement may occur when the pattern forming material is in a roll configuration due to excessively high slipperiness, and when the static friction coefficient is more than 1.4, winding of the material in a roll configuration tends to be difficult.

Preferably, the pattern forming material is wound on a cylindrical winding core and is formed in an elongated roll shape. The length of the elongated pattern forming material may be properly selected without particular limitations, for example the length is from 10 meters to 20,000 meters. Further, the pattern forming material may be subjected to slit processing for easy handling in the usage, and may be provided as a roll configuration for every 100 meters to 1,000 meters. Preferably, the pattern forming material is wound such that the support exists at outer most side of the roll configuration. Further, the pattern forming material may be slit into a sheet configuration. In the storage, preferably, a separator of moisture proof with desiccant in particular is provided at the end surface of the pattern forming material, and the package is performed by a material of higher moisture proof for preventing edge fusion.

The protective film may be subjected to surface treatment in order to control the adhesive property between the protective film and the photosensitive layer. The surface treatment is performed, for example, by providing an under-coat layer of polymer such as polyorganosiloxane, fluorinated polyolefin, polyfluoroethylene, and polyvinyl alcohol on the surface of the protective film. The under-coat layer may be formed by coating the liquid of the polymer on the surface of the protective film, then drying the coating at 30 to 150° C., in particular 50 to 120° C. for 1 to 30 minutes. In addition to the photosensitive layer, the support, and the protective film, other layers such as an exfoliation layer, adhesive layer, optical absorbing layer, and surface protective layer may be provided.

### <<Other Layers>>

The other layers may be properly selected depending on the application; examples of the other layers include a cushioning layer, barrier layer, peeling layer, adhesive layer, optical absorbing layer, surface protective layer, and the like. The pattern forming material may include one of these layers or two or more of these layers, or may include two or more layers of an identical type.

### [Substrate]

The substrate may be properly selected from commercially available materials, which may be of nonuniform surface other than of highly smooth surface. Preferably, the substrate is plate-like; specifically, the substrate selected from the materials such as printed wiring boards e.g. cupper-laminated plate, glass plates e.g. soda glass plate, synthetic resin films, paper, and metal plates.

The substrate is utilized such that the photosensitive layer of the pattern forming material is duplicated on the substrate to form a consolidated laminate. In such a construction, a pattern may be formed by a developing step, for example, through exposing the photosensitive layer of the pattern forming material on the laminate thereby hardening the exposed region.

The pattern forming material in the present invention may be applied to printed wiring boards, color filters; display members such as a column member, rib member, spacer, and partition member; holograms, micro machines, and proofs. Also, the pattern forming material may be applied to the pattern forming processes according to the present invention.

In the pattern forming process according to the present invention, permanent patterns may be precisely and effectively formed by suppressing the distortion of images formed on the pattern forming material, therefore, the pattern forming process may be successfully applied to various patterns that require highly precise exposure, in particular to highly precise interconnection patterns.

### [Process for Producing Printed Wiring Board]

The pattern forming process according to the present invention may be successfully applied to the production of printed wiring boards, in particular the printed wiring boards having through holes or via holes, and to the production of color filters. The processes for producing printed wiring boards and color filters based on the pattern forming process according to the present invention will be exemplarily explained in the following.

In process for producing printed wiring boards having through holes and/or via holes, a pattern may be formed by (i) laminating the pattern forming material on a substrate of a printed wiring board having holes such that the photosensitive layer faces the substrate thereby to form a laminated body, (ii) irradiating a light onto the regions for forming interconnection patterns and holes from the opposite side of the substrate of the laminated body thereby to harden the photosensitive layer, (iii) removing the support of the pattern forming material from the laminated body, and (iv) developing the photosensitive layer of the laminated body to remove unhardened portions in the laminated body.

By the way, removing the support of (iii) may be carried out between the (i) and (ii) instead of between (ii) and (iv) set forth above.

Then, using the formed pattern, etching treatment or plating treatment of the substrate of the printed wiring board by means of conventional subtractive or additive method e.g. semi-additive or full-additive method may produce the printed wiring board. Among these methods, the subtractive method is preferable in order to form printed wiring boards by industrially advantageous tenting. After the treatment, the hardened resin remaining on the substrate of the printed wiring board is peeled off, or copper thin film is etched after the peeling in the case of semi-additive process, thereafter the intended printed wiring board is obtained. In the case of multi-layer printed wiring board, the similar process with the printed wiring board may be applicable.

The process for producing printed wiring boards having through holes by means of the pattern forming material will be explained in the following.

Initially, the substrate of printed wiring board is prepared in which the surface of the substrate is covered with a metal plating layer. The substrate of printed wiring board may be a copper-laminated layer substrate, a substrate that is produced by forming a copper plating layer on an insulating substrate such as glass or epoxy resin, or a substrate that is laminated on these substrate and formed into a copper plating layer.

In a case where a protective layer exists on the pattern forming material, the protective film is peeled, and the photosensitive layer of the pattern forming material is contact bonded to the surface of the printed wiring board by means a pressure roller as a laminating process, thereby a laminated body may be obtained that contains the substrate of the printed wiring board and the laminated body set forth above.

The laminating temperature of the pattern forming material may be properly selected without particular limitations; the temperature may be about room temperature such as 15° C. to 30° C., or higher temperature such as 30° C. to 180° C., preferably it is substantially warm temperature such as 60° C. to 140° C. The roll pressure of the contact bonding roll may be properly selected without particular limitations; preferably the pressure is 0.1 MPa to 1 MPa; the velocity of the contact bonding may be properly selected without particular limitations, preferably, the velocity is 1 meter/m to 3 meters/m.

The substrate of the printed wiring board may be pre-heated before the contact bonding; and the substrate may be laminated under a reduced pressure.

The laminated body may be formed by laminating the pattern forming material on the substrate of the printed wiring board; alternatively by coating the solution of the photosensitive resin composition for pattern forming material directly on the substrate of the printed wiring board, followed by drying the solution, thereby laminating the photosensitive layer and the support on the substrate of the printed wiring board.

Then, a laser beam is irradiated onto the photosensitive layer from the opposite side of the substrate of the laminated body thereby to harden the photosensitive layer. In such a case, the irradiation is performed after the support is peeled, depending on the requirement such that the transparency of the support is lower. Here, when an energy amount of laser beam applied to the upper portion of through holes of the photosensitive layer (regions to form tents) is regarded as A, and an energy amount of laser beam applied to the regions of the photosensitive layer other than the through holes (regions to form printed wiring boards) is regarded as B, the photosensitive layer is irradiated with laser beam such that A is larger than B. By making the energy amount of laser beam applied to the regions to form tents higher than that of the regions to form printed wiring boards, the hardness of the tent film to be formed on the hole portions can be increased to thereby improve the durability of the tent film in the processes subsequent to the developing. Further, when the diameter of hole portions is large, a tent film having high hardness can be formed without thickening the photosensitive layer.

The method for increasing the energy amount of laser beam applied to the regions to form tents is not particularly limited. Examples thereof include a method in which the intensity of laser beam applied is increased, and a method in which the time for applying a laser beam is lengthened.

In the process, in accordance with the necessity, for example, when the light transmission of the support is insufficient, the support may be exfoliated before the exposing process.

In the case that the support exists on the support after the laser irradiation, the support is peeled from the laminated body as the support peeling step.

The un-hardened region of the photosensitive layer on the substrate of the printed wiring board is dissolved away by means of an appropriate developer, a pattern is formed that contains a hardened layer for forming an interconnection pattern and a hardened layer for protecting a metal layer of through holes, and the metal layer is exposed at the substrate surface of the printed wiring board as the developing step.

Additional treatment to promote the hardening reaction, for example, may be performed by means of post-heating or post-exposing optionally. The developing may be of a wet method set forth above or a dry developing method.

Then, the metal layer exposed on the substrate surface of the printed wiring board is dissolved away by an etching liquid as an etching process. The apertures of the through holes are covered by cured resin or tent film, therefore, the etching liquid does not infiltrate into the through holes to corrode the metal plating within the through holes, and the metal plating may maintain the specific shape, thus an interconnection pattern may be formed on the substrate of the printed wiring board.

The etching liquid may be properly selected depending on the application; cupric chloride solution, ferric chloride solution, alkali etching solution, and hydrogen peroxide solution are exemplified for the etching liquid when the metal layer set forth above is formed of copper; among these, ferric chloride solution is preferred in light of the etching factor.

Then, the hardened layer is removed from the substrate of the printed wiring board by means of a strong alkali aqueous solution for example as the removing step of hardened material.

The basic component of the strong alkali aqueous solution may be properly selected without particular limitations, examples of the basic component include sodium hydroxide and potassium hydroxide. The pH of the strong alkali aqueous solution may be about 12 to 14 for example, preferably is about 13 to 14. The strong alkali aqueous solution may be an aqueous solution of sodium hydroxide or potassium hydroxide at a concentration of 1 to 10% by mass.

The printed wiring board may be of multi-layer construction. By the way, the pattern forming material set forth above may be applied to plating processes instead of the etching process set forth above. The plating method may be copper plating such as copper sulfate plating and copper pyrophosphate plating, solder plating such as high flow solder plating, nickel plating such as watt bath (nickel sulfate-nickel chloride) plating and nickel sulfamate plating, and gold plating such as hard gold plating and soft gold plating.

Hereafter, the present invention will be further described in detail referring to specific Examples and Comparative Examples, however, the present invention is not limited to the disclosed Examples.

### EXAMPLE 1

### Production of Laminate

### —Production of Pattern Forming Material—

A photosensitive resin composition solution composed of the following composition was applied over a surface of polyethylene terephthalate film 20 μm in thickness as the support, and the surface of the support was dried to form a photosensitive layer 15 μm in thickness, thereby the pattern forming material was produced.

| | |
|---|---|
| Methylmethacrylate/2-ethylhexyl acrylate/benzyl methacrylate/methacrylic acid copolymer (composition | 15 parts by mass |
| of copolymer (mass ratio)): 50/20/7/23; mass average molecular mass: 90,000; and acid value 150) | |
| Polymerizable monomer represented by the following Structural Formula (73) | 7.0 parts by mass |
| Adduct of ½ molar ratio of hexamethylene diisocyanate and tetraethylene oxide monomethacrylate | 7.0 parts by mass |
| N-methylacridone | 0.11 parts by mass |
| 2,2-bis(o-chlorophenyl)-4,4′,5,5′-tetraphenylbiimidazole | 2.17 parts by mass |
| 2-mercaptobenzimidazole | 0.23 parts by mass |
| malachite green oxalate | 0.02 parts by mass |
| leuko-crystal violet | 0.26 parts by mass |
| methylethylketone | 40 parts by mass |
| 1-methoxy-2-propanol | 20 parts by mass |

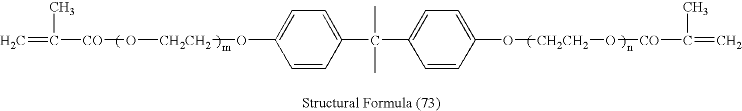

In Structural Formula (73), “m+n” is equal to 10. It should be noted that the compound represented by the Structural Formula (73) is an example of a compound represented by the Structural Formula (38).

On the photosensitive layer of the pattern forming material, polyethylene film 20 μm in thickness as the protective film was laminated. Next, to the surface of a copper-clad laminate (having no through hole and a copper thickness of 12 μm) which had been polished, washed, and dried, the pattern forming material was pressure bonded using a laminator (MODEL8B-720-PH, manufactured by Taisei Laminator Co. Ltd.) while peeling the pattern forming material such that the photosensitive layer of the pattern forming material made contact with the copper-clad laminate to thereby prepare a laminate in which the copper-clad laminate, the photosensitive layer, and the polyethylene terephthalate film (support) were formed in this order in a laminate structure.

As the pressure bonding conditions, the pressure roller temperature was set at 105° C., the pressure roller pressure was set at 0.3 MPa, and the laminating rate was set at 1 meter/m.

The produced laminate was measured as to the shortest developing time and photosensitivity (light energy amount necessary to harden the photosensitive layer).

(1) Measurement of the Shortest Developing Time

The polyethylene terephthalate film (support) was exfoliated from the laminate, 1% by mass sodium carbonate aqueous solution of 30° C. was sprayed over the entire surface of the photosensitive layer formed on the copper-clad laminate at a pressure of 0.15 MPa. Then, the time required from the beginning of spraying of the sodium carbonate aqueous solution until that the photosensitive layer on the copper-clad laminate was dissolved and removed was measured. The time was regarded as the shortest developing time. The shortest developing time was 10 seconds.

(2) Measurement of Photosensitivity

The photosensitive layer of the pattern forming material in the prepared laminate was exposed with light while varying optical energy among from 0.1 mJ/cm² to 100 mJ/cm² at a 2^{1/2} intervals to thereby harden a part of regions of the photosensitive layer. The pattern forming material was left intact at room temperature for 10 minutes, and the polyethylene terephthalate film (support) was exfoliated from the laminate. Then, 1% by mass sodium carbonate aqueous solution of 30° C. was sprayed over the entire surface of the photosensitive layer on the copper-clad laminate at spray pressure of 0.15 MPa for double the shortest developing time to dissolve and remove unhardened regions and then to measure the thickness of remaining hardened regions.

Next, the relation between the exposure dose and the thickness of the hardened layer was plotted to obtain a photosensitive curve. From the thus obtained photosensitive curve, the light energy amount when the thickness of the hardened regions was 15 μm was regarded as an light energy amount required to harden the photosensitive layer.

As the result, the optical energy required to harden the photosensitive layer was 3 mJ/cm².

### <Pattern Forming>

### —Pattern Forming Apparatus—

A pattern forming apparatus was employed which was provided with the combined laser source shown in FIGS. 27A to 32 as a laser source; DMD 50 as the laser modulator, in which 1,024 micromirrors are arrayed as one array in the main scanning direction shown in FIGS. 4A and 4B, 768 sets of the arrays are arranged in the sub-scanning direction, and 1,024 rows×256 lines among these micromirrors can be driven; microlens array 472 in which microlenses 474, of which one surface is a toric surface as shown in FIG. 13A, are arrayed; and optical systems 480, 482 that images the laser through the microlens array onto the pattern forming material.

The toric surface of the microlens was as follows. In order to compensate the distortion of the output surface of microlenses 474 as the imaging portions of DMD 50, the distortion at the output surface was measured, and the results were shown in FIG. 14. In FIG. 14, contour lines indicate the identical heights of the reflective surface, the pitch of the contour lines is 5 nm. In FIG. 14, X and Y directions are two diagonals of micromirror 62, the micromirror 62 may rotate around the rotating axis extending to Y direction. In FIGS. 15A and 15B, the height displacements of micromirrors 62 are shown along the X and Y directions respectively.

As shown in FIGS. 14, 15A, and 15B, there exists distortion at the reflective surface of micromirror 62. With respect to the central portion of the micromirror, the distortion in one diagonal direction i.e. Y direction is larger than the other diagonal direction. Therefore, the shape of laser beam B should be distorted at the collected site through microlenses 55a of microlens array 55.

In FIGS. 16A and 16B, the front shape and side shape of the entire microlens array 55 are shown in detail, and also shown the sizes of various portions in the unit of millimeter (mm). As explained before referring to FIGS. 4A and 4B, 1024 lines×256 rows of micromirrors 62 in DMD 50 are driven; correspondingly, microlens array 55 is constructed such that 1024 of microlenses 55a are aligned in width direction to form one row and the 256 rows are arrayed in length direction. In FIG. 16A, each of the sites of microlenses 55a is expressed by “j” in the width direction and “k” in the length direction.

In FIGS. 17A and 17B, the front shape and the side shape of microlens 55a of microlens array 55 are shown respectively. In FIG. 17A, contour lines of microlens 55a are also shown. Each of the end surfaces of the microlenses 55a is non-spherical surface in order to compensate the aberration due to the distortion of the reflective surface of micromirror 62. Specifically, microlens 55a is a toric lens; the curvature radius of optical X direction Rx is −0.125 mm, and the curvature radius of optical Y direction Ry is −0.1 mm.

Accordingly, the collecting condition of laser beam B within the cross section parallel to the X and Y directions are approximately as shown in FIGS. 18A and 18B respectively. Namely, comparing the X and Y directions, the curvature radius of microlens 55a is shorter and the focal length is also shorter in Y direction.

FIGS. 19A, 19B, 19C, and 19D show the simulations of beam diameter near the focal point of microlens 55a in the above noted shape. For the reference, FIGS. 20A, 20B, 20C, and 20D show the simulations for microlens of Rx=Ry=−0.1 mm. The values of “z” in the figures are expressed as the evaluation sites in focus direction of microlens 55a by the distance from the laser beam irradiating surface of microlens 55a.

The surface shape of microlens 55a in the simulation may be calculated by the following equation.

$$Z = \frac{{C}_{x}^{2} {X}^{2} + {C}_{y}^{2} {Y}^{2}}{1 + SQRT ( 1 - {C}_{x}^{2} {X}^{2} - {C}_{y}^{2} {Y}^{2} )}$$

In the above equation, Cx means the curvature (=1/Rx) in X direction, Cy means the curvature (=1/Ry) in Y direction, X means the distance from optical axis O in X direction, and Y means the distance from optical axis O in Y direction.

From the comparison of FIGS. 19A to 19D, and FIGS. 20A to 20D, it is apparent in the pattern forming process according to the present invention that the employment of the toric lens as the microlens 55a that has a shorter focal length in the cross section parallel to Y direction than the focal length in the cross section parallel to X direction may reduce the strain of the beam shape near the collecting site. Consequently, images can be exposed on pattern forming material 150 with more clearness and without distortion or strain. In addition, it is apparent that the inventive mode shown in FIGS. 19A to 19D may bring about a wider region with smaller beam diameter, i.e. longer focal depth.

Further, aperture arrays 59 disposed near the collecting site of microlens array 55 are constricted such that each aperture 59a receives only the light through the corresponding microlens 55a. Namely, aperture array 59 may afford the respective apertures with the insurance that the light incidence from the adjacent apertures 59a may be prevented and the extinction ratio may be enhanced.

(3) Measurement of Resolution

A laminate was prepared in the same manner and same conditions as in the evaluation method employed in (1) the shortest developing time, and the laminate was left intact at room temperature (23° C., 55% RH) for 10 minutes. From the side of the obtained polyethylene terephthalate film (support) of the laminate, the pattern forming material was exposed at line/space=1/1 of each line width from 10 μm to 50 μm on every 5 μm interval using the pattern forming apparatus. The exposure dose was set to the light energy amount (3 mJ/cm²) required to harden the photosensitive layer of the pattern forming material measured in (2) Measurement of Photosensitivity stated above. The pattern forming material was left intact at room temperature for 10 minutes, and then the polyethylene terephthalate film (support) was exfoliated from the laminate. Then, 1% by mass sodium carbonate aqueous solution of 30° C. was sprayed over the entire surface of the photosensitive layer formed on the copper-clad laminate at a spray pressure of 0.15 MPa for double the shortest developing time determined in (1) Measurement of the shortest developing time stated above to thereby dissolve and remove unhardened regions of the photosensitive layer. The surface of the thus obtained copper-clad laminate with hardened resin pattern formed thereon was observed using an optical microscope. The shortest line width with no abnormality such as stuck and clogging was measured, and the shortest line was evaluated as the resolution. The smaller the resolution value the better. Table 3 shows the evaluation results.

(4) Measurement of Exposing Speed

Using the pattern forming apparatus, the speed to move the exposing light and the photosensitive layer relatively was altered to determine the speed at which a typical interconnection pattern was formed. The photosensitive layer of the pattern forming material in the prepared laminate was exposed from the polyethylene terephthalate film (support) side. The higher the set speed allows more efficient pattern formation. Table 3 shows the evaluation results.

(5) Evaluation of Etching Property

A laminate having the pattern formed thereon in (3) Measurement of Resolution was used, and over the exposed surface of the copper-clad laminate in the laminate, an iron chloride etchant (ferric chloride-containing etching solution, Baume: 40° C., liquid temperature: 40° C.) was sprayed at 0.25 MPa for 36 seconds to dissolve and remove exposed regions of the copper layer, which were not covered with a hardened layer, thereby the surface of the laminate was subjected to an etching treatment. Next, 2% by mass sodium hydroxide aqueous solution was sprayed over the laminate surface to remove the formed pattern and thereby prepare a printed wiring board provided with an interconnection pattern of copper-layer on a surface thereof as the permanent pattern. The interconnection pattern formed on the printed wiring substrate was observed using an optical microscope to measure the shortest line width of the interconnection pattern. The smaller the shortest line width allows obtaining the finer and the more precise interconnection pattern and means that the interconnection pattern excels in etching property. Table 3 shows the measurement results.

### <Production of Printed Wiring Board>

A laminate was prepared in the same manner as stated above except that a copper-clad laminate provided with through holes of 100 μmφ, 150 μmφ, 200 μmφ, 300 μmφ, 400 μmφ, 500 μmφ, 1 mmφ, 2 mmφ, 3 mmφ, and 4 mmφ was used as the substrate. The laminate was exposed using the pattern forming apparatus. A hardened relief was obtained in the same manner as in (3) Measurement of Resolution except that the energy amount of laser light applied to the through holes was tripled (9 mJ/cm²) the light applied to the wiring portions by tripling the intensity of light.

(6) Evaluation of Tenting Property

The hardened layer pattern formed on the printed wiring board was observed to check whether or not there was any defect of the tent layer. As for the wiring portions, presence or absence of peel-off of the hardened layer was checked. As for the tent layer formed on through holes, presence or absence of tears was checked. The tent layer formed on the through holes 100 μm to 500 μm in diameter was observed using an optical microscope at a magnification of 100 times, and the tent layer formed on through holes of 1 mmφ to 4 mmφ was checked visually.

Laminates were evaluated as to tent property based on the length of the maximum through hole diameter without having tear portions. The longer the maximum thorough hole diameter, the more excellent in tent property. Table 4 shows the results.

### EXAMPLE 2

A pattern forming material was produced in the same manner as in Example 1 except that a hexamethylene diisocyanate and tetraethyleneoxide mono-methacrylate adduct at a molar ratio of 1/2 of the photosensitive resin composition solution was changed to a compound represented by the following Structural Formula (74). The shortest developing time was 10 seconds, and the light energy amount required to harden the photosensitive layer was 3 mJ/cm². The compound represented by the Structural Formula (74) is an example of the compound represented by the Structural Formula (24).

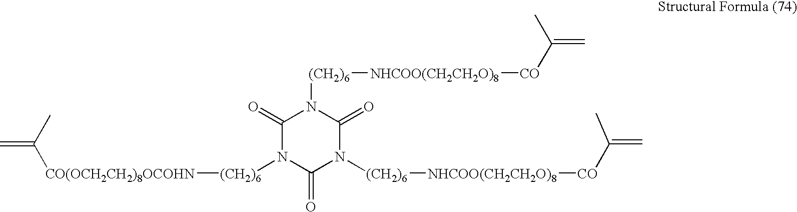

A pattern similar to the pattern in Example 1 was formed on the pattern forming material, and the laminate with the pattern formed thereon was evaluated as to resolution, exposing speed, and etching property. Table 3 shows the results. Further, a printed wiring board was produced in the same manner as in Example 1, a pattern was formed by increasing the energy amount of light applied to the through hole portions to a tripled amount i.e. 9 mJ/cm². The tent layer was evaluated as in Example 1. Table 4 shows the results.

### EXAMPLE 3

A pattern forming material was produced in the same manner as in Example 1 except that a hexamethylene diisocyanate and tetraethyleneoxide mono-methacrylate adduct at a molar ratio of 1/2 of the photosensitive resin composition solution was changed to a compound represented by the following Structural Formula (75). The shortest developing time was 10 seconds, and the light energy amount required to harden the photosensitive layer was 3 mJ/cm². The compound represented by the Structural Formula (75) is an example of the compound represented by the Structural Formula (22).

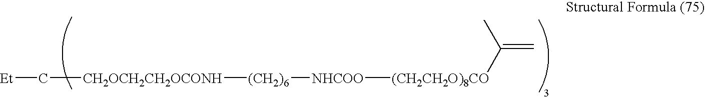

A pattern similar to the pattern in Example 1 was formed on the pattern forming material, and the laminate with the pattern formed thereon was evaluated as to resolution, exposing speed, and etching property. Table 3 shows the results. Further, a printed wiring board was produced in the same manner as in Example 1, a pattern was formed by increasing the energy amount of light applied to the through hole portions to a tripled amount i.e. 9 mJ/cm². The tent layer was evaluated as in Example 1. Table 4 shows the results.

### EXAMPLE 4

A pattern forming material was produced in the same manner as in Example 1 except that methyl methacrylate/2-ethylhexylacrylate/benzyl methacrylate/methacrylic acid copolymer (copolymer composition (mass ratio): 50/20/7/23; mass average molecular mass: 90,000, acid value 150) was changed to methyl methacrylate/styrene/benzyl methacrylate/methacrylic acid copolymer (copolymer composition (mass ratio): 8/30/37/25; mass average molecular mass: 60,000; acid value 163). The shortest developing time was 10 seconds, and the light energy amount required to harden the photosensitive layer was 3 mJ/cm².

A pattern similar to the pattern in Example 1 was formed on the pattern forming material, and the laminate with the pattern formed thereon was evaluated as to resolution, exposing speed, and etching property. Table 3 shows the results. Further, a printed wiring board was produced in the same manner as in Example 1, a pattern was formed by increasing the energy amount of light applied to the through hole portions to a tripled amount i.e. 9 mJ/cm². The tent layer was evaluated as in Example 1. Table 4 shows the results.

### EXAMPLE 5

### Production of Laminate

### —Production of Pattern Forming Material—

A cushion layer coating solution composed of the following composition was applied over a surface of a polyethylene terephthalate film having a thickness of 16 μm as the above-noted support of a laminate, and the support surface was dried to thereby form a cushion layer having a thickness of 15 μm.

[Composition of Cushion Layer Coating Solution]

| | |
|---|---|
| Methyl methacrylate/2-ethylehexyl | 60 parts by mass |
| acrylate/benzyl methacrylate/methacrylic | |
| acid copolymer (copolymer composition | |
| (molar ratio): 55/10/5/30; | |
| mass average molecular mass: 100,000) | |
| Styrene/acrylic acid (copolymer composition | 140 parts by mass |
| (molar ratio): 65/35; mass average | |
| molecular mass: 10,000) | |
| 2,2-bis(4-(methacryloyloxyipentaethoxy) phenyl) | 150 parts by mass |
| propane (BPE-500, manufactured by | |
| Shin-Nakamura Chemical Co., Ltd.) | |
| 2,3-dihydroxy-1,4-dioxane | 10 parts by mass |
| Methylethylketone | 700 parts by mass |

Next, a barrier layer-coating solution composed of the following composition was applied over the surface of the cushion layer, and the surface was dried to for a barrier layer having a thickness of 2.5 μm.

[Composition of Barrier Layer-Coating Solution]

| | |
|---|---|
| Polyvinyl alcohol | 13 parts by mass |
| (PVA 205, manufactured by KURARAY Co., Ltd.) | |
| Polyvinyl pyrolidone | 6 parts by mass |
| (K-30, manufactured by ISP Co. Ltd.) | |
| Water | 200 parts by mass |
| Methanol | 180 parts by mass |

The same photosensitive resin composition solution as used in Example 1 was applied over the surface of the barrier layer, the surface was dried to form a photosensitive layer having a thickness of 5 μm on the barrier layer, thereby a pattern forming material was produced in the same manner as in Example 1. The shortest developing time was 15 seconds, and the light energy amount required to harden the photosensitive layer was 2 mJ/cm².

A pattern similar to the pattern in Example 1 was formed on the pattern forming material, and the laminate with the pattern formed thereon was evaluated as to resolution, exposing speed, and etching property. Table 3 shows the results. Further, a printed wiring board was produced in the same manner as in Example 1, a pattern was formed by increasing the energy amount of light applied to the through hole portions to a quintupled amount i.e. 10 mJ/cm². The tent layer was evaluated as in Example 1. Table 4 shows the results.

### COMPARATIVE EXAMPLE 1

The tent layer was evaluated in the same manner as in Example 1 except that the energy amount of light applied to through hole portions was set at the same level as in other regions i.e. 3 mJ/cm² in the production of Printed Wiring Board of Example 1. Table 4 shows the results.

### COMPARATIVE EXAMPLE 2

The tent layer was evaluated in the same manner as in Example 1 except that the energy amount of light applied to through hole portions was set at the same level as in other regions i.e. 3 mJ/cm² in the production of Printed Wiring Board of Example 2. Table 4 shows the results.

### COMPARATIVE EXAMPLE 3

The tent layer was evaluated in the same manner as in Example 1 except that the energy amount of light applied to through hole portions was set at the same level as in other regions i.e. 3 mJ/cm² in the production of Printed Wiring Board of Example 3. Table 4 shows the results.

### COMPARATIVE EXAMPLE 4

The tent layer was evaluated in the same manner as in Example 1 except that the energy amount of light applied to through hole portions was set at the same level as in other regions i.e. 3 mJ/cm² in the production of Printed Wiring Board of Example 4. Table 4 shows the results.

### COMPARATIVE EXAMPLE 5

The tent layer was evaluated in the same manner as in Example 1 except that the energy amount of light applied to through hole portions was set at the same level as in other regions i.e. 2 mJ/cm² in the production of Printed Wiring Board of Example 4. Table 4 shows the results.

TABLE 3

| | | Exposing | Etching |
|---|---|---|---|
| | Resolution | speed | property |
| | (μm) | (mm/sec) | (μm) |
| Ex. 1 | 15 | 40 | 25 |
| Ex. 2 | 15 | 40 | 25 |
| Ex. 3 | 15 | 40 | 25 |
| Ex. 4 | 15 | 40 | 25 |
| Ex. 5 | 15 | 40 | 25 |

TABLE 4

| | | | Wiring | Evaluation on |
|---|---|---|---|---|
| | | | portion | tent property |
| | Irradiation energy | | Peel-off at | Maximum |
| | amount (mJ/cm²) | | hardened | through |
| | Hole portion | Wiring portions | layer | hole diameter |
| Ex. 1 | 9 | 3 | None | 3 mm |
| Ex. 2 | 9 | 3 | None | 3 mm |
| Ex. 3 | 9 | 3 | None | 3 mm |
| Ex. 4 | 9 | 3 | None | 3 mm |
| Ex. 5 | 10 | 2 | None | 200 μm |
| Compara. | 3 | 3 | None | 2 mm |
| Ex. 1 | | | | |
| Compara. | 3 | 3 | None | 2 mm |
| Ex. 2 | | | | |
| Compara. | 3 | 3 | None | 2 mm |
| Ex. 3 | | | | |
| Compara. | 3 | 3 | None | 2 mm |
| Ex. 4 | | | | |
| Compara. | 2 | 2 | None | 100 μm |
| Ex. 5 | | | | |

From the results shown in Table 3, it turned out that the pattern forming processes of Examples 1 to 5 allowed efficiently, highly precisely forming of a pattern at high exposing speed. Further, from the results shown in Table 4, it turned out that it was possible to form a hardened layer excelling in tent property on through holes having large diameters as well by increasing the energy amount of light irradiation applied to only hole portions.

### INDUSTRIAL APPLICABILITY

The pattern forming process of the present invention allows forming of a permanent pattern efficiently and highly precisely by substantially preventing distortion of an image to be formed on a pattern forming material and allows achieving both tent property and resolution at high level. Thus, the pattern forming process of the present invention can be preferably used for forming of various patterns which needs highly precise exposure and particularly can be preferably used for forming a highly precise interconnection pattern.

1. A pattern forming process comprising:
laminating a photosensitive layer on a substrate to be processed in a pattern forming material which comprises at least the photosensitive layer, and
exposing two or more arbitrarily selected regions in the photosensitive layer respectively with a laser beam of a different amount of energy,
wherein the photosensitive layer comprises a binder, a polymerizable compound, and a photopolymerization initiator.

2. The pattern forming process according to claim 1, wherein a laser beam emitted from a light irradiating unit is modulated using a light modulating unit having ‘n’ imaging portions receiving light from the light irradiating unit and outputting the light before the photosensitive layer is exposed with laser beam through a microlens array in which microlenses each having a non-spherical surface capable of compensating the aberration due to distortion of output surfaces of the imaging portions are arrayed.

3. The pattern forming process according to claim 1, wherein a laser beam emitted from a light irradiating unit having ‘n’ imaging portions receiving light from a light irradiating unit and outputting the light is modulated before the photosensitive layer is exposed with the laser beam through a microlens array in which microlenses each having a lens aperture shape that prevents light from the periphery of the imaging portions from entering the each of lenses.

4. The pattern forming process according to claim 3, wherein each of the microlenses comprises a non-spherical surface capable of compensating the aberration due to distortion of output surfaces of the imaging portions.

5. The pattern forming process according to claim 2, wherein the non-spherical surface is a toric surface.

6. The pattern forming process according to claim 3, wherein each of the microlenses has a circular aperture shape.

7. The pattern forming process according to claim 3, wherein the lens aperture shape is defined by providing with a light shielding part on the lens surface.

8. The pattern forming process according to claim 1, wherein the substrate to be processed has hole portions; and the energy amount of light applied to the hole portions of the photosensitive layer differs from the energy amount of light applied to the regions of the photosensitive layer other than the hole portions.

9. The pattern forming process according to claim 8, wherein when the energy amount of light applied to the hole portions of the photosensitive layer is represented by A and the energy amount of light applied to the regions of the photosensitive layer other than the hole portions is represented by B, the relation A>B is satisfied.

10. The pattern forming process according to claim 2, wherein the light modulating unit is able to control any imaging portions of less than arbitrarily selected “n” imaging portions disposed successively from among the ‘n’ imaging portions depending on the pattern information.

11. The pattern forming process according to claim 2, wherein the light modulating unit is a spatial light modulator.

12. The pattern forming process according to claim 11, wherein the spatial light modulator is a digital micromirror device (DMD).

13. The pattern forming process according to claim 1, wherein the photosensitive layer is exposed through an aperture array.

14. The pattern forming process according to claim 1, wherein the photosensitive layer is exposed while relatively moving the exposure light and the photosensitive layer.

15. The pattern forming process according to claim 1, wherein the photosensitive layer is exposed before the photosensitive layer is developed.

16. The pattern forming process according to claim 15, wherein the photosensitive layer is developed before a permanent pattern is formed thereon.

17. The pattern forming process according to claim 16, wherein the permanent pattern is an interconnection pattern and is formed by any one of an etching treatment and a plating treatment.

18. The pattern forming process according to claim 2, wherein the light irradiating unit allows irradiation with two or more combined light.

19. The pattern forming process according to claim 2, wherein the light irradiating unit comprises a plurality of lasers, a multi-mode optical finer, and a collecting optical system which collects respective laser beams and connect them to the multimode optical fiber.

20. The pattern forming process according to claim 1 wherein the photosensitive layer is formed by transcription of a dry film resist.

21. The pattern forming process according to N claim 1, wherein the photosensitive layer is formed by application of a liquid resist.

22. (canceled)

23. The pattern forming process according to claim 1, wherein the binder comprises an acid group.

24. The pattern forming process according to claim 1, wherein the binder comprises a vinyl copolymer.

25. The pattern forming process according to claim 1, wherein the binder has an acid value of 70 mgKOH/g to 250 mgKOH/g.

26. The pattern forming process according to claim 1, wherein the polymerizable compound comprises a monomer containing at least any one of a urethane group, an aryl group, an ethylene oxide group, and propylene oxide group.

27. The pattern forming process according to claim 1, wherein the photopolymerization initiator is at least one selected from the group consisting of halogenated hydrocarbon derivatives, hexaaryl-bimidazole compounds, oxime derivatives, organic peroxides, thio-compounds, ketone compounds, aromatic onium salts, and metallocenes.

28. The pattern forming process according to claim 1, wherein the photosensitive layer comprises the binder in an amount of 10% by mass to 90% by mass and the polymerizable compound in an amount of 5% by mass to 90% by mass.

29. The pattern forming process according to claim 1, wherein the photosensitive layer has a thickness of 1 μm to 100 μm.

30. The pattern forming process according to claim 1, wherein the pattern forming material comprises at least the photosensitive layer on a support.

31. The pattern forming process according to claim 1, wherein the pattern forming material comprises a cushion layer between the support and the photosensitive layer.

32. The pattern forming process according to claim 30, wherein the support comprises a synthetic resin and is transparent.

33. The pattern forming process according to claim 30, wherein the support is formed in an elongated shape.

34. The pattern forming process according to claim 1, wherein the pattern forming material is formed in an elongated roll shape.

35. The pattern forming process according to claim 1, wherein a protective film is formed on the photosensitive layer in the pattern forming material.
